(19) United States
(12) Patent Application Publication
(10) Pub. No.: US 2025/0183051 A1
(43) Pub. Date: Jun. 5, 2025

(54) SELECTIVE PRECISION ETCHING OF SEMICONDUCTOR MATERIALS

(71) Applicant: Lam Research Corporation, Fremont, CA (US)

(72) Inventors: Madeleine Parker GORDON, San Jose, CA (US); Nathan MUSSELWHITE, San Jose, CA (US); Mark Naoshi KAWAGUCHI, San Carlos, CA (US)

(21) Appl. No.: 18/839,177

(22) PCT Filed: Feb. 17, 2023
(86) PCT No.: PCT/US2023/062787

§ 371 Date: Aug. 16, 2024

Related U.S. Application Data
(60) Provisional application No. 63/268,802, filed on Mar. 3, 2022.

(51) Int. Cl. H01L 21/311; C09K 13/08; H01L 21/67

(52) U.S. Cl. CPC H01L 21/31116; C09K 13/08; H01L 21/67069

(57) ABSTRACT

Various embodiments described herein relate to methods and apparatus for etching a semiconductor substrate to remove a target material from a surface of the substrate. Generally, the techniques described herein are thermal techniques that do not rely on the use of plasma. In a number of embodiments, a particular gas mixture is provided to the reaction chamber to react with the target material. The gas mixture may include a combination of a halogen source such as hydrogen fluoride (HF), an organic solvent and/or water, an additive, and a carrier gas. A number of different materials may be used for the organic solvent and/or for the additive. The additive may act to form a complex with HF or another halogen source.

### INCORPORATION BY REFERENCE

A PCT Request Form is filed concurrently with this specification as part of the present application. Each application that the present application claims benefit of or priority to as identified in the concurrently filed PCT Request Form is incorporated by reference herein in their entireties and for all purposes.

### BACKGROUND

Fabrication of semiconductors involves many different kinds of processing. One type of processing involves depositing materials on the surface of a substrate. Another type of processing involves etching materials from the surface of the substrate. In some cases, such etching is done selectively to target one or more material on the substrate for removal.

The background description provided herein is for the purposes of generally presenting the context of the disclosure. Work of the presently named inventors, to the extent it is described in this background section, as well as aspects of the description that may not otherwise qualify as prior art at the time of filing, are neither expressly nor impliedly admitted as prior art against the present disclosure.

### SUMMARY

Various embodiments herein relate to methods and apparatus for etching a semiconductor substrate.

In one aspect of the disclosed embodiments, a method of etching a substrate is provided, the method including: (a) providing the substrate in a reaction chamber, the substrate including a target material that is to be partially or wholly removed from the substrate during etching; (b) providing a gas mixture in the reaction chamber and exposing the substrate to the gas mixture, where the gas mixture is vapor phase and includes: (i) a halogen source, (ii) an organic solvent and/or water, (iii) an additive including a hydrogen fluoride complex forming chemical, and (iv) a carrier gas; and (c) providing thermal energy to the reaction chamber to drive a reaction that partially or wholly etches the target material from the substrate, where the substrate is not exposed to plasma during etching.

In various embodiments, the method may further include prior to (b), providing a second gas mixture in the reaction chamber and exposing the substrate to thermal energy and to the second gas mixture, where the thermal energy drives a second reaction between the second gas mixture and the target material to form a modified target material, and where the reaction in (c) etches the modified target material to thereby partially or wholly etch the target material.

Various chemistries may be used. In a number of embodiments, the hydrogen fluoride complex forming chemical may include at least one group selected from the group consisting of an amine group, a urea group, a phosphine group, an alkyl group, an imidazole group, a heterocyclic aliphatic group, a heterocyclic aromatic group, an ether group, or a combination thereof. In some embodiments, the hydrogen fluoride complex forming chemical may include the urea group. In some such embodiments, the hydrogen fluoride complex forming chemical includes N,N′-dimethylpropylene urea (DMPU). In these or other embodiments, the hydrogen fluoride complex forming chemical may include an alkyl-substituted ammonium compound. In some such embodiments, the hydrogen fluoride complex forming chemical includes a compound selected from the group consisting of tetraethylammonium, tetrabutylammonium, and combinations thereof. In these or other embodiments, the hydrogen fluoride complex forming chemical may include a heterocyclic aromatic amine-containing compound. In some such embodiments, the hydrogen fluoride complex forming chemical includes melamine. In these or other embodiments, the hydrogen fluoride complex forming chemical may include a heterocyclic aliphatic compound and/or a cyclic ether compound. In some such embodiments, the hydrogen fluoride complex forming chemical includes tetrahydrofuran. In these or other embodiments, the hydrogen fluoride complex forming chemical may include an alkyl-substituted imidazole compound, an alkyl-substituted ether compound, and/or an alkyl-substituted phosphine compound. In some such embodiments, the hydrogen fluoride complex forming chemical includes a compound selected from the group consisting of dialkylimidazolium, dimethyl ether, trialkylphosphine, and combinations thereof.

In another aspect of the disclosed embodiments, an apparatus for etching a substrate is provided, the apparatus including: a reaction chamber configured to withstand sub-atmospheric pressure; a substrate support configured to support the substrate during etching; an inlet for introducing a gas mixture to the reaction chamber, where the gas mixture is vapor phase; an outlet for removing vapor phase species from the reaction chamber; and a controller configured to cause: (a) providing the substrate in the reaction chamber, the substrate including a target material that is to be partially or wholly removed from the substrate during etching, (b) providing the gas mixture to the reaction chamber and exposing the substrate to the gas mixture, where the gas mixture is vapor phase and includes: (i) a halogen source, (ii) an organic solvent and/or water, (iii) an additive including a hydrogen fluoride complex forming chemical, and (iv) a carrier gas, and (c) providing thermal energy to the reaction chamber to drive a reaction that partially or wholly etches the target material from the substrate, where the substrate is not exposed to plasma during etching.

The controller may be further configured to cause prior to (b) providing a second gas mixture in the reaction chamber and exposing the substrate to thermal energy and to the second gas mixture, where the thermal energy drives a second reaction between the second gas mixture and the target material to form a modified target material, and where the reaction in (c) etches the modified target material to thereby partially or wholly etch the target material.

Further, the controller may be configured to cause delivery of particular chemistry to the reaction chamber. In a number of embodiments, the hydrogen fluoride complex forming chemical may include at least one group selected from the group consisting of an amine group, a urea group, a phosphine group, an alkyl group, an imidazole group, a heterocyclic aliphatic group, a heterocyclic aromatic group, an ether group, or a combination thereof. In some embodiments, the hydrogen fluoride complex forming chemical may include the urea group. In some such embodiments, the hydrogen fluoride complex forming chemical includes N,N′-dimethylpropylene urea (DMPU). In these or other embodiments, the hydrogen fluoride complex forming chemical may include an alkyl-substituted ammonium compound. In some such embodiments, the hydrogen fluoride complex forming chemical includes a compound selected from the group consisting of tetraethylammonium, tetrabutylammonium, and combinations thereof. In these or other embodiments, the hydrogen fluoride complex forming chemical may include a heterocyclic aromatic amine-containing compound. In some such embodiments, the hydrogen fluoride complex forming chemical includes melamine. In these or other embodiments, the hydrogen fluoride complex forming chemical may include a heterocyclic aliphatic compound and/or a cyclic ether compound. In some such embodiments, the hydrogen fluoride complex forming chemical includes tetrahydrofuran. In these or other embodiments, the hydrogen fluoride complex forming chemical may include an alkyl-substituted imidazole compound, an alkyl-substituted ether compound, and/or an alkyl-substituted phosphine compound. In some such embodiments, the hydrogen fluoride complex forming chemical includes a compound selected from the group consisting of dialkylimidazolium, dimethyl ether, trialkylphosphine, and combinations thereof.

These and other aspects are described further below with reference to the drawings.

### BRIEF DESCRIPTION OF THE DRAWINGS

FIG. 1 is a flow chart describing a method of etching a semiconductor substrate according to certain embodiments.

FIG. 2 is a flow chart describing a cyclic method of etching a semiconductor substrate according to certain embodiments.

FIGS. 3A-3C depict a semiconductor substrate as it undergoes processing according to the method described in FIG. 2.

FIG. 4 illustrates how temperature can be varied overtime to achieve the method of FIG. 2.

FIG. 5 depicts a cross-sectional side view of an example apparatus in accordance with disclosed embodiments.

FIG. 6 depicts a top view of a substrate heater with a plurality LEDs.

FIG. 7 depicts a top view of another substrate heater with a plurality LEDs.

FIG. 8 depicts the pedestal of FIG. 5 with additional features in accordance with various embodiments.

FIG. 9 depicts the substrate support of FIGS. 5 and 8 in accordance with disclosed embodiments.

FIG. 10 depicts a plan view of first example faceplate.

FIG. 11 depicts a plan view of second example faceplate.

FIG. 12 depicts a graph of four different active cooling experiments.

FIG. 13 provides an example temperature control sequence.

FIG. 14 depicts a first technique for thermal processing in accordance with disclosed embodiments.

FIG. 15 depicts a second technique for thermal processing in accordance with disclosed embodiments.

FIG. 16 depicts a third technique for thermal processing in accordance with disclosed embodiments.

FIG. 17 depicts a graph of silicon absorption at various wavelengths and temperatures.

FIG. 18 depicts the pedestal of FIG. 8 with additional features in accordance with various embodiments.

### DETAILED DESCRIPTION

In the following description, numerous specific details are set forth to provide a thorough understanding of the presented embodiments. The disclosed embodiments may be practiced without some or all of these specific details. In other instances, well-known process operations have not been described in detail to not unnecessarily obscure the disclosed embodiments. While the disclosed embodiments will be described in conjunction with the specific embodiments, it will be understood that it is not intended to limit the disclosed embodiments.

In various embodiments herein, a semiconductor substrate is etched using a mixture of vapor phase reactants that include (1) a halogen source such as hydrogen fluoride, (2) an organic solvent and/or water, (3) an additive, and (4) a carrier gas. The terms “vapor phase” and “gas phase” are used interchangeably in this disclosure. The additive may have particular properties or a particular composition, as described further below. The substrate may be etched at low pressure using thermal energy, for example in a vacuum reaction chamber. In such cases, the substrate is not exposed to plasma during the etching reaction. The substrate may be etched in a selective manner, such that one or more materials are targeted for removal while other materials are etched to a lesser degree. One advantage of the disclosed techniques is that they achieve a high degree of selectivity during etching. Another advantage of the disclosed techniques is that they provide extremely precise control of the etching rate and etch removal amount, especially compared to other thermally-driven etch processes.

The techniques described herein may be used to etch a variety of substrate materials in a number of different contexts. In many cases, the substrate includes two or more different materials that are exposed on a surface of the substrate. One of these materials may be targeted for removal over another of these materials in a selective etching process. In some implementations, the substrate includes a first material and a second material, the first material being selectively etched compared to the second material. In other cases, the substrate may include only a single material that is exposed, such that the etching does not need to be selective. In still other cases, the substrate may include multiple different materials that are all removed without any need for selectivity. The first and/or second materials on the substrate may each be selected from the group consisting of: oxides (e.g., silicon oxide, tin oxide, etc.), nitrides (e.g., silicon nitride, tantalum nitride, titanium nitride, etc.), carbides (e.g., silicon carbide, etc.), carbonitrides (e.g., silicon carbonitride, etc.), carboxides (e.g., silicon carboxide, etc.), etc. In some cases, at least one of the first and second materials may be a dielectric material such as a high-k dielectric material or a low-k dielectric material. Generally, high-k dielectric materials are dielectric materials that have a high dielectric constant relative to silicon dioxide, and low-k dielectric materials are dielectric materials that have a low dielectric constant relative to silicon oxide. Silicon oxide has a dielectric constant of about 3.7-3.9. As such, high-k dielectric materials typically have a dielectric constant greater than about 3.9, while low-k dielectric materials typically have a dielectric constant lower than about 3.7. Examples of low-k dielectric materials include carbon-doped silicon oxides, fluorine-doped silicon oxides, as well as spin-on organic polymeric dielectric materials such as polyimides, polynorbenes, and benzocyclobutenes. Examples of high-k dielectric materials include hafnium silicate, zirconium silicate, hafnium dioxide, and zirconium dioxide. In some cases, at least one of the first and second materials is an epitaxial material such as silicon (Si), or silicon germanium (SiGe). The materials exposed on the substrate may be selected in various combinations and provided in various structures, as desired for a particular application. The techniques described herein are widely applicable to many different applications. Further description of etch selectivity on a first material (e.g., silicon dioxide) with a second material (e.g., silicon nitride) is given below.

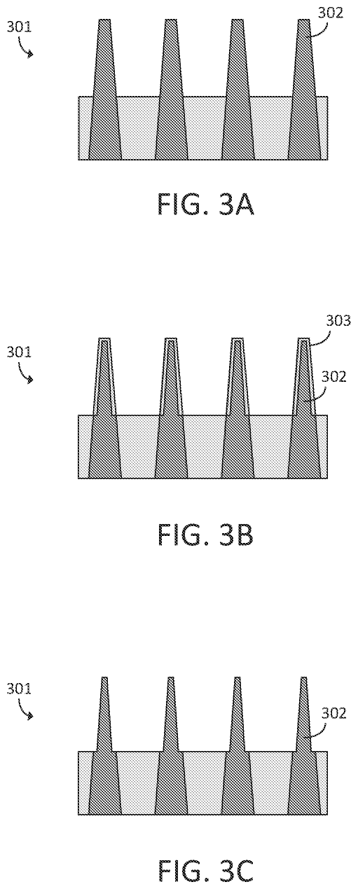

In one particular embodiment, the methods described herein may be used in the context of trimming silicon fins. FIGS. 3A-3C, described further below, illustrate such an embodiment. In another particular embodiment, the methods described herein may be used in the context of removing native oxide on gate-all-around structures. Many other applications are possible.

One advantage of the disclosed techniques is that they achieve extremely precise control of the etching rate. Such etch rate control is substantially improved compared to other thermal (e.g., non-plasma) etching techniques. Another advantage of the disclosed techniques is that they achieve a very high degree of etch selectivity. For instance, an oxide material may be etched with a high degree of selectivity compared to a nitride material. Other materials may be similarly etched in a selective manner.

As mentioned above, the substrate is etched using a particular set of chemistry. This chemistry includes (1) a halogen source such as hydrogen fluoride (HF), (2) one or more organic solvent and/or water, (3) one or more additive, and (4) one or more carrier gas. The reactants are provided to the reaction chamber and exposed to the substrate while they are in vapor phase. Appropriate hardware may be provided to ensure that the reactants are adequately vaporized before and during delivery to the reaction chamber, as described further below. Two or more of the reactants may be mixed before delivery to the reaction chamber. In other embodiments, each of the reactants may be delivered to the reaction chamber individually, for example in separate lines or at separate times.

### Halogen Source

The halogen source may be any halogen-containing (e.g., X-containing, where X is fluorine (F), chlorine (Cl), bromine (Br), or iodine (I)) compound that exists in vapor phase at the processing temperature. Examples include hydrogen fluoride (HF), hydrogen chloride (HCl), hydrogen bromide (HBr), fluorine (F₂), chlorine (Cl₂), bromine (Br₂), chlorine trifluoride (ClF₃), nitrogen trifluoride (NF₃), nitrogen trichloride (NCl₃), and nitrogen tribromide (NBr₃). In some implementations, the halogen source is an organohalide, with examples including fluoroform (CHF₃), chloroform (CHCl₃), bromoform (CHBr₃), carbon tetrafluoride (CF₄), carbon tetrachloride (CCl₄), carbon tetrabromide (CBr₄), perfluorobutene (C₄F₈), and perchlorobutene (C₄Cl₈). In some implementations, the halogen source is a silicon halide, with examples including silicon tetrafluoride (SiF₄), silicon tetrachloride (SiCl₄), silicon tetrabromide (SiBr₄), and compounds that include SiX₆ such as H₂SiX₆. In some implementations, the halogen source is a metal halide with examples including molybdenum hexafluoride (MoF₆), molybdenum hexachloride (MoCl₆), molybdenum hexabromide (MoBr₆), tungsten hexafluoride (WF₆), tungsten hexachloride (WCl₆), tungsten hexabromide (WBr₆), titanium tetrafluoride (TiF₄), titanium tetrachloride (TiCl₄), titanium tetrabromide (TiBr₄), zirconium fluoride (ZrF₄), zirconium chloride (ZrCl₄), and zirconium bromide (ZrBr₄). Metal halides may be used in some embodiments to selectively etch metal oxides.

In the description below, various examples include HF as the halogen source. However, any appropriate halogen source may be used. The volume and mass percentages described for HF can be used for other halogen sources. In some embodiments, two or more halogen sources may be used.

### Organic Solvent

### Alcohols:

In certain implementations, the organic solvent may be an alcohol. The alcohol can be an alcohol having a formula of X—C(R)ₙ(OH)—Y, where:
n is 1;
each X and Y can be independently selected from hydrogen, —[C(R₁)₂]ₘ—C(R²)₃, or OH, wherein each R¹ and R² is independently selected from hydrogen, hydroxyl, aliphatic, haloaliphatic, haloheteroaliphatic, heteroaliphatic, aromatic, aliphatic-aromatic, heteroaliphatic-aromatic, or any combinations thereof, and wherein m is an integer from 0 to 10; and each R independently is selected from hydrogen, hydroxyl, aliphatic, haloaliphatic, haloheteroaliphatic, heteroaliphatic, aromatic, aliphatic-aromatic, heteroaliphatic-aromatic, or any combinations thereof.

In some embodiments, each R,R¹ and R² independently is selected from alkyl, alkenyl, alkynyl, heteroalkyl, heteroalkenyl, heteroalkynyl, haloalkyl, haloalkenyl, haloalkynyl, haloheteroalkyl, haloheteroalkenyl, haloheteroalkynyl, aryl, heterocyclyl, heteroaryl, alkyl-aryl, alkenyl-aryl, alkynyl-aryl, alkyl-heterocyclyl, alkenyl-heterocyclyl, alkynyl-heterocyclyl, alkyl-heteroaryl, alkenyl-heteroaryl, alkynyl-heteroaryl, heteroalkyl-aryl, heteroalkenyl-aryl, heteroalkynyl-aryl, heteroalkyl-heterocyclyl, heteroalkenyl-heterocyclyl, heteroalkynyl-heterocyclyl, heteroalkyl-heteroaryl, heteroalkenyl-heteroaryl, heteroalkynyl-heteroaryl, or any combinations thereof. In particular disclosed embodiments, the alcohol may further be substituted with one or more substituents, such as alkoxy, amide, amine, thioether, thiol, acyloxy, silyl, cycloaliphatic, aryl, aldehyde, ketone, ester, carboxylic acid, acyl, acyl halide, cyano, halogen, sulfonate, nitro, nitroso, quaternary amine, pyridinyl (or pyridinyl wherein the nitrogen atom is functionalized with an aliphatic or aryl group), alkyl halide, or any combinations thereof.

In other embodiments, when at least one of X or Y═—[C(R¹)₂]ₘ—C(R²)₃ or R is a hydrogen and m is 1, the alcohol can be a C₃ alcohol. For instance, if at least one R¹ and one R² is absent, then the C₃ alcohol can be a C₃ alkenol (e.g., allyl alcohol). In another instance, R and one R² together can form a ring(such as, cycloaliphatic), then the C₃ alcohol can be a cyclopropanol or 2-cyclopropenol.

In yet other embodiments, when at least one of X or Y=—[C(R¹)₂]ₘ—C(R²)₃ or R is a hydrogen and m is 2, the alcohol can be a C₄ alcohol. For instance, if at least one R¹ and one R² is absent, then the C₄ alcohol can be a C₄ alkenol (e.g., 2-buten-1-ol or 3-buten-1-ol). In another instance, R and one R² together can form a ring (such as, cycloaliphatic), then the C₄ alcohol can be a C₄-cyclic alcohol (e.g., cyclobutanol or a cyclopropylmethanol). In yet another instance, if both X and Y are not OH, then the C₄ alcohol can be a C₄-branched alcohol (e.g., 2-butanol, isobutanol, or tert-butanol).

In some instances, when X═OH and Y═—[C(R¹)₂]ₘ—C(R²)₃, the alcohol can be a diol. In other instances, when at least one X or Y═—[C(R¹)₂]ₘ—C(R²)₃ and at least one R¹═OH or one R²═OH, or when R═OH, the alcohol can be a diol. Example diols include, but are not limited to, 1,4-butane diol, propylene-1,3-diol, and the like.

In other instances, when X═Y═OH, the alcohol can be a triol. In yet other instances, when X═R═OH, the alcohol can be a triol. In some instances, when at least one of X or Y is —[C(R¹)₂]ₘ—C(R²)₃ and one R¹ and at least one R² is OH, the alcohol can be triol. In other instances, when R═OH and X═—[C(R¹)₂]ₘ—C(R²)₃ and one R¹ and at least one R² is OH, the alcohol can be triol. Example triols include, but are not limited to, glycerol or glycerine derivatives thereof.

In particular embodiments, when R═cycloheteroaliphatic, heterocyclyl, heteroaryl, alkyl-heterocyclyl, alkenyl-heterocyclyl, alkynyl-heterocyclyl, heteroalkyl-heterocyclyl, heteroalkenyl-heterocyclyl, or heteroalkynyl-heterocyclyl, the alcohol can be a heterocyclyl alcohol (e.g., an optionally substituted heterocyclyl substituted with or more hydroxyls, such as furfuryl alcohol). In other embodiments, when at least one of X or Y is —[C(R¹)₂]ₘ—C(R²)₃ and one R¹ and at least one R² is cycloheteroaliphatic, heterocyclyl, heteroaryl, alkyl-heterocyclyl, alkenyl-heterocyclyl, alkynyl-heterocyclyl, heteroalkyl-heterocyclyl, heteroalkenyl-heterocyclyl, or heteroalkynyl-heterocyclyl, the alcohol can be a heterocyclyl alcohol.

In various embodiments, the alcohol may have between 1-10 carbon atoms. The alcohol may be a primary alcohol, a secondary alcohol, or a tertiary alcohol. In some cases, the alcohol may be selected from the group consisting of: methanol, ethanol, 1-propanol, 2-propanol, 1-butanol, 2-butanol, t-butanol, 1-pentanol, 1-hexanol, 1-heptanol, 1-octanol, 1-nonanol, 1-decanol, and combinations thereof.

### Laboratory Solvents:

In these or other cases, the organic solvent may include a laboratory-type solvent such as acetonitrile, dichloromethane, carbon tetrachloride, or a combination thereof.

### Ketones:

In some embodiments, the organic solvent may be a ketone.

The organic solvent can also be a ketone having a formula of X—[C(O)]ₙ—Y, where:
n is an integer from 1 to 2;
each X and Y can be independently selected from-C(R¹)₃, —R², or —[C(R³)2]ₘ—C(O)—R⁴, wherein each R¹, R², R³ and R⁴ can be independently selected from hydrogen, hydroxyl, aliphatic, haloaliphatic, haloheteroaliphatic, heteroaliphatic, aromatic, aliphatic-aromatic, heteroaliphatic-aromatic, or any combinations thereof;
in which R³ and R⁴, taken together with the atom to which each are attached, can optionally form a cycloaliphatic or cycloheteroaliphatic, and in which X and Y, taken together with the atom to which each are attached, can optionally form a cycloaliphatic or cycloheteroaliphatic; and
m is an integer from 0 to 10.

In some embodiments, each R¹, R², R³ and R⁴, independently, are alkyl, alkenyl, alkynyl, heteroalkyl, heteroalkenyl, heteroalkynyl, haloalkyl, haloalkenyl, haloalkynyl, haloheteroalkyl, haloheteroalkenyl, haloheteroalkynyl, aryl, heterocyclyl, heteroaryl, alkyl-aryl, alkenyl-aryl, alkynyl-aryl, alkyl-heterocyclyl, alkenyl-heterocyclyl, alkynyl-heterocyclyl, alkyl-heteroaryl, alkenyl-heteroaryl, alkynyl-heteroaryl, heteroalkyl-aryl, heteroalkenyl-aryl, heteroalkynyl-aryl, heteroalkyl-heterocyclyl, heteroalkenyl-heterocyclyl, heteroalkynyl-heterocyclyl, heteroalkyl-heteroaryl, heteroalkenyl-heteroaryl, heteroalkynyl-heteroaryl, or any combinations thereof. In particular disclosed embodiments, the organic solvent may further be substituted with one or more substituents, such as aldehyde (—C(O)H), oxo (═O), alkoxy, amide, amine, hydroxyl, thioether, thiol, acyloxy, silyl, cycloaliphatic, aryl, aldehyde, ketone, ester, carboxylic acid, acyl, acyl halide, cyano, halogen, sulfonate, nitro, nitroso, quaternary amine, pyridinyl (or pyridinyl wherein the nitrogen atom is functionalized with an aliphatic or aryl group), alkyl halide, or any combinations thereof. One example ketone is acetone.

In some embodiments, when X and Y, taken together with the atom to which each are attached, forms a cycloaliphatic or cycloheteroaliphatic, the organic solvent can be a cyclic ketone. Example cyclic ketones include cyclohexanone, cyclopentanone, and the like.

In other embodiments, when at least one of X or Y═—[C(R³)₂]ₘ—C(O)—R⁴, the organic solvent can be a diketone. Example diketones include diacetyl, 2,3-pentanedione, 2,3-hexanedione, 3,4-hexanedione, acetylacetone, acetonylacetone, and the like, as well as halogenated forms thereof, such as hexafluoroacetylacetone.

In further embodiments, when at least one of X or Y═—[C(R³)₂]ₘ—C(O)—R⁴ and X and Y, taken together with the atom to which each are attached, forms a cycloaliphatic or cycloheteroaliphatic, the organic solvent can be a cyclic diketone. Example cyclic diketones include dimedone, 1,3-cyclohexanedione, and the like.

In some instances, when X═—CH₃, the organic solvent can have Y═—C(R¹)₃, in which at least one R¹ is C₂₋₁₀ hydroxyl, aliphatic, haloaliphatic, haloheteroaliphatic, heteroaliphatic, aromatic, aliphatic-aromatic, heteroaliphatic-aromatic, or any combinations thereof. Example materials can include methyl propyl ketone, methyl butyl ketone, hydroxyacetone, and the like.

In other instances, when X═—CH₃, the organic solvent can have Y═—R², in which at least one R² is C₂ alkenyl, C₃₋₁₀ aliphatic, haloaliphatic, haloheteroaliphatic, heteroaliphatic, aromatic, aliphatic-aromatic, heteroaliphatic-aromatic, or any combinations thereof. Example materials can include methyl vinyl ketone, methyl propyl ketone, methyl butyl ketone, and the like.

In yet other instances, when at least one of X or Y═aromatic, or aliphatic-aromatic, or heteroaliphatic-aromatic, the organic solvent can be an aromatic ketone. Example materials include acetophenone, benzophenone, benzylacetone, 1,3-diphenylacetone, cyclopentyl phenyl ketone, and the like.

In certain embodiments where the organic solvent includes a ketone, the ketone may be selected from acetone and acetophenone. One or more additional ketones and/or other organic solvents described herein may be provided, as well.

### Alkanes:

In some embodiments, the organic solvent may be an alkane. In certain embodiments, the alkane may be an acyclic branched or unbranched hydrocarbon having the general formula CₙH₂ₙ₊₂. Example acyclic alkanes include, but are not limited to, pentane, hexane, octane, and combinations thereof. In certain other embodiments, the alkane may be a cyclic hydrocarbon. Example cyclic hydrocarbons include, but are not limited to, cyclopentane, cyclohexane, and combinations thereof.

### Aromatic Solvents:

In some embodiments, the organic solvent may be an aromatic solvent. As used herein, “aromatic” means a cyclic, conjugated group or moiety of, unless specified otherwise, from 5 to 15 ring atoms having a single ring (e.g., phenyl) or multiple condensed rings in which at least one ring is aromatic (e.g., naphthyl, indolyl, or pyrazolopyridinyl); that is, at least one ring, and optionally multiple condensed rings, have a continuous, delocalized π-electron system. Typically, the number of out of plane 7-electrons corresponds to the Hückel rule (4n+2). The point of attachment to the parent structure typically is through an aromatic portion of the condensed ring system. In some cases, an aromatic solvent may be selected from toluene and benzene.

### Ethers:

In some embodiments, the organic solvent may be an ether having a formula of X—O—Y or X—O—[C(R)₂]ₙ—O—Y, where:
n is an integer from 1 to 4;
each X and Y can be independently selected from —[C(R¹)₂]ₘ—C(R²)₃ or —R³ or —[C(R⁴)₂]ₚ—O—[C(R⁵)₂]ₘ—C(R⁶)₃, wherein each of R¹, R², R³, R⁴, R⁵, R⁶ and R is independently selected from hydrogen, hydroxyl, aliphatic, haloaliphatic, haloheteroaliphatic, heteroaliphatic, aromatic, aliphatic-aromatic, heteroaliphatic-aromatic, or any combinations thereof, and wherein m is an integer from 0 to 10 and p is an integer from 1 to 10;
in which X and Y, taken together with the atom to which each are attached, can optionally form a cycloheteroaliphatic group.

In some embodiments, each R, R¹, R², R³, R⁴, R⁵ and R⁶ independently are selected from alkyl, alkenyl, alkynyl, heteroalkyl, heteroalkenyl, heteroalkynyl, haloalkyl, haloalkenyl, haloalkynyl, haloheteroalkyl, haloheteroalkenyl, haloheteroalkynyl, aryl, heterocyclyl, heteroaryl, alkyl-aryl, alkenyl-aryl, alkynyl-aryl, alkyl-heterocyclyl, alkenyl-heterocyclyl, alkynyl-heterocyclyl, alkyl-heteroaryl, alkenyl-heteroaryl, alkynyl-heteroaryl, heteroalkyl-aryl, heteroalkenyl-aryl, heteroalkynyl-aryl, heteroalkyl-heterocyclyl, heteroalkenyl-heterocyclyl, heteroalkynyl-heterocyclyl, heteroalkyl-heteroaryl, heteroalkenyl-heteroaryl, heteroalkynyl-heteroaryl, or any combinations thereof. In particular disclosed embodiments, the ether may further be substituted with one or more substituents, such as alkoxy, amide, amine, thioether, thiol, acyloxy, silyl, cycloaliphatic, aryl, aldehyde, ketone, ester, carboxylic acid, acyl, acyl halide, cyano, halogen, sulfonate, nitro, nitroso, quaternary amine, pyridinyl (or pyridinyl wherein the nitrogen atom is functionalized with an aliphatic or aryl group), alkyl halide, or any combinations thereof.

In some embodiments, when X and Y are taken together with the atom to which each are attached in order form a cycloheteroaliphatic group, the organic solvent is a cyclic ether, such as, acetal, dioxane, dioxolane, etc. In some embodiments, when n=1 and each R═H, X and Y taken together form a six, seven, eight, nine, or ten-membered ring. Example ethers include, but are not limited to, 1,3-dioxolane, or derivatives thereof. In other embodiments, when n=2 and R═H, X and Y form a seven, eight, nine, or ten-membered ring. Example ethers include, but are not limited to, 1,4-dioxane, or derivatives thereof. In yet other embodiments, when n=1 or n=2, then R is aliphatic, haloaliphatic, haloheteroaliphatic, heteroaliphatic, aromatic, aliphatic-aromatic, heteroaliphatic-aromatic, or any combinations thereof. Example cyclic ethers include tetrahydrofuran, 2-methyltetrahydrofuran, 2-methyl-1,3-dioxolane, and the like.

In other embodiments, when at least one of X or Y=aromatic, the organic solvent can be an aromatic ether. Example aromatic ethers include anisole, diphenyl ether, and the like.

In some embodiments, when at least one of X or Y=cycloaliphatic, the organic solvent can be a cycloalkyl ether. Example cycloalkyl ethers include cyclopentyl methyl ether, cyclohexyl methyl ether, and the like.

In other embodiments, when at least one of X or Y═—[C(R⁴)₂—O]ₚ—C(R⁶)₃, the organic solvent can be a glycol based ether. Example glycol based ethers include diethylene glycol diethyl ether, dipropylene glycol dimethyl ether, poly(ethylene glycol) dimethyl ether, etc., including methyl, ethyl, propyl, and butyl mono- and di-ethers of ethylene glycol, and the like.

### Nitriles:

In some cases, the organic solvent is a nitrile having a formula R—C≡N, where R is aliphatic, haloaliphatic, haloheteroaliphatic, heteroaliphatic, aromatic, aliphatic-aromatic, or heteroaliphatic-aromatic.

In certain embodiments, R can be optionally substituted with a hydroxyl group (e.g., in one example R can be CH₃—CH(OH)—CH₂—, and the organic solvent will be CH₃—CH(OH)—CH₂—CN).

One example nitrile is acetonitrile, mentioned above.

In some embodiments, the organic solvent may include two or more of the organic solvents or types of organic solvents described herein. In some embodiments, water may be provided instead of, or in addition to, the organic solvent.

### Carrier Gas

The carrier gas may be an inert gas. In some cases the carrier gas is a noble gas. In certain embodiments, the carrier gas may be selected from the group consisting of N₂, He, Ne, Ar, Kr, and Xe. In some such embodiments, the carrier gas may be selected from the group consisting of N₂, He, and Ar.

### Additive

The additive may be selected from a number of different types of additives. For instance, in some cases the additive may be a heterocycle compound, a heterocyclic aromatic compound, a halogen-substituted heterocyclic aromatic compound, a heterocyclic aliphatic compound, an amine, a fluoroamine, an amino acid, an organophosphorus compound, an oxidizer, a bifluoride source, ammonia, an aldehyde, a carbene, an organic acid, and/or a hydrogen fluoride complex forming chemical. In some cases, more than one additive may be used. In some embodiments, the additive may be a boron-containing Lewis acid or Lewis adduct. Boron trifluoride (BF₃) is an example of a Lewis acid that forms the acid-base adduct BF₄⁻. In some cases, the additive may fall into two or more of the categories listed above. In various embodiments, the additive serves the purposes of accelerating the reaction rate and enhancing the reaction selectivity.

### Heterocyclic Aromatic Compounds:

In certain embodiments, the additive is a heterocyclic aromatic compound. The term “aromatic” is defined above. A heterocyclic aromatic compound is an aromatic compound that includes a 5-, 6- or 7-membered ring, unless otherwise specified, containing one, two, three, or four non-carbon heteroatoms (e.g., independently selected from the group consisting of nitrogen, oxygen, phosphorous, sulfur, or halo). Example heterocyclic aromatic compounds that may be used include, but are not limited to, picoline, pyridine, pyrrole, imidazole, thiophene, N-methylimidazole, N-methylpyrrolidone, benzimidazole, 2,2-bipyridine, dipicolonic acid, 2,6-lutidine, 4-N,N-dimethylaminopyridine, and azulene. In some cases, a heterocyclic aromatic compound may be methylated. In some cases, a heterocyclic aromatic compound may follow the Hückel 4n+2 rule. In some cases, the additive is a halogen-substituted aromatic compound. A halogen-substituted aromatic compound is an aromatic compound that includes at least one halogen bonded to the aromatic ring. As used herein, halogen or halo refers to F, Cl, Br, or I. Example halogen-substituted aromatic compounds include, but are not limited to, 4-bromopyridine, chlorobenzene, 4-chlorotoluene, fluorobenzene, etc.

### Heterocyclic Aliphatic Compounds:

In some embodiments, the additive is a heterocyclic aliphatic compound. As used herein, “aliphatic” means a hydrocarbon group having at least one carbon atom to 50 carbon atoms (C₁₋₅₀), such as one to 25 carbon atoms (C₁₋₂₅), or one to ten carbon atoms (C₁₋₁₀), and which includes alkanes (or alkyl), alkenes (or alkenyl), alkynes (or alkynyl), including cyclic versions thereof, and further including straight- and branched-chain arrangements, and all stereo and position isomers as well. A heterocyclic aliphatic compound is an aliphatic compound that includes a 5-, 6- or 7-membered ring, unless otherwise specified, containing one, two, three, or four non-carbon heteroatoms (e.g., independently selected from the group consisting of nitrogen, oxygen, phosphorous, sulfur, or halo). Example heterocyclic aliphatic compounds include pyrrolidine, piperidine, etc.

### Amines:

In some embodiments, the additive is an amine having a formula of NR¹R²R³, where:
each of R¹, R², and R³ is independently selected from hydrogen, hydroxyl, aliphatic, haloaliphatic, haloheteroaliphatic, heteroaliphatic, aromatic, aliphatic-aromatic, heteroaliphatic-aromatic, or any combinations thereof;
in which R and R², taken together with the atom to which each are attached, can optionally form a cycloheteroaliphatic; and
in which R¹, R², and R³, taken together with the atom to which each are attached, can optionally form a cycloheteroaliphatic.

In some embodiments, each of R¹, R², and R³ is independently selected from alkyl, alkenyl, alkynyl, heteroalkyl, heteroalkenyl, heteroalkynyl, haloalkyl, haloalkenyl, haloalkynyl, haloheteroalkyl, haloheteroalkenyl, haloheteroalkynyl, aryl, heterocyclyl, heteroaryl, alkyl-aryl, alkenyl-aryl, alkynyl-aryl, alkyl-heterocyclyl, alkenyl-heterocyclyl, alkynyl-heterocyclyl, alkyl-heteroaryl, alkenyl-heteroaryl, alkynyl-heteroaryl, heteroalkyl-aryl, heteroalkenyl-aryl, heteroalkynyl-aryl, heteroalkyl-heterocyclyl, heteroalkenyl-heterocyclyl, heteroalkynyl-heterocyclyl, heteroalkyl-heteroaryl, heteroalkenyl-heteroaryl, heteroalkynyl-heteroaryl, or any combinations thereof. In particular disclosed embodiments, the amine may further be substituted with one or more substituents, such as alkoxy, amide, amine, hydroxyl, thioether, thiol, acyloxy, silyl, cycloaliphatic, aryl, aldehyde, ketone, ester, carboxylic acid, acyl, acyl halide, cyano, halogen, sulfonate, nitro, nitroso, quaternary amine, pyridinyl (or pyridinyl wherein the nitrogen atom is functionalized with an aliphatic or aryl group), alkyl halide, or any combinations thereof.

In some embodiments, when at least one of R¹, R², and R³ is aliphatic, haloaliphatic, haloheteroaliphatic, or heteroaliphatic, the additive is an alkyl amine. The alkyl amine can include dialkylamines, trialkyl amines, and derivatives thereof. Example alkyl amines include dimethylisopropylamine, N-ethyldiisopropylamine, trimethylamine, dimethylamine, methylamine, triethylamine, t-butyl amine, and the like.

In other embodiments, when at least one of R¹, R², and R³ includes a hydroxyl, the additive is an alcohol amine. In one instance, at least one of R¹, R², and R³ is an aliphatic group substituted with one or more hydroxyls. Example alcohol amines include 2-(dimethylamino)ethanol, 2-(diethylamino)ethanol, 2-(dipropylamino)ethanol, 2-(dibutylamino)ethanol, N-ethyldiethanolamine, N-tertbutyldiethanolamine, and the like.

In some embodiments, when R¹ and R², taken together with the atom to which each are attached, form a cycloheteroaliphatic, the additive can be a cyclic amine. Example cyclic amines include piperidine, N-alkyl piperidine (e.g., N-methyl piperidine, N-propyl piperidine, etc.), pyrrolidine, N-alkyl pyrrolidine (e.g., N-methyl pyrrolidine, N-propyl pyrrolidine, etc.), morpholine, N-alkyl morpholine (e.g., N-methyl morpholine, N-propyl morpholine, etc.), piperazine, N-alkyl piperazine, N,N-dialkyl piperazine (e.g., 1,4-dimethylpiperazine), and the like.

In other embodiments, when at least one of R¹, R², and R³ includes an aromatic, the additive is an aromatic amine. In some embodiments, at least one of R¹, R², and R³ is aromatic, aliphatic-aromatic, or heteroaliphatic-aromatic. In other embodiments, both R¹ and R² includes an aromatic. In yet other embodiments, R¹ and R² and optionally R³, taken together with the atom to which each are attached, from a cycloheteroaliphatic that is an aromatic. Example aromatic amines include aniline, histamine, pyrrole, pyridine, imidazole, pyrimidine, and the derivatives thereof.

In some embodiments, the additive may include an amine selected from the group consisting of: methylamine, dimethylamine, trimethylamine, ethylamine, diethylamine, triethylamine, isopropylamine, 1,2-ethylenediamine, aniline (and aniline derivatives such as N, Ndimethylaniline), N-ethyldiisopropylamine, tert-butylamine, and combinations thereof.

In some embodiments, the additive may include a fluoramine. A fluoramine is an amine having one or more fluorinated substituents. Example fluoroamines that may be used include, but are not limited to, 4-trifluoromethylaniline.

In some embodiments, the additive can be a nitrogenous analogue of a carbonic acid, having a formula R₁N—C(NR²)—NR³. Example additives can include, but are not limited to, guanidine or derivatives thereof.

In some embodiments, the additive may be a relatively low molecular weight amine, e.g., having a molecular weight of less than 200 g/mol or 100 g/mol in certain embodiments. Higher molecular weight amines, including those having long chains and/or heterocyclic compounds with aromatic rings, may be used in some embodiments.

### Amino Acids:

In some embodiments, the additive may include an amino acid. The amino acid may have a formula of R—CH(NR′₂)—COOH, where:
each R and R′ independently are hydroxyl, aliphatic, haloaliphatic, haloheteroaliphatic, heteroaliphatic, aromatic, aliphatic-aromatic, heteroaliphatic-aromatic, or any combination thereof.

Example amino acids that may be used include, but are not limited to, histidine, alanine, and derivatives thereof.

### Organophosphorus Compounds:

In some embodiments, the additive may include an organophosphorus compound. The organophosphorus compound may be a phosphate ester, a phosphate amide, a phosphonic acid, a phosphinic acid, a phosphonate, a phosphinate, a phosphine oxide, a phosphine imide, or a phosphonium salt. Example organophosphorus compounds include phosphoric acid and trialkylphosphate. In some cases, the organophosphorous compound is a phosphazene. A phosphazene is an organophosphorus compound that includes phosphorus (V) with a double bond between P and N. The phosphazene may have a formula of RN═P(NR₂)₃ (where each of R and R² are independently selected from hydroxyl, aliphatic, haloaliphatic, haloheteroaliphatic, heteroaliphatic, aromatic, aliphatic-aromatic, heteroaliphatic-aromatic, or any combination thereof). In some cases, the phosphazene may have a formula of [X₂PN]ₙ (where X is a halide, alkoxide, or amide). Other types of phosphazenes may be used as desired.

### Oxidizers:

In some embodiments, the additive includes an oxidizer. As used herein, an oxidizer is a material that has the ability to oxidize (e.g., accept electrons from) another substance. Example oxidizers that may be used include, but are not limited to, hydrogen peroxide, sodium hypochlorate, and tetramethyl ammonium hydroxide.

### Bifluoride Sources:

In some embodiments, the additive includes a bifluoride source. A bifluoride source is a material that includes or produces bifluoride (HF₂⁻). Example bifluoride sources that may be used include, but are not limited to, ammonium fluoride, aqueous HF, gaseous HF, buffered oxide etch mixture (e.g., a mixture of HF and a buffering agent such as ammonium fluoride), and hydrogen fluoride pyridine. In some embodiments, the bifluoride source (and/or one or more of the other additives listed herein) may react to form HF₂⁻ before or after delivery to the reaction chamber.

### Aldehydes:

In some embodiments, the additive includes an aldehyde having a formula of X—[C(O)]—H, where:
X can be selected from hydrogen, —R¹, —C(R²)₃ or —[C(R³)₂]ₘ—C(O)H, wherein each R¹, R² and R³ independently are selected from hydrogen, aliphatic, haloaliphatic, haloheteroaliphatic, heteroaliphatic, aromatic, aliphatic-aromatic, heteroaliphatic-aromatic, or any combinations thereof, and m is an integer from 0 to 10.

In some embodiments, each of R¹, R², and R³ is, independently, alkyl, alkenyl, alkynyl, heteroalkyl, heteroalkenyl, heteroalkynyl, haloalkyl, haloalkenyl, haloalkynyl, haloheteroalkyl, haloheteroalkenyl, haloheteroalkynyl, aryl, heterocyclyl, heteroaryl, alkyl-aryl, alkenyl-aryl, alkynyl-aryl, alkyl-heterocyclyl, alkenyl-heterocyclyl, alkynyl-heterocyclyl, alkyl-heteroaryl, alkenyl-heteroaryl, alkynyl-heteroaryl, heteroalkyl-aryl, heteroalkenyl-aryl, heteroalkynyl-aryl, heteroalkyl-heterocyclyl, heteroalkenyl-heterocyclyl, heteroalkynyl-heterocyclyl, heteroalkyl-heteroaryl, heteroalkenyl-heteroaryl, heteroalkynyl-heteroaryl, or any combinations thereof. In particular disclosed embodiments, the aldehyde or ketone may further be substituted with one or more substituents, such as aldehyde (—C(O)H), oxo (═O), alkoxy, amide, amine, hydroxyl, thioether, thiol, acyloxy, silyl, cycloaliphatic, aryl, aldehyde, ketone, ester, carboxylic acid, acyl, acyl halide, cyano, halogen, sulfonate, nitro, nitroso, quaternary amine, pyridinyl (or pyridinyl wherein the nitrogen atom is functionalized with an aliphatic or aryl group), alkyl halide, or any combinations thereof.

In some embodiments, when X═aromatic, the additive can be an aromatic aldehyde. Example aromatic aldehydes include benzaldehyde, 1-naphthaldehyde, phthalaldehyde, and the like.

In other embodiments, when X═aliphatic, the additive can be an aliphatic aldehyde. Example aliphatic aldehydes include acetaldehyde, propionaldehyde, butyraldehyde, isovalerylaldehyde, and the like.

In yet other embodiments, when X═—[C(R³)₂]ₘ—C(O)H and m is 0 to 10 or when X═aliphatic or heteroaliphatic substituted with —C(O)H, the additive can be a dialdehyde. Example dialdehydes include glyoxal, phthalaldehyde, glutaraldehyde, malondialdehyde, succinaldehyde, and the like.

In some examples, an aldehyde used as an additive may be selected from the group consisting of: acrolein, acetaldehyde, formaldehyde, benzaldehyde, propionaldehyde, butyraldehyde, cinnamaldehyde, vanillin, and tolualdehyde. In these or other cases, an aldehyde used as an additive may be selected from the aldehydes discussed in this section and the aldehydes discussed in the organic solvent section.

### Carbenes:

In some embodiments, the additive includes a carbene. The carbene may have a formula of X—(C:)—Y, where:
each of X and Y can be independently selected from H, halo, —[C(R¹)₂]ₘ—C(R²)₃, —C(O)—R¹, or —C(═NR¹)—R², —NR¹R², —OR², —SR², or —C(R²)₃, wherein each of R¹ and R² is independently selected from hydrogen, hydroxyl, aliphatic, haloaliphatic, haloheteroaliphatic, heteroaliphatic, aromatic, aliphatic-aromatic, heteroaliphatic-aromatic, or any combinations thereof, and wherein m is an integer from 0 to 10;
in which R¹ and R², taken together with the atom to which each are attached, can optionally form a cycloheteroaliphatic group; and
in which X and Y, taken together with the atom to which each are attached, can optionally form a cycloaliphatic or cycloheteroaliphatic group.

Furthermore, the additive can be a carbenium cation having a formula R¹—C⁺(R)—R², wherein each of R, R¹, and R² is independently selected from hydrogen, aliphatic, haloaliphatic, haloheteroaliphatic, heteroaliphatic, aromatic, aliphatic-aromatic, heteroaliphatic-aromatic, or any combinations thereof.

In some embodiments, each R, R¹, and R² independently is selected from alkyl, alkenyl, alkynyl, heteroalkyl, heteroalkenyl, heteroalkynyl, haloalkyl, haloalkenyl, haloalkynyl, haloheteroalkyl, haloheteroalkenyl, haloheteroalkynyl, aryl, heterocyclyl, heteroaryl, alkyl-aryl, alkenyl-aryl, alkynyl-aryl, alkyl-heterocyclyl, alkenyl-heterocyclyl, alkynyl-heterocyclyl, alkyl-heteroaryl, alkenyl-heteroaryl, alkynyl-heteroaryl, heteroalkyl-aryl, heteroalkenyl-aryl, heteroalkynyl-aryl, heteroalkyl-heterocyclyl, heteroalkenyl-heterocyclyl, heteroalkynyl-heterocyclyl, heteroalkyl-heteroaryl, heteroalkenyl-heteroaryl, heteroalkynyl-heteroaryl, or any combinations thereof. In particular disclosed embodiments, the carbene may further be substituted with one or more substituents, such as alkoxy, amide, amine, hydroxyl, thioether, thiol, acyloxy, silyl, cycloaliphatic, aryl, aldehyde, ketone, ester, carboxylic acid, acyl, acyl halide, cyano, halogen, sulfonate, nitro, nitroso, quaternary amine, pyridinyl (or pyridinyl wherein the nitrogen atom is functionalized with an aliphatic or aryl group), alkyl halide, or any combinations thereof. In any embodiment of a carbene, each of R¹ and R² can be independently selected.

In some embodiments, when at least one of X or Y is halo, the additive can be a halocarbene. Example, non-limiting halocarbenes include dihalocarbene, such as dichlorocarbene, difluorocarbene, and the like.

In some embodiments, when both X═Y═—NR¹R², the additive can be a diaminocarbene. In one instance, each of R¹ and R² is independently aliphatic. Example diaminocarbenes include bis(diisopropylamino) carbene, and the like.

In other embodiments, when both at least one of X or Y═—NR¹R² and both R¹ and R² within X or within Y are taken together, with the nitrogen atom to which each are attached, to form a cycloheteroaliphatic group, the additive can be a cyclic diaminocarbene. Example cyclic diamino carbenes include bis(N-piperidyl) carbene, bis(N-pyrrolidinyl) carbene, and the like.

In one instance, when both X═Y═—NR¹R² and an R¹ group from X and an R² group from Y are taken together, with the nitrogen atom to which each are attached, to form a cycloheteroaliphatic group, the additive is an N-heterocyclic carbene. Example N-heterocyclic carbenes include imidazol-2-ylidenes (e.g., 1,3-dimesitylimidazol-2-ylidene, 1,3-dimesityl-4,5-dichloroimidazol-2-ylidene, 1,3-bis(2,6-diisopropylphenyl)imidazol-2-ylidene, 1,3-di-tert-butylimidazol-2-ylidene, etc.), imidazolidin-2-ylidenes (e.g., 1,3-bis(2,6-diisopropylphenyl)imidazolidin-2-ylidene), triazol-5-ylidenes (e.g., 1,3,4-triphenyl-4,5-dihydro-1H-1,2,4-triazol-5-ylidene), and the like.

In some embodiments, when X═—NR¹R² and Y═—SR² and an R¹ group from X and an R² group from Y are taken together, with the nitrogen atom to which each are attached, to form a cycloheteroaliphatic group, the additive is acyclic thioalkyl amino carbene. Example cyclic thioalkyl amino carbenes include thiazol-2-ylidenes (e.g., 3-(2,6-diisopropylphenyl)thiazol-2-ylidene and the like).

In some embodiments, when X═—NR¹R² and Y═—C(R²)₃ and an R¹ group from X and an R² group from Y are taken together, with the atom to which each are attached, to form a cycloheteroaliphatic group, the additive is an cyclic alkyl amino carbene. Example cyclic alkyl amino carbenes include pyrrolidine-2-ylidenes (e.g., 1,3,3,5,5-pentamethyl-pyrrolidin-2-ylidene and the like) and piperidin-2-ylidenes (e.g., 1,3,3,6,6-pentamethyl-piperidin-2-ylidene and the like).

Further example carbenes and derivatives thereof include compounds having a thiazol-2-ylidene moiety, a dihydroimidazol-2-ylidene moiety, an imidazol-2-ylidene moiety, a triazol-5-ylidene moiety, or a cyclopropenylidene moiety. Yet other carbenes and carbene analogs include an aminothiocarbene compound, an aminooxycarbene compound, a diaminocarbene compound, a heteroamino carbene compound, a 1,3-dithiolium carbene compound, a mesoionic carbene compound (e.g., an imidazolin-4-ylidene compound, a 1,2,3-triazolylidene compound, a pyrazolinylidene compound, a tetrazol-5-ylidene compound, an isoxazol-4-ylidene compound, a thiazol-5-ylidene compound, etc.), a cyclic alkyl amino carbene compound, a boranylidene compound, a silylene compound, a stannylene compound, a nitrene compound, a phosphinidene compound, a foiled carbene compound, etc. Further example carbenes include dimethyl imidazol-2-ylidene, 1,3-bis(2,4,6-trimethylphenyl)-4,5-dihydroimidazol-2-ylidene, (phosphanyl)(trifluoromethyl)carbene, bis(diisopropylamino) carbene, bis(diisopropylamino) cyclopropenylidene, 1,3-dimesityl-4,5-dichloroimidazol-2-ylidene, 1,3-diadamantylimidazol-2-ylidene, 1,3,4,5-tetramethylimidazol-2-ylidene, 1,3-dimesitylimidazol-2-ylidene, 1,3-dimesitylimidazol-2-ylidene, 1,3,5-triphenyltriazol-5-ylidene, bis(diisopropylamino) cyclopropenylidene, bis(9-anthryl)carbene, norbomen-7-ylidene, dihydroimidazol-2-ylidene, methylidenecarbene, etc.

### Organic Acids:

In some embodiments, the additive includes an organic acid. The organic acid may have a formula of R—CO₂H, wherein R is selected from hydrogen, aliphatic, haloaliphatic, haloheteroaliphatic, heteroaliphatic, aromatic, aliphatic-aromatic, heteroaliphatic-aromatic or any combinations thereof. In certain embodiments, R is alkyl, alkenyl, alkynyl, heteroalkyl, heteroalkenyl, heteroalkynyl, haloalkyl, haloalkenyl, haloalkynyl, haloheteroalkyl, haloheteroalkenyl, haloheteroalkynyl, aryl, heteroaryl, alkyl-aryl, alkenyl-aryl, alkynyl-aryl, alkyl-heteroaryl, alkenyl-heteroaryl, alkynyl-heteroaryl, heteroalkyl-aryl, heteroalkenyl-aryl, heteroalkynyl-aryl, heteroalkyl-heteroaryl, heteroalkenyl-heteroaryl, heteroalkynyl-heteroaryl or any combinations thereof. In particular disclosed embodiments, R may further be substituted with one or more substituents such as, alkoxy, amide, amine, thioether, hydroxyl, thiol, acyloxy, silyl, cycloaliphatic, aryl, aldehyde, ketone, ester, carboxylic acid, acyl, acyl halide, cyano, halogen, sulfonate, nitro, nitroso, quaternary amine, pyridinyl (or pyridinyl wherein the nitrogen atom is functionalized with an aliphatic or aryl group), alkyl halide or any combinations thereof. In certain implementations, the organic acid may be selected from formic acid and acetic acid.

### Hydrogen Fluoride Complex Forming Chemicals

In some embodiments, the additive includes a chemical that forms a complex with hydrogen fluoride. Such chemicals are referred to herein as hydrogen fluoride complex forming chemicals. The complex that is formed may act to increase the rate at which the target material is etched from the substrate, while maintaining a high degree of selectivity.

In various embodiments herein, a hydrogen fluoride complex forming chemical may be provided in combination with hydrogen fluoride. In such embodiments, the additive includes the hydrogen fluoride complex forming chemical, and the halogen source includes the hydrogen fluoride. These may be combined with any of the organic solvents and/or water, and any of the carrier gases described herein. In a related embodiment, a hydrogen fluoride complex forming chemical may be used in combination with a halogen source other than hydrogen fluoride.

Hydrogen fluoride complex forming chemicals may have a variety of different formulas and/or properties. For instance, in various implementations a hydrogen fluoride complex forming chemical may be or include one or more amine group, urea group, phosphine group, alkyl group, imidazole group, heterocyclic aliphatic group, heterocyclic aromatic group, ether group, etc. In various embodiments, a hydrogen fluoride complex forming chemical may include two or more particular groups, for example two or more alkyl groups, three or more alkyl groups, or four or more alkyl groups. This also applies to the other types of groups listed above. A number of additives include more than one kind of group (e.g., an imidazole group and one or more alkyl group, etc.). Such groups may be combined in various ways, including but not limited to the particular examples provided below.

Examples of hydrogen fluoride complex forming chemicals that may be used as an additive include, but are not limited to, cyclic urea or other urea-containing compounds such as 1,3-dimethyl-3,4,5,6-tetrahydro-2(1H)-pyrimidinone (also referred to as N,N′-dimethylpropylene urea or DMPU); alkyl-substituted ammonium compounds such as tetraethylammonium and tetrabutylammonium; heterocyclic aromatic amine-containing compounds such as melamine; heterocyclic aliphatic compounds or cyclic ether compounds such as tetrahydrofuran; alkyl-substituted imidazole compounds such as dialkylimidazolium; alkyl-substituted ether compounds such as dimethyl ether; alkyl-substituted phosphine compounds such as trialkylphosphine; and combinations thereof. Various compounds may form complexes with HF in a similar manner, and may be used in the same or similar way.

Other examples of additives that may act as hydrogen fluoride complex forming chemicals include, but are not limited to, pyridine and triethylamine. These may be used in some embodiments. In other embodiments, the hydrogen fluoride complex forming chemical may exclude pyridine and/or triethylamine.

### Substitutions:

Any of the example materials described herein include unsubstituted and/or substituted forms of the compound. Non-limiting example substituents include, e.g., one, two, three, four, or more substituents independently selected from the group consisting of: (1) C₁₋₆ alkoxy (e.g., —O—R, in which R is C₁₋₆ alkyl); (2) C₁₋₆ alkylsulfinyl (e.g., —S(O)—R, in which R is C₁₋₆ alkyl); (3) C₁₋₆ alkylsulfonyl (e.g., —SO₂—R, in which R is C₁₋₆ alkyl); (4) amine (e.g., —C(O)NR¹R² or —NHCOR¹, where each of R¹ and R² is, independently, selected from hydrogen, aliphatic, heteroaliphatic, haloaliphatic, haloheteroaliphatic, aromatic, as defined herein, or any combination thereof, or R¹ and R², taken together with the nitrogen atom to which each are attached, form a heterocyclyl group, as defined herein); (5) aryl; (6) arylalkoxy (e.g., —O-L-R, in which L is alkyl and R is aryl); (7) aryloyl (e.g., —C(O)—R, in which R is aryl); (8) azido (e.g., —N₃); (9) cyano (e.g., —CN); (10) aldehyde (e.g., —C(O)H); (11) C₃₋₉ cycloalkyl; (12) halo; (13) heterocyclyl (e.g., as defined herein, such as a 5-, 6- or 7-membered ring containing one, two, three, or four non-carbon heteroatoms); (14) heterocyclyloxy (e.g., —O—R, in which R is heterocyclyl, as defined herein); (15) heterocyclyloyl (e.g., —C(O)—R, in which R is heterocyclyl, as defined herein); (16) hydroxyl (e.g., —OH); (17)N-protected amino; (18) nitro (e.g., —NO₂); (19) oxo (e.g., ═O); (20) C₁₋₆ thioalkoxy (e.g., —S—R, in which R is C₁₋₆ alkyl); (21) thiol (e.g., —SH); (22) —CO₂R¹, where R¹ is selected from the group consisting of (a) hydrogen, (b) C₁₋₆ alkyl, (c) C₄₋₁₈ aryl, and (d) C₁₋₆ alkyl-C₄₋₁₈ aryl (e.g., -L-R, in which L is C₁₋₆ alkyl and R is C₄₋₁₈ aryl); (23) —C(O)NR¹R², where each of R¹ and R² is, independently, selected from the group consisting of (a) hydrogen, (b) C₁₋₆ alkyl, (c) C₄₋₁₈ aryl, and (d) C₁₋₆ alkyl-C₄₋₁₈ aryl (e.g., -L-R, in which L is C₁₋₆ alkyl and R is C₄₋₁₈ aryl); (24) —SO₂R¹, where R¹ is selected from the group consisting of (a) C₁₋₆ alkyl, (b) C₄₋₁₈ aryl, and (c) C₁₋₆ alkyl-C₄₋₁₈ aryl (e.g., -L-R, in which L is C₁₋₆ alkyl and R is C₄₋₁₈ aryl); (25) —SO₂NR¹R², where each of R¹ and R² is, independently, selected from the group consisting of (a) hydrogen, (b) C₁₋₆ alkyl, (c) C₄₋₁₈ aryl, and (d) C₁₋₆ alkyl-C₄₋₁₈ aryl (e.g., -L-R, in which L is C₁₋₆ alkyl and R is C₄₋₁₈ aryl); and (26) —NR¹R², where each of R¹ and R² is, independently, selected from the group consisting of (a) hydrogen, (b) an N-protecting group, (c) C₁₋₆ alkyl, (d) C₂₋₆ alkenyl, (e) C₂₋₆ alkynyl, (f) C₄₋₁₈ aryl, (g) C₁₋₆ alkyl-C₄₋₁₈ aryl (e.g., -L-R, in which L is C₁₋₆ alkyl and R is C₄₋₁₈ aryl), (h) C₃₋₉ cycloalkyl, and (i) C₁₋₆ alkyl-C₃₋₉ cycloalkyl (e.g., -L-R, in which L is C₁₋₆ alkyl and R is C₃₋₉ cycloalkyl), wherein in one embodiment no two groups are bound to the nitrogen atom through a carbonyl group or a sulfonyl group.

In certain embodiments, the additive may act as a proton acceptor and promote formation of HF₂⁻. In some such cases, the HF₂⁻ may actively etch one or more materials on the substrate such as an oxide material or another material.

### Etching

The vapor phase species delivered to the reaction chamber may be collectively referred to as a gas mixture. The non-inert species delivered to the reaction chamber (e.g., the reactants other than the carrier gas) may be collectively referred to as a reactant mixture. The gas mixture includes the reactant mixture and the carrier gas. In some cases, the reactant mixture and/or the gas mixture may have a particular composition. For example, hydrogen fluoride or other halogen source may be provided in the reactant mixture at a concentration between about 20-100% (by volume), or between about 20-99% (by volume). In these or other cases, hydrogen fluoride or other halogen source may be provided in the gas mixture at a concentration between about 0.5-20% (by volume). The organic solvent and/or water may be provided in the reactant mixture at a concentration between about 10-100% (by volume), or between about 10-99% (by volume). In these or other cases, the organic solvent and/or water may be provided in the gas mixture at a concentration between about 0-10% (by volume). The additive may be provided in the reactant mixture at a concentration between about 0.2-5% (by volume). In these or other cases, the additive may be provided in the gas mixture at a concentration between about 0-0.2%, or between about 0.0001-0.2% (by volume). The carrier gas may be provided in the gas mixture at a concentration between about 0-99% (by volume).

In some embodiments, the additive and organic solvent and/or water are mixed such that the additive is between about 0.1-5% (by weight) of the additive/organic solvent and/or water mixture. A reactant mixture regardless of the order of mixing may be characterized by the additive being about 0.1-5% (by weight) of the total of the amounts of additive and organic solvent and/or water.

In the same or alternate embodiments, the reactant mixture may be characterized by halogen source:additive ratio (by volume). As described further below, in some embodiments, the selectivity can be tuned by the halogen source:additive vol. ratio, with selectivity increasing with an increasing amount of additive (and thus a decreasing ratio). In some embodiments, the halogen source:additive ratio is less than or equal to 10. In some embodiments, the halogen:source additive ratio is greater than 10.

According to various embodiments, the reactant mixture may include a halogen source, an alcohol, and an amine, where the amine is between 0.1-5% wt of the total alcohol and amine amounts. In some embodiments, the halogen source:amine volumetric ratio is no more than 10. In other embodiments, the halogen source:amine volumetric ratio is 10 or higher. In some embodiments, the amine is pyridine. In some embodiments, the alcohol is isopropyl alcohol. In some embodiment the halogen source is HF.

As described above, according to various implementations, the etch may be selective to one material on a substrate with respect to another material. In other implementations, the etch may be non-selective with respect to multiple materials on a substrate.

In some embodiments, oxides are selectively etched with respect to one or more of nitrides and epitaxial materials such as Si and SiGe. The etch selectivity of the reactant mixture to silicon oxide can be tuned by the amount of additive in the mixture. For example, very high (at least 50:1) etch selectivity of silicon oxide with respect to silicon nitride is achieved with a reactant mixture having a halogen source:additive (e.g., HF:pyridine) of no more than 10. The etch selectivity decreases with increasing ratio such that no selectivity is observed in the case where there is no additive. Similar effects may be observed for etch selectivity of silicon oxide with respect to Si and SiGe.

In some embodiments, low-k materials are selectively etched with respect to barrier materials. For example, a carbon doped silicon oxide material may be etched selectively with respect to a barrier material such as a titanium nitride layer.

Examples of target materials, second materials, and etch chemistries to achieve selective or non-selective etch of the target material with respect to the second material are described in the below table. The ratios in parentheses indicate approximate etch rates of the target material with respect to the second material.

| Target material | Second material | Etch chemistry |
|---|---|---|
| SiO₂ | SiN | HF:additive ≤10 for high |
| | | selectivity of target (50:1). |
| | | No additive for non-selective |
| | | etch (1:1) |
| SiO₂ | Si, SiGe | HF:additive <10 |
| | | 1000:1 Selectivity |
| SiN | SiO₂ | No additive for non-selective |
| | | etch (1:1) |
| SiOC | Si, SiGe | HF:additive ≤10 for high |
| | | selectivity of target. (100:1) |

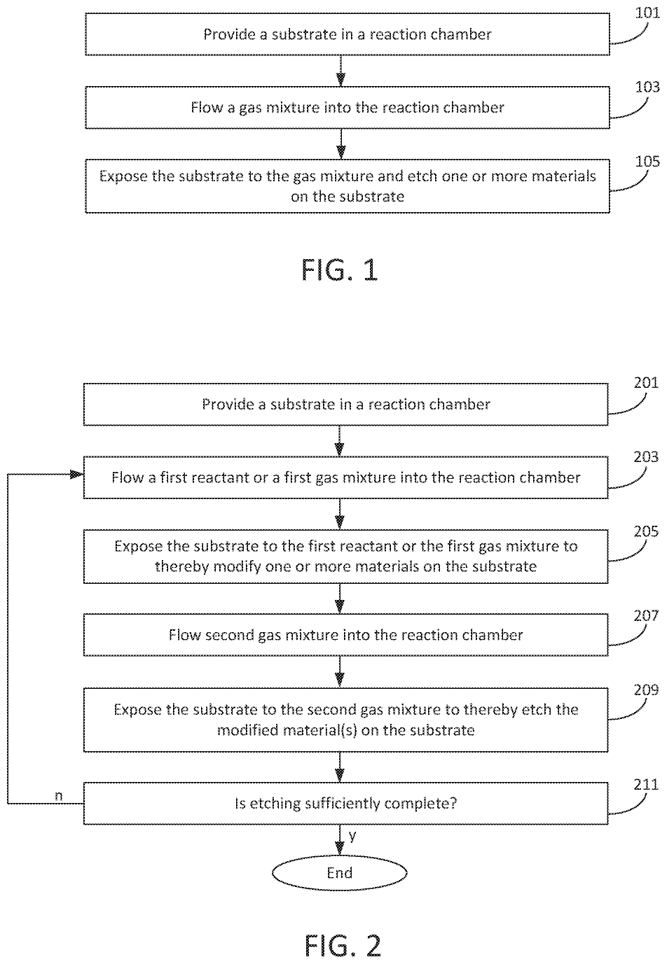

FIG. 1 presents a flow chart for a method of etching a substrate according to various embodiments herein. The method begins with operation 101, where a substrate is provided in a reaction chamber. The substrate includes one or more materials thereon that are to be removed. Example materials are listed above. At operation 103, a gas mixture is flowed into the reaction chamber. The gas mixture may have a composition and other properties as described herein. Similarly, one or more processing variables such as pressure, temperature, absolute and relative flow rates, etc. may be controlled as described herein. At operation 105, the substrate is exposed to the gas mixture, and one or more of the materials on the substrate are etched as a result of such exposure. These operations may overlap in time.

In some examples, the gas mixture is prepared by first creating a mixture of (1) the additive and (2) the organic solvent and/or water. The mixture of the additive and the organic solvent and/or water may be added to the carrier gas, and then the hydrogen fluoride gas or other halogen source may be added. In other examples, the hydrogen fluoride or other halogen source gas, the carrier gas and the alcohol may be mixed together to form a gas flow, and then the additive may be added to the gas flow. Various mixing schemes are possible, and all are considered to be within the scope of the disclosed embodiments.

In some implementations, one or more processing variable may be controlled during etching. For instance, a pressure within the reaction chamber may be controlled at about 10 Torr or less, for example between about 0.2-10 Torr in some embodiments. A temperature within the reaction chamber may be controlled, for example by controlling the temperature of a substrate support on which the substrate is positioned during etching, and/or by controlling the temperature of the gas mixture and/or the temperature of showerhead used to deliver the gas mixture into the reaction chamber. In some embodiments, the temperature of one or more of the reaction chamber, the substrate support, and the showerhead may be controlled during etching, for example at temperatures between about 20-500° C. In some embodiments, the temperature of one or more of these elements may cycle between two or more different temperatures. One example is discussed further below in the context of FIGS. 2-4. In some embodiments, the duration over which the substrate is exposed to the gas mixture may be controlled. For instance, this duration may be between about 0-10 minutes. In some cases, the duration of exposure to the gas mixture may control the degree to which the materials on the substrate are etched. In other cases, the etching process may be self-limiting, such that additional exposure duration does not lead to additional etching of a targeted material. One such example is discussed in the context of FIGS. 2-4.

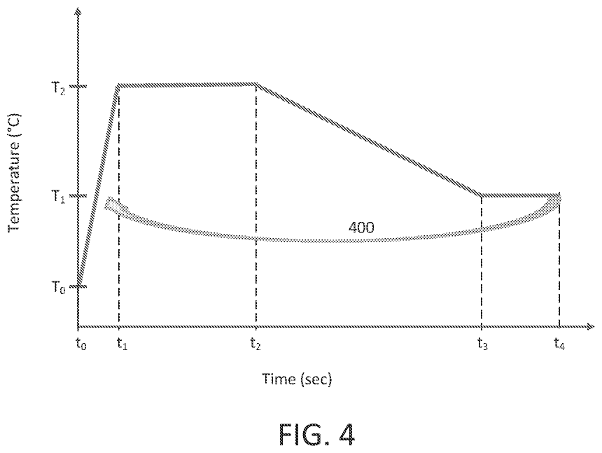

FIG. 2 is a flow chart describing a cyclic etching method that may be used in some embodiments. FIGS. 3A-3C illustrate a partially fabricated semiconductor substrate as it undergoes the processing method of FIG. 2. FIG. 4 illustrates how temperature may be controlled during the method of FIG. 2 in certain embodiments. For the sake of clarity, these figures will be described with reference to one another.

The method of FIG. 2 begins with operation 201, where a substrate 301 is provided to a reaction chamber. The substrate may have one or more materials thereon, as described above. One or more of these materials may be targeted for removal compared to other materials present on the substrate. In the particular example shown in FIG. 3A, the substrate 301 includes silicon fins 302 as well as an exposed spacer layer (not shown) that includes a spacer material such as SiN, SiCN, SiCO, or SiCON. In this example, it is desired to trim the fins such that they become smaller.

Next, at operation 203, a first reactant or first gas mixture is flowed into the reaction chamber. The first reactant or first gas mixture includes one or more species that will act to modify one or more materials present on the surface of the substrate 301. In some cases, the modification involves formation of an oxide material. In these or other cases, the modification involves fluorination of an exposed material, organic molecule adsorption on an exposed material, etc. Various surface modifications are available. In the context of the embodiment shown in FIGS. 3A-3C, the first reactant or first gas mixture includes an oxidizing species (e.g., O₂ or other oxidizing species) that will act to modify the silicon fins 302 to form silicon oxide 303, as described below. In many embodiments, the first reactant or first gas mixture may selectively modify one or more of the materials on the substrate 301 compared to other materials on the substrate 301. For instance, in the context of FIGS. 3A-3C, oxygen provided to the reaction chamber will selectively modify the silicon fins 302, with substantially less modification (or no modification) occurring on other materials such as the spacer material.

At operation 205, the substrate 301 is exposed to the first reactant or first gas mixture to modify one or more of the materials on the surface of the substrate 301. In the embodiment of FIGS. 3A-3C, exposure to the first reactant or first gas mixture results in modifying the exposed surface of the silicon fins 302 to form a thin layer of silicon oxide 303, as shown in FIG. 3B.

At operation 207, a second gas mixture is provided to the reaction chamber. The second gas mixture may have the composition and properties described herein. For example, it may include (1) HF or other halogen source(s), (2) one or more organic solvents and/or water, (3) one or more additives as described above, and (4) a carrier gas.

At operation 209, the substrate 301 is exposed to the second gas mixture, and the modified material formed in operation 205 (e.g., silicon oxide 303 in FIG. 3B) is etched away. In cases where the substrate 301 includes more than one material exposed, the modified material formed in operation 205 may be selectively etched away compared to other materials such as spacer materials, etc. At this point, some portion of the material targeted for removal has been modified and then removed from the substrate 301. In the context of FIGS. 3A-3C, this means that the silicon fins 302 are now smaller/narrower than they were previously, as shown in FIG. 3C.

Next, at operation 211, it is determined whether the etching process is sufficiently complete (e.g., whether a sufficient amount of material has been removed from the substrate 301). This determination may be made based on a number of factors including time, etch rate, thickness of material to be removed, etc. If it is determined that a sufficient amount of material has been removed from the substrate 301, then the method is complete. Otherwise, the method repeats, starting at operation 203. The surface modification and etching steps are cycled with one another until it is determined that a sufficient amount of material has been removed from the substrate 301.

FIG. 4 illustrates how a temperature in the reaction chamber may be controlled overtime when practicing a cyclic etching technique such as the one described in FIGS. 2 and 3A-3C. While FIG. 4 is explained in the context of FIGS. 2 and 3A-3C, it is understood that the embodiments are not so limited, and that the temperature control described in FIG. 4 may be used in many different contexts, including those that utilize other structures and/or other materials.

The temperature may be controlled using a number of techniques that may be combined as desired, for example by controlling the temperature of a substrate support, a showerhead, reaction chamber walls, process gases, etc. The process sequence of FIG. 4 begins at time to, when a substrate is introduced to the reaction chamber, as described in operation 201 of FIG. 2. The substrate includes one or more materials that are to be removed or otherwise etched. For instance, in the example of FIGS. 3A-3C, the substrate 301 includes silicon fins 302 that are to be trimmed, as shown in FIG. 3A. At time t₀, the temperature is at the initial starting temperature of T₀. Between times t₀ and t₁, the temperature increases from T₀ to T₂, as shown in FIG. 4. This period may be referred to as a ramp period because the temperature is ramping up. Between times t₁ and t₂, the temperature is maintained at T₂. This period may be referred to as a modification period. During the modification period, the substrate is exposed to the first reactant or first gas mixture to thereby modify one or more materials on the substrate, as described in operations 203 and 205 of FIG. 2. In some cases, the first reactant or first gas mixture may begin flowing into the reaction chamber at or shortly after time t₁, while in other cases the first reactant or first gas mixture may begin flowing into the reaction chamber at a time between t₀ and t₁. In the example of FIGS. 3A-3C, during the modification period, an exposed portion of the silicon fins 302 is converted to silicon oxide 303, as shown in FIG. 3B.

Returning to FIG. 4, between times t₂ and t₃, the temperature is decreased from T₂ to T₁. T₁ may be greater than T₀, as shown. In other cases, T₁ may be less than or equal to T₀. The period between times t₂ and t₃ may be referred to as a cool down period because the temperature is decreasing. Between times t₃ and t₄, the temperature is maintained at T₁. This period may be referred to as a vapor etch period. During the vapor etch period, the substrate is exposed to the second gas mixture to thereby etch some or all of the modified material(s) on the surface of the substrate, as described in operations 207 and 209 of FIG. 2. In some cases, the second gas mixture may begin flowing into the reaction chamber at or shortly after time t₃, while in other cases the second gas mixture may begin flowing into the reaction chamber at a time between t₂ and t₃. In the context of FIGS. 3A-3C, the silicon oxide 303 may be partially or wholly removed during the vapor etch period. After the vapor etch period, the substrate 301 may be as shown in FIG. 3C. By time t₃, at least a portion of the material that was targeted for removal (e.g., silicon fin 302 in FIGS. 3A-3C) has been removed. However, additional etching may be desired. As such, at time t₄ it is determined whether the etching is sufficiently complete, as described in operation 211 of FIG. 2. If the etching is sufficiently complete, the process sequence is complete and the substrate may be removed from the reaction chamber (not shown in FIG. 4). Where the etching is not yet sufficiently complete, the method may cycle back to an earlier stage, as indicated by arrow 400. At this time, the temperature is raised to T₂ in a second ramp period, followed by a second modification period, a second cool down period, and a second vapor etch period. The ramp period, modification period, cool down period, and vapor etch period may be cycled as desired until the etching is sufficiently complete.

As shown in FIG. 4, where cyclic etching techniques are used, the temperature may cycle between two or more different settings. In some embodiments, the temperature during the modification period (e.g., T₂) may be between about 100-500° C., while the temperature during the vapor etch period (e.g., T₁) may be between about 20-200° C. In various implementations, the substrate is not exposed to plasma during any of the periods described in FIG. 4. In such embodiments, both the reaction that occurs during the modification period and the reaction that occurs during the vapor etch period are driven by thermal energy.

The etching operation described in FIGS. 2-4 may be carried out in a self-limiting manner. For instance, the second gas mixture provided during the vapor etch period may selectively etch the modified material formed during the modification period. Once the modified material is consumed, the etching rate may decrease substantially or even stop as a result of the selective nature of the etching process. As such, the etch process may be considered self-limiting in certain embodiments. Further, as mentioned above, the etch process may selectively target the material to be removed, without substantially removing other materials present on the substrate such as spacer materials or other materials that are not targeted for etching. In some cases, the material targeted for removal may be etched with a selectivity of at least about 2:1 as compared to another material on the substrate, such as a spacer material. As used herein, an etch process with a selectivity of at least about 2:1 is considered to be selective. In some embodiments, the selectivity may be at least about 1000:1.

### Additional Definitions

This section presents additional definitions that may be used herein. Some of the materials described in this section may overlap with those presented elsewhere in the application.

The term “acyl,” or “alkanoyl,” as used interchangeably herein, represents groups of 1, 2, 3, 4, 5, 6, 7, 8 or more carbon atoms of a straight, branched, cyclic configuration, saturated, unsaturated and aromatic, and combinations thereof, or hydrogen, attached to the parent molecular group through a carbonyl group, as defined herein. This group is exemplified by formyl, acetyl, propionyl, isobutyryl, butanoyl, and the like. In some embodiments, the acyl or alkanoyl group is —C(O)—R, in which R is hydrogen, an aliphatic group, or an aromatic group, as defined herein.

By “acyl halide” is meant —C(O)X, where X is a halogen, such as Br, F, I, or C₁.

By “aldehyde” is meant a —C(O)H group.

By “aliphatic” is meant a hydrocarbon group having at least one carbon atom to 50 carbon atoms (C₁₋₅₀), such as one to 25 carbon atoms (C₁₋₂₅), or one to ten carbon atoms (C₁₋₁₀), and which includes alkanes (or alkyl), alkenes (or alkenyl), alkynes (or alkynyl), including cyclic versions thereof, and further including straight- and branched-chain arrangements, and all stereo and position isomers as well.

By “alkyl-aryl,” “alkenyl-aryl,” and “alkynyl-aryl” is meant an aryl group, as defined herein, that is or can be coupled (or attached) to the parent molecular group through an alkyl, alkenyl, or alkynyl group, respectively, as defined herein. The alkyl-aryl, alkenyl-aryl, and/or alkynyl-aryl group can be substituted or unsubstituted. For example, the alkyl-aryl, alkenyl-aryl, and/or alkynyl-aryl group can be substituted with one or more substitution groups, as described herein for alkyl, alkenyl, alkynyl, and/or aryl. Example unsubstituted alkyl-aryl groups are of from 7 to 16 carbons (C₇₋₁₆ alkyl-aryl), as well as those having an alkyl group with 1 to 6 carbons and an aryl group with 4 to 18 carbons (i.e., C₁₋₆ alkyl-C₄₋₁₈ aryl). Example unsubstituted alkenyl-aryl groups are of from 7 to 16 carbons (C₇₋₁₆ alkenyl-aryl), as well as those having an alkenyl group with 2 to 6 carbons and an aryl group with 4 to 18 carbons (i.e., C₂₋₆ alkenyl-C₄₋₁₈ aryl). Example unsubstituted alkynyl-aryl groups are of from 7 to 16 carbons (C₇₋₁₆ alkynyl-aryl), as well as those having an alkynyl group with 2 to 6 carbons and an aryl group with 4 to 18 carbons (i.e., C₂₋₆ alkynyl-C₄₋₁₈ aryl). In some embodiments, the alkyl-aryl group is -L-R, in which L is an alkyl group, as defined herein, and R is an aryl group, as defined herein. In some embodiments, the alkenyl-aryl group is -L-R, in which L is an alkenyl group, as defined herein, and R is an aryl group, as defined herein. In some embodiments, the alkynyl-aryl group is -L-R, in which L is an alkynyl group, as defined herein, and R is an aryl group, as defined herein.

By “alkenyl” is meant an unsaturated monovalent hydrocarbon having at least two carbon atom to 50 carbon atoms (C₂₋₅₀), such as two to 25 carbon atoms (C₂₋₂₅), or two to ten carbon atoms (C₂₋₁₀), and at least one carbon-carbon double bond, wherein the unsaturated monovalent hydrocarbon can be derived from removing one hydrogen atom from one carbon atom of a parent alkene. An alkenyl group can be branched, straight-chain, cyclic (e.g., cycloalkenyl), cis, or trans (e.g., E or Z). An example alkenyl includes an optionally substituted C₂₋₂₄ alkyl group having one or more double bonds. The alkenyl group can be monovalent or multivalent (e.g., bivalent) by removing one or more hydrogens to form appropriate attachment to the parent molecular group or appropriate attachment between the parent molecular group and another substitution. The alkenyl group can also be substituted or unsubstituted. For example, the alkenyl group can be substituted with one or more substitution groups, as described herein for alkyl.

By “alkyl-heteroaryl” is meant a heteroaryl group, as defined herein, attached to the parent molecular group through an alkyl group, as defined herein. In some embodiments, the alkyl-heteroaryl group is -L-R, in which L is an alkyl group, as defined herein, and R is a heteroaryl group, as defined herein.

By “alkyl-heterocyclyl,” “alkenyl-heterocyclyl,” and “alkynyl-heterocyclyl” is meant a heterocyclyl group, as defined herein, that is or can be coupled (or attached) to the parent molecular group through an alkyl, alkenyl, or alkynyl group, respectively, as defined herein. The alkyl-heterocyclyl, alkenyl-heterocyclyl, and/or alkynyl-heterocyclyl group can be substituted or unsubstituted. For example, the alkyl-heterocyclyl, alkenyl-heterocyclyl, and/or alkynyl-heterocyclyl group can be substituted with one or more substitution groups, as described herein for alkyl, alkenyl, alkynyl, and/or heterocyclyl. Example unsubstituted alkyl-heterocyclyl groups are of from 2 to 16 carbons (C₂₋₁₆ alkyl-heterocyclyl), as well as those having an alkyl group with 1 to 6 carbons and a heterocyclyl group with 1 to 18 carbons (i.e., C₁₋₆ alkyl-C₁₋₁₈ heterocyclyl). Example unsubstituted alkenyl-heterocyclyl groups are of from 3 to 16 carbons (C₃₋₁₆ alkenyl-heterocyclyl), as well as those having an alkenyl group with 2 to 6 carbons and a heterocyclyl group with 1 to 18 carbons (i.e., C₂₋₆ alkenyl-C₁₋₁₈ heterocyclyl). Example unsubstituted alkynyl-heterocyclyl groups are of from 3 to 16 carbons (C₃₋₁₆ alkynyl-heterocyclyl), as well as those having an alkynyl group with 2 to 6 carbons and a heterocyclyl group with 1 to 18 carbons (i.e., C₂₋₆ alkynyl-C₁₋₁₈ heterocyclyl). In some embodiments, the alkyl-heterocyclyl group is -L-R, in which L is an alkyl group, as defined herein, and R is a heterocyclyl group, as defined herein. In some embodiments, the alkenyl-heterocyclyl group is -L-R, in which L is an alkenyl group, as defined herein, and R is a heterocyclyl group, as defined herein. In some embodiments, the alkynyl-heterocyclyl group is -L-R, in which L is an alkynyl group, as defined herein, and R is a heterocyclyl group, as defined herein.

By “alkoxy” is meant —OR, where R is an optionally substituted aliphatic group, as described herein. Example alkoxy groups include, but are not limited to, methoxy, ethoxy, n-propoxy, isopropoxy, n-butoxy, t-butoxy, sec-butoxy, n-pentoxy, trihaloalkoxy, such as trifluoromethoxy, etc. The alkoxy group can be substituted or unsubstituted. For example, the alkoxy group can be substituted with one or more substitution groups, as described herein for alkyl. Example unsubstituted alkoxy groups include C₁₋₃, C₁₋₆, C₁₋₁₂, C₁₋₁₆, C₁₋₁₈, C₁₋₂₀, or C₁₋₂₄ alkoxy groups.

By “alkyl” is meant a saturated monovalent hydrocarbon having at least one carbon atom to 50 carbon atoms (C₁₋₅₀), such as one to 25 carbon atoms (C₁₋₂₅), or one to ten carbon atoms (C₁₋₁₀), wherein the saturated monovalent hydrocarbon can be derived from removing one hydrogen atom from one carbon atom of a parent compound (e.g., alkane). An alkyl group can be branched, straight-chain, or cyclic (e.g., cycloalkyl). An example alkyl includes a branched or unbranched saturated hydrocarbon group of 1 to 24 carbon atoms, such as methyl, ethyl, n-propyl, isopropyl, n-butyl, isobutyl, s-butyl, t-butyl, n-pentyl, isopentyl, s-pentyl, neopentyl, hexyl, heptyl, octyl, nonyl, decyl, dodecyl, tetradecyl, hexadecyl, eicosyl, tetracosyl, and the like. The alkyl group can also be substituted or unsubstituted. The alkyl group can be monovalent or multivalent (e.g., bivalent) by removing one or more hydrogens to form appropriate attachment to the parent molecular group or appropriate attachment between the parent molecular group and another substitution. For example, the alkyl group can be substituted with one, two, three or, in the case of alkyl groups of two carbons or more, four substituents independently selected from the group consisting of: (1) C₁₋₆ alkoxy (e.g., —O—R, in which R is C₁₋₆ alkyl); (2) C₁₋₆ alkylsulfinyl (e.g., —S(O)—R, in which R is C₁₋₆ alkyl); (3) C₁₋₆ alkylsulfonyl (e.g., —SO₂—R, in which R is C₁₋₆ alkyl); (4) amine (e.g., —C(O)NR¹R² or —NHCOR¹, where each of R¹ and R² is, independently, selected from hydrogen, aliphatic, heteroaliphatic, haloaliphatic, haloheteroaliphatic, aromatic, as defined herein, or any combination thereof, or R¹ and R², taken together with the nitrogen atom to which each are attached, form a heterocyclyl group, as defined herein); (5) aryl; (6) arylalkoxy (e.g., —O-L-R, in which L is alkyl and R is aryl); (7) aryloyl (e.g., —C(O)—R, in which R is aryl); (8) azido (e.g., —N₃); (9) cyano (e.g., —CN); (10) aldehyde (e.g., —C(O)H); (11) C₃₋₉ cycloalkyl; (12) halo; (13) heterocyclyl (e.g., as defined herein, such as a 5-, 6- or 7-membered ring containing one, two, three, or four non-carbon heteroatoms); (14) heterocyclyloxy (e.g., —O—R, in which R is heterocyclyl, as defined herein); (15) heterocyclyloyl (e.g., —C(O)—R, in which R is heterocyclyl, as defined herein); (16) hydroxyl (e.g., —OH); (17)N-protected amino; (18) nitro (e.g., —NO₂); (19) oxo (e.g., ═O); (20) C₁₋₆ thioalkoxy (e.g., —S—R, in which R is alkyl); (21) thiol (e.g., —SH); (22) —CO₂R¹, where R¹ is selected from the group consisting of (a) hydrogen, (b) C₁₋₆ alkyl, (c) C₄₋₁₈ aryl, and (d) C₁₋₆ alkyl-C₄₋₁₈ aryl (e.g., -L-R, in which L is C₁₋₆ alkyl and R is C₄₋₁₈ aryl); (23) —C(O)NR₁R², where each of R¹ and R² is, independently, selected from the group consisting of (a) hydrogen, (b) C₁₋₆ alkyl, (c) C₄₋₁₈ aryl, and (d) C₁₋₆ alkyl-C₄₋₁₈ aryl (e.g., -L-R, in which L is C₁₋₆ alkyl and R is C₄₋₁₈ aryl); (24) —SO₂R¹, where R¹ is selected from the group consisting of (a) C₁₋₆ alkyl, (b) C₄₋₁₈ aryl, and (c) C₁₋₆ alkyl-C₄₋₁₈ aryl (e.g., -L-R, in which L is C₁₋₆ alkyl and R is C₄₋₁₈ aryl); (25) —SO₂NR¹R², where each of R¹ and R² is, independently, selected from the group consisting of (a) hydrogen, (b) C₁₋₆ alkyl, (c) C₄₋₁₈ aryl, and (d) C₁₋₆ alkyl-C₄₋₁₈ aryl (e.g., -L-R, in which L is C₁₋₆ alkyl and R is C₄₋₁₈ aryl); and (26) —NR¹R², where each of R¹ and R² is, independently, selected from the group consisting of (a) hydrogen, (b) an N-protecting group, (c) C₁₋₆ alkyl, (d) C₂₋₆ alkenyl, (e) C₂₋₆ alkynyl, (f) C₄₋₁₈ aryl, (g) C₁₋₆ alkyl-C₄₋₁₈ aryl (e.g., -L-R, in which L is C₁₋₆ alkyl and R is C₄₋₁₈ aryl), (h) C₃₋₉ cycloalkyl, and (i) C₁₋₆ alkyl-C₃₋₉ cycloalkyl (e.g., -L-R, in which L is C₁₋₆ alkyl and R is C₃₋₉ cycloalkyl), wherein in one embodiment no two groups are bound to the nitrogen atom through a carbonyl group or a sulfonyl group. The alkyl group can be a primary, secondary, or tertiary alkyl group substituted with one or more substituents (e.g., one or more halo or alkoxy). In some embodiments, the unsubstituted alkyl group is a C₁₋₃, C₁₋₆, C₁₋₁₂, C₁₋₁₆, C₁₋₁₈, C₁₋₂₀, or C₁₋₂₄ alkyl group.

By “alkylsulfinyl” is meant an alkyl group, as defined herein, attached to the parent molecular group through an —S(O)— group. In some embodiments, the unsubstituted alkylsulfinyl group is a C₁₋₆ or C₁₋₁₂ alkylsulfinyl group. In other embodiments, the alkylsulfinyl group is —S(O)—R, in which R is an alkyl group, as defined herein.

By “alkylsulfonyl” is meant an alkyl group, as defined herein, attached to the parent molecular group through an —SO₂— group. In some embodiments, the unsubstituted alkylsulfonyl group is a C₁₋₆ or C₁₋₁₂ alkylsulfonyl group. In other embodiments, the alkylsulfonyl group is —SO₂—R, where R is an optionally substituted alkyl (e.g., as described herein, including optionally substituted C₁₋₁₂ alkyl, haloalkyl, or perfluoroalkyl).

By “alkynyl” is meant an unsaturated monovalent hydrocarbon having at least two carbon atom to 50 carbon atoms (C₂₋₅₀), such as two to 25 carbon atoms (C₂₋₂₅), or two to ten carbon atoms (C₂₋₁₀), and at least one carbon-carbon triple bond, wherein the unsaturated monovalent hydrocarbon can be derived from removing one hydrogen atom from one carbon atom of a parent alkyne. An alkynyl group can be branched, straight-chain, or cyclic (e.g., cycloalkynyl). An example alkynyl includes an optionally substituted C₂₋₂₄ alkyl group having one or more triple bonds. The alkynyl group can be cyclic or acyclic and is exemplified by ethynyl, 1-propynyl, and the like. The alkynyl group can be monovalent or multivalent (e.g., bivalent) by removing one or more hydrogens to form appropriate attachment to the parent molecular group or appropriate attachment between the parent molecular group and another substitution. The alkynyl group can also be substituted or unsubstituted. For example, the alkynyl group can be substituted with one or more substitution groups, as described herein for alkyl.

By “amide” is mean —C(O)NR¹R² or —NHCOR₁, where each of R¹ and R² is, independently, selected from hydrogen, aliphatic, heteroaliphatic, haloaliphatic, haloheteroaliphatic, aromatic, as defined herein, or any combination thereof, or R¹ and R², taken together with the nitrogen atom to which each are attached, form a heterocyclyl group, as defined herein.

By “amine” is meant —NR¹R², where each of R¹ and R² is, independently, selected from hydrogen, aliphatic, heteroaliphatic, haloaliphatic, haloheteroaliphatic, aromatic, as defined herein, or any combination thereof, or R¹ and R², taken together with the nitrogen atom to which each are attached, form a heterocyclyl group, as defined herein.

By “aminoalkyl” is meant an alkyl group, as defined herein, substituted by an amine group, as defined herein. In some embodiments, the aminoalkyl group is -L-NR¹R², in which L is an alkyl group, as defined herein, and each of R¹ and R² is, independently, selected from hydrogen, aliphatic, heteroaliphatic, haloaliphatic, haloheteroaliphatic, aromatic, as defined herein, or any combination thereof, or R¹ and R², taken together with the nitrogen atom to which each are attached, form a heterocyclyl group, as defined herein. In other embodiments, the aminoalkyl group is -L-C(NR¹R²)(R³)—R⁴, in which L is a covalent bond or an alkyl group, as defined herein; each of R¹ and R² is, independently, selected from hydrogen, aliphatic, heteroaliphatic, haloaliphatic, haloheteroaliphatic, aromatic, as defined herein, or any combination thereof, or R¹ and R², taken together with the nitrogen atom to which each are attached, form a heterocyclyl group, as defined herein; and each of R³ and R⁴ is, independently, H or alkyl, as defined herein.

By “aromatic” is meant a cyclic, conjugated group or moiety of, unless specified otherwise, from 5 to 15 ring atoms having a single ring (e.g., phenyl) or multiple condensed rings in which at least one ring is aromatic (e.g., naphthyl, indolyl, or pyrazolopyridinyl); that is, at least one ring, and optionally multiple condensed rings, have a continuous, delocalized 2-electron system. Typically, the number of out of plane 2-electrons corresponds to the Huckel rule (4n+2). The point of attachment to the parent structure typically is through an aromatic portion of the condensed ring system.

By “aryl” is meant an aromatic carbocyclic group comprising at least five carbon atoms to 15 carbon atoms (C₅₋₁₅), such as five to ten carbon atoms (C₅₋₁₀), having a single ring or multiple condensed rings, which condensed rings can or may not be aromatic provided that the point of attachment to a remaining position of the compounds disclosed herein is through an atom of the aromatic carbocyclic group. Aryl groups may be substituted with one or more groups other than hydrogen, such as aliphatic, heteroaliphatic, aromatic, other functional groups, or any combination thereof. Example aryl groups include, but are not limited to, benzyl, naphthalene, phenyl, biphenyl, phenoxybenzene, and the like. The term aryl also includes heteroaryl, which is defined as a group that contains an aromatic group that has at least one heteroatom incorporated within the ring of the aromatic group. Examples of heteroatoms include, but are not limited to, nitrogen, oxygen, sulfur, and phosphorus. Likewise, the term non-heteroaryl, which is also included in the term aryl, defines a group that contains an aromatic group that does not contain a heteroatom. The aryl group can be substituted or unsubstituted. The aryl group can be substituted with one, two, three, four, or five substituents independently selected from the group consisting of: (1) C₁₋₆ alkanoyl (e.g., —C(O)—R, in which R is C₁₋₆ alkyl); (2) C₁₋₆ alkyl; (3) C₁₋₆ alkoxy (e.g., —O—R, in which R is C₁₋₆ alkyl); (4) C₁₋₆ alkoxy-C₁₋₆ alkyl (e.g., -L-O—R, in which each of L and R is, independently, C₁₋₆ alkyl); (5) C₁₋₆ alkylsulfinyl (e.g., —S(O)—R, in which R is C₁₋₆ alkyl); (6) C₁₋₆ alkylsulfinyl-C₁₋₆ alkyl (e.g., -L-S(O)—R, in which each of L and R is, independently, C₁₋₆ alkyl); (7) C₁₋₆ alkylsulfonyl (e.g., —SO₂—R, in which R is C₁₋₆ alkyl); (8) C₁₋₆ alkylsulfonyl-C₁₋₆ alkyl (e.g., -L-SO₂—R, in which each of L and R is, independently, C₁₋₆ alkyl); (9) aryl; (10) amine (e.g., —NR¹R², where each of R¹ and R² is, independently, selected from hydrogen, aliphatic, heteroaliphatic, haloaliphatic, haloheteroaliphatic, aromatic, as defined herein, or any combination thereof, or R¹ and R², taken together with the nitrogen atom to which each are attached, form a heterocyclyl group, as defined herein); (11) C₁₋₆ aminoalkyl (e.g., -L¹-NR¹R² or -L²-C(NR¹R²)(R³)—R⁴, in which L¹ is C₁₋₆ alkyl; L² is a covalent bond or C₁₋₆ alkyl; each of R¹ and R² is, independently, selected from hydrogen, aliphatic, heteroaliphatic, haloaliphatic, haloheteroaliphatic, aromatic, as defined herein, or any combination thereof, or R¹ and R², taken together with the nitrogen atom to which each are attached, form a heterocyclyl group, as defined herein; and each of R³ and R⁴ is, independently, H or C₁₋₆ alkyl); (12) heteroaryl; (13) C₁₋₆ alkyl-C₄₋₁₈ aryl (e.g., -L-R, in which L is C₁₋₆ alkyl and R is C₄₋₁₈ aryl); (14) aryloyl (e.g., —C(O)—R, in which R is aryl); (15) azido (e.g., —N₃); (16) cyano (e.g., —CN); (17) C₁₋₆ azidoalkyl (e.g., -L-N₃, in which L is C₁₋₆ alkyl); (18) aldehyde (e.g., —C(O)H); (19) aldehyde-C₁₋₆ alkyl (e.g., -L-C(O)H, in which L is C₁₋₆ alkyl); (20) C₃₋₉ cycloalkyl; (21) C₁₋₆ alkyl-C₃₋₉ cycloalkyl (e.g., -L-R, in which L is C₁₋₆ alkyl and R is C₃₋₉ cycloalkyl); (22) halo; (23) C₁₋₆ haloalkyl (e.g., -L¹-X or -L²-C(X)(R¹)—R², in which L¹ is C₁₋₆ alkyl; L² is a covalent bond or C₁₋₆ alkyl; X is fluoro, bromo, chloro, or iodo; and each of R¹ and R² is, independently, H or C₁₋₆ alkyl); (24) heterocyclyl (e.g., as defined herein, such as a 5-, 6- or 7-membered ring containing one, two, three, or four non-carbon heteroatoms); (25) heterocyclyloxy (e.g., —O—R, in which R is heterocyclyl, as defined herein); (26) heterocyclyloyl (e.g., —C(O)—R, in which R is heterocyclyl, as defined herein); (27) hydroxyl (—OH); (28) C₁₋₆ hydroxyalkyl (e.g., -L¹-OH or -L²-C(OH)(R¹)—R², in which L¹ is C₁₋₆ alkyl; L² is a covalent bond or alkyl; and each of R¹ and R² is, independently, H or C₁₋₆ alkyl, as defined herein); (29) nitro; (30) C₁₋₆ nitroalkyl (e.g., -L¹-NO or -L²-C(NO)(R¹)—R², in which L¹ is C₁₋₆ alkyl; L² is a covalent bond or alkyl; and each of R¹ and R² is, independently, H or C₁₋₆ alkyl, as defined herein); (31)N-protected amino; (32)N-protected amino-C₁₋₆ alkyl; (33) oxo (e.g., ═O); (34) C₁₋₆ thioalkoxy (e.g., —S—R, in which R is C₁₋₆ alkyl); (35) thio-C₁₋₆ alkoxy-C₁₋₆ alkyl (e.g., -L-S—R, in which each of L and R is, independently, C₁₋₆ alkyl); (36) —(CH₂)ᵣCO₂R¹, where r is an integer of from zero to four, and R¹ is selected from the group consisting of (a) hydrogen, (b) C₁₋₆ alkyl, (c) C₄₋₁₈ aryl, and (d) C₁₋₆ alkyl-C₄₋₁₈ aryl (e.g., -L-R, in which L is C₁₋₆ alkyl and R is C₄₋₁₈ aryl); (37) —(CH₂)ᵣCONR¹R², where r is an integer of from zero to four and where each R¹ and R² is independently selected from the group consisting of (a) hydrogen, (b) C₁₋₆ alkyl, (c) C₄₋₁₈ aryl, and (d) C₁₋₆ alkyl-C₄₋₁₈ aryl (e.g., -L-R, in which L is C₁₋₆ alkyl and R is C₄₋₁₈ aryl); (38) —(CH₂)ᵣSO₂R¹, where r is an integer of from zero to four and where R¹ is selected from the group consisting of (a) C₁₋₆ alkyl, (b) C₄₋₁₈ aryl, and (c) C₁₋₆ alkyl-C₄₋₁₈ aryl (e.g., -L-R, in which L is C₁₋₆ alkyl and R is C₄₋₁₈ aryl); (39) —(CH₂)ᵣSO₂NR¹R², where r is an integer of from zero to four and where each of R¹ and R² is, independently, selected from the group consisting of (a) hydrogen, (b) C₁₋₆ alkyl, (c) C₄₋₁₈ aryl, and (d) C₁₋₆ alkyl-C₄₋₁₈ aryl (e.g., -L-R, in which L is C₁₋₆ alkyl and R is C₄₋₁₈ aryl); (40) —(CH₂)ᵣNR¹R², where r is an integer of from zero to four and where each of R¹ and R² is, independently, selected from the group consisting of (a) hydrogen, (b) an N-protecting group, (c) C₁₋₆ alkyl, (d) C₂₋₆ alkenyl, (e) C₂₋₆ alkynyl, (f) C₄₋₁₈ aryl, (g) C₁₋₆ alkyl-C₄₋₁₈ aryl (e.g., -L-R, in which L is C₁₋₆ alkyl and R is C₄₋₁₈ aryl), (h) C₃₋₉ cycloalkyl, and (i) C₁₋₆ alkyl-C₃₋₉ cycloalkyl (e.g., -L-R, in which L is C₁₋₆ alkyl and R is C₃₋₉ cycloalkyl), wherein in one embodiment no two groups are bound to the nitrogen atom through a carbonyl group or a sulfonyl group; (41) thiol (e.g., —SH); (42) perfluoroalkyl (e.g., —(CF₂)ₙCF₃, in which n is an integer from 0 to 10); (43) perfluoroalkoxy (e.g., —O—(CF₂)ₙCF₃, in which n is an integer from 0 to 10); (44) aryloxy (e.g., —O—R, in which R is aryl); (45) cycloalkoxy (e.g., —O—R, in which R is cycloalkyl); (46) cycloalkylalkoxy (e.g., —O-L-R, in which L is alkyl and R is cycloalkyl); and (47) arylalkoxy (e.g., —O-L-R, in which L is alkyl and R is aryl). In particular embodiments, an unsubstituted aryl group is a C₄₋₁₈, C₄₋₁₄, C₄₋₁₂, C₄₋₁₀, C₆₋₁₈, C₆₋₁₄, C₆₋₁₂, or C₆₋₁₀ aryl group.

By “arylalkoxy” is meant an alkyl-aryl group, as defined herein, attached to the parent molecular group through an oxygen atom. In some embodiments, the arylalkoxy group is —O-L-R, in which L is an alkyl group, as defined herein, and R is an aryl group, as defined herein.

By “aryloxy” is meant —OR, where R is an optionally substituted aryl group, as described herein. In some embodiments, an unsubstituted aryloxy group is a C₄₋₁₈ or C₆₋₁₈ aryloxy group.

By “aryloyl” is meant an aryl group that is attached to the parent molecular group through a carbonyl group. In some embodiments, an unsubstituted aryloyl group is a C₇₋₁₁ aryloyl or C₅₋₁₉ aryloyl group. In other embodiments, the aryloyl group is —C(O)—R, in which R is an aryl group, as defined herein.

By “azido” is meant an —N₃ group.

By “azidoalkyl” is meant an azido group attached to the parent molecular group through an alkyl group, as defined herein. In some embodiments, the azidoalkyl group is -L-N₃, in which L is an alkyl group, as defined herein. By “azo” is meant an —N═N— group.

By “carbene” is meant H₂C; and derivatives thereof having carbon bearing two nonbonding electrons or (C:). In some embodiments, the carbene is R¹R²(C:), where each of R¹ and R² is, independently, selected from hydrogen, aliphatic, heteroaliphatic, haloaliphatic, haloheteroaliphatic, aromatic, as defined herein, or any combination thereof, or R¹ and R², taken together with the atom to which each are attached, form a cycloaliphatic group, as defined herein.

By “carbenium cation” is meant H₃C⁺ and derivatives thereof having carbon bearing a +1 formal charge or C⁺. In some embodiments, the carbenium cation is R¹—C⁺(R)—R², where each of R, R¹, and R² is, independently, selected from hydrogen, aliphatic, heteroaliphatic, haloaliphatic, haloheteroaliphatic, aromatic, as defined herein, or any combination thereof, or R¹ and R² and optionally R, taken together with the atom to which each are attached, form a cycloaliphatic group, as defined herein.

By “carbonyl” is meant a —C(O)— group, which can also be represented as > C═O.

By “carboxyl” is meant a —CO₂H group or an anion thereof.

By “cyano” is meant a —CN group.

By “cycloaliphatic” is meant an aliphatic group, as defined herein, that is cyclic.

By “cycloalkoxy” is meant a cycloalkyl group, as defined herein, attached to the parent molecular group through an oxygen atom. In some embodiments, the cycloalkoxy group is —O—R, in which R is a cycloalkyl group, as defined herein.

By “cycloalkylalkoxy” is meant an alkyl-cycloalkyl group, as defined herein, attached to the parent molecular group through an oxygen atom. In some embodiments, the cycloalkylalkoxy group is —O-L-R, in which L is an alkyl group, as defined herein, and R is a cycloalkyl group, as defined herein.

By “cycloalkyl” is meant a monovalent saturated or unsaturated non-aromatic cyclic hydrocarbon group of from three to eight carbons, unless otherwise specified, and is exemplified by cyclopropyl, cyclobutyl, cyclopentyl, cyclohexyl, cycloheptyl, bicyclo[2.2.1.heptyl, and the like. The cycloalkyl group can also be substituted or unsubstituted. For example, the cycloalkyl group can be substituted with one or more groups including those described herein for alkyl.

By “cycloheteroaliphatic” is meant a heteroaliphatic group, as defined herein, that is cyclic.

By “ester” is meant —C(O)OR or —OC(O)R, where R is selected from aliphatic, heteroaliphatic, haloaliphatic, haloheteroaliphatic, aromatic, as defined herein, or any combination thereof.

By “ether” is meant R—O—R¹, where each of R and R¹ is, independently, selected from an aryl or alkyl group, or where R and R¹, taken together with the atom to which each are attached, form a heterocyclic ring, as defined herein.

By “halo” is meant F, Cl, Br, or I.

By “haloaliphatic” is meant an aliphatic group, as defined herein, in which one or more hydrogen atoms, such as one to 10 hydrogen atoms, independently is replaced with a halogen atom, such as fluoro, bromo, chloro, or iodo.

By “haloalkyl” is meant an alkyl group, as defined herein, where one or more hydrogen atoms, such as one to 10 hydrogen atoms, independently is replaced with a halogen atom, such as fluoro, bromo, chloro, or iodo. In an independent embodiment, haloalkyl can be a —CX₃ group, wherein each X independently can be selected from fluoro, bromo, chloro, or iodo. In some embodiments, the haloalkyl group is -L-X, in which L is an alkyl group, as defined herein, and X is fluoro, bromo, chloro, or iodo. In other embodiments, the halooalkyl group is -L-C(X)(R¹)—R², in which L is a covalent bond or an alkyl group, as defined herein; X is fluoro, bromo, chloro, or iodo; and each of R¹ and R² is, independently, H or alkyl, as defined herein.

By “haloheteroaliphatic” is meant a heteroaliphatic, as defined herein, in which one or more hydrogen atoms, such as one to 10 hydrogen atoms, independently is replaced with a halogen atom, such as fluoro, bromo, chloro, or iodo.

By “heteroaliphatic” is meant an aliphatic group, as defined herein, including at least one heteroatom to 20 heteroatoms, such as one to 15 heteroatoms, or one to 5 heteroatoms, which can be selected from, but not limited to oxygen, nitrogen, sulfur, silicon, boron, selenium, phosphorous, and oxidized forms thereof within the group.

By “heteroalkyl,” “heteroalkenyl,” and “heteroalkynyl” is meant an alkyl, alkenyl, or alkynyl group (which can be branched, straight-chain, or cyclic), respectively, as defined herein, including at least one heteroatom to 20 heteroatoms, such as one to 15 heteroatoms, or one to 5 heteroatoms, which can be selected from, but not limited to, oxygen, nitrogen, sulfur, silicon, boron, selenium, phosphorous, and oxidized forms thereof within the group.

By “heteroalkyl-aryl,” “heteroalkenyl-aryl,” and “heteroalkynyl-aryl” is meant an aryl group, as defined herein, that is or can be coupled to a compound disclosed herein, where the aryl group is or becomes coupled through a heteroalkyl, heteroalkenyl, or heteroalkynyl group, respectively, as defined herein. In some embodiments, the heteroalkyl-aryl group is -L-R, in which L is a heteroalkyl group, as defined herein, and R is an aryl group, as defined herein. In some embodiments, the heteroalkenyl-aryl group is -L-R, in which L is a heteroalkenyl group, as defined herein, and R is an aryl group, as defined herein. In some embodiments, the heteroalkynyl-aryl group is -L-R, in which L is a heteroalkynyl group, as defined herein, and R is an aryl group, as defined herein.

By “heteroalkyl-heteroaryl,” “heteroalkenyl-heteroaryl,” and “heteroalkynyl-heteroaryl” is meant a heteroaryl group, as defined herein, that is or can be coupled to a compound disclosed herein, where the heteroaryl group is or becomes coupled through a heteroalkyl, heteroalkenyl, or heteroalkynyl group, respectively, as defined herein. In some embodiments, the heteroalkyl-heteroaryl group is -L-R, in which L is a heteroalkyl group, as defined herein, and R is a heteroaryl group, as defined herein. In some embodiments, the heteroalkenyl-heteroaryl group is -L-R, in which L is a heteroalkenyl group, as defined herein, and R is a heteroaryl group, as defined herein. In some embodiments, the heteroalkynyl-heteroaryl group is -L-R, in which L is a heteroalkynyl group, as defined herein, and R is a heteroaryl group, as defined herein.

By “heteroaryl” is meant an aryl group including at least one heteroatom to six heteroatoms, such as one to four heteroatoms, which can be selected from, but not limited to, oxygen, nitrogen, sulfur, silicon, boron, selenium, phosphorous, and oxidized forms thereof within the ring. Such heteroaryl groups can have a single ring or multiple condensed rings, where the condensed rings may or may not be aromatic and/or contain a heteroatom, provided that the point of attachment is through an atom of the aromatic heteroaryl group. Heteroaryl groups may be substituted with one or more groups other than hydrogen, such as aliphatic, heteroaliphatic, aromatic, other functional groups, or any combination thereof. An example heteroaryl includes a subset of heterocyclyl groups, as defined herein, which are aromatic, i.e., they contain 4n+2 pi electrons within the mono- or multicyclic ring system.

By “heteroatom” is meant an atom other than carbon, such as oxygen, nitrogen, sulfur, silicon, boron, selenium, or phosphorous. In particular disclosed embodiments, such as when valency constraints do not permit, a heteroatom does not include a halogen atom.

By “heterocyclyl” is meant a 5-, 6- or 7-membered ring, unless otherwise specified, containing one, two, three, or four non-carbon heteroatoms (e.g., independently selected from the group consisting of nitrogen, oxygen, phosphorous, sulfur, or halo). The 5-membered ring has zero to two double bonds and the 6- and 7-membered rings have zero to three double bonds. The term “heterocyclyl” also includes bicyclic, tricyclic and tetracyclic groups in which any of the above heterocyclic rings is fused to one, two, or three rings independently selected from the group consisting of an aryl ring, a cyclohexane ring, a cyclohexene ring, a cyclopentane ring, a cyclopentene ring, and another monocyclic heterocyclic ring, such as indolyl, quinolyl, isoquinolyl, tetrahydroquinolyl, benzofuryl, benzothienyl and the like. Heterocyclics include thiiranyl, thietanyl, tetrahydrothienyl, thianyl, thiepanyl, aziridinyl, azetidinyl, pyrrolidinyl, piperidinyl, azepanyl, pyrrolyl, pyrrolinyl, pyrazolyl, pyrazolinyl, pyrazolidinyl, imidazolyl, imidazolinyl, imidazolidinyl, pyridyl, homopiperidinyl, pyrazinyl, piperazinyl, pyrimidinyl, pyridazinyl, oxazolyl, oxazolidinyl, oxazolidonyl, isoxazolyl, isoxazolidiniyl, morpholinyl, thiomorpholinyl, thiazolyl, thiazolidinyl, isothiazolyl, isothiazolidinyl, indolyl, quinolinyl, isoquinolinyl, benzimidazolyl, benzothiazolyl, benzoxazolyl, furyl, thienyl, thiazolidinyl, isothiazolyl, isoindazoyl, triazolyl, tetrazolyl, oxadiazolyl, uricyl, thiadiazolyl, pyrimidyl, tetrahydrofuranyl, dihydrofuranyl, dihydrothienyl, dihydroindolyl, tetrahydroquinolyl, tetrahydroisoquinolyl, pyranyl, dihydropyranyl, tetrahydropyranyl, dithiazolyl, dioxanyl, dioxinyl, dithianyl, trithianyl, oxazinyl, thiazinyl, oxothiolanyl, triazinyl, benzofuranyl, benzothienyl, and the like.

By “heterocyclyloxy” is meant a heterocyclyl group, as defined herein, attached to the parent molecular group through an oxygen atom. In some embodiments, the heterocyclyloxy group is —O—R, in which R is a heterocyclyl group, as defined herein.

By “heterocyclyloyl” is meant a heterocyclyl group, as defined herein, attached to the parent molecular group through a carbonyl group. In some embodiments, the heterocyclyloyl group is —C(O)—R, in which R is a heterocyclyl group, as defined herein.

By “hydroxyl” is meant —OH.

By “hydroxyalkyl” is meant an alkyl group, as defined herein, substituted by one to three hydroxyl groups, with the proviso that no more than one hydroxyl group may be attached to a single carbon atom of the alkyl group and is exemplified by hydroxymethyl, dihydroxypropyl, and the like. In some embodiments, the hydroxyalkyl group is -L-OH, in which L is an alkyl group, as defined herein. In other embodiments, the hydroxyalkyl group is -L-C(OH)(R¹)—R², in which L is a covalent bond or an alkyl group, as defined herein, and each of R¹ and R² is, independently, H or alkyl, as defined herein.

By “ketone” is meant —C(O)R, where R is selected from aliphatic, heteroaliphatic, aromatic, as defined herein, or any combination thereof.

By “nitro” is meant an —NO₂ group.

By “nitroalkyl” is meant an alkyl group, as defined herein, substituted by one to three nitro groups. In some embodiments, the nitroalkyl group is -L-NO, in which L is an alkyl group, as defined herein. In other embodiments, the nitroalkyl group is -L-C(NO)(R¹)—R², in which L is a covalent bond or an alkyl group, as defined herein, and each of R¹ and R² is, independently, H or alkyl, as defined herein.

By “oxo” is meant an ═O group.

By “oxy” is meant —O—.

By “perfluoroalkyl” is meant an alkyl group, as defined herein, having each hydrogen atom substituted with a fluorine atom. Example perfluoroalkyl groups include trifluoromethyl, pentafluoroethyl, etc. In some embodiments, the perfluoroalkyl group is —(CF₂)ₙCF₃, in which n is an integer from 0 to 10.

By “perfluoroalkoxy” is meant an alkoxy group, as defined herein, having each hydrogen atom substituted with a fluorine atom. In some embodiments, the perfluoroalkoxy group is —O—R, in which R is a perfluoroalkyl group, as defined herein.

By “phosphine” is meant P—R¹R², where each of R¹ and R² is independently selected from hydrogen, aliphatic, heteroaliphatic, haloaliphatic, haloheteroaliphatic, or aromatic, or R¹ and R² taken together with the atom to which each are attached, form a heterocyclic group, as defined herein.

By “salt” is meant an ionic form of a compound or structure (e.g., any formulas, compounds, or compositions described herein), which includes a cation or anion compound to form an electrically neutral compound or structure. Salts are well known in the art. For example, non-toxic salts are described in Berge S M et al., “Pharmaceutical salts,” J. Pharm. Sci. 1977 January; 66(1):1-19; and in “Handbook of Pharmaceutical Salts: Properties, Selection, and Use,” Wiley-VCH, April 2011 (2nd rev. ed., eds. P. H. Stahl and C. G. Wermuth. The salts can be prepared in situ during the final isolation and purification of the compounds of the invention or separately by reacting the free base group with a suitable organic acid (thereby producing an anionic salt) or by reacting the acid group with a suitable metal or organic salt (thereby producing a cationic salt). Representative anionic salts include acetate, adipate, alginate, ascorbate, aspartate, benzenesulfonate, benzoate, bicarbonate, bisulfate, bitartrate, borate, bromide, butyrate, camphorate, camphorsulfonate, chloride, citrate, cyclopentanepropionate, digluconate, dihydrochloride, diphosphate, dodecylsulfate, edetate, ethanesulfonate, fumarate, glucoheptonate, gluconate, glutamate, glycerophosphate, hemisulfate, heptonate, hexanoate, hydrobromide, hydrochloride, hydroiodide, hydroxyethanesulfonate, hydroxynaphthoate, iodide, lactate, lactobionate, laurate, lauryl sulfate, malate, maleate, malonate, mandelate, mesylate, methanesulfonate, methylbromide, methylnitrate, methylsulfate, mucate, 2-naphthalenesulfonate, nicotinate, nitrate, oleate, oxalate, palmitate, pamoate, pectinate, persulfate, 3-phenylpropionate, phosphate, picrate, pivalate, polygalacturonate, propionate, salicylate, stearate, subacetate, succinate, sulfate, tannate, tartrate, theophyllinate, thiocyanate, triethiodide, toluenesulfonate, undecanoate, valerate salts, and the like. Representative cationic salts include metal salts, such as alkali or alkaline earth salts, e.g., barium, calcium (e.g., calcium edetate), lithium, magnesium, potassium, sodium, and the like; other metal salts, such as aluminum, bismuth, iron, and zinc; as well as nontoxic ammonium, quatemary ammonium, and amine cations, including, but not limited to ammonium, tetramethylammonium, tetraethylammonium, methylamine, dimethylamine, trimethylamine, triethylamine, ethylamine, pyridinium, and the like. Other cationic salts include organic salts, such as chloroprocaine, choline, dibenzylethylenediamine, diethanolamine, ethylenediamine, methylglucamine, and procaine. Yet other salts include ammonium, sulfonium, sulfoxonium, phosphonium, iminium, imidazolium, benzimidazolium, amidinium, guanidinium, phosphazinium, phosphazenium, pyridinium, etc., as well as other cationic groups described herein (e.g., optionally substituted isoxazolium, optionally substituted oxazolium, optionally substituted thiazolium, optionally substituted pyrrolium, optionally substituted furanium, optionally substituted thiophenium, optionally substituted imidazolium, optionally substituted pyrazolium, optionally substituted isothiazolium, optionally substituted triazolium, optionally substituted tetrazolium, optionally substituted furazanium, optionally substituted pyridinium, optionally substituted pyrimidinium, optionally substituted pyrazinium, optionally substituted triazinium, optionally substituted tetrazinium, optionally substituted pyridazinium, optionally substituted oxazinium, optionally substituted pyrrolidinium, optionally substituted pyrazolidinium, optionally substituted imidazolinium, optionally substituted isoxazolidinium, optionally substituted oxazolidinium, optionally substituted piperazinium, optionally substituted piperidinium, optionally substituted morpholinium, optionally substituted azepanium, optionally substituted azepinium, optionally substituted indolium, optionally substituted isoindolium, optionally substituted indolizinium, optionally substituted indazolium, optionally substituted benzimidazolium, optionally substituted isoquinolinum, optionally substituted quinolizinium, optionally substituted dehydroquinolizinium, optionally substituted quinolinium, optionally substituted isoindolinium, optionally substituted benzimidazolinium, and optionally substituted purinium).

By “sulfo” is meant an —S(O)₂OH group.

By “sulfonyl” or “sulfonate” is meant an —S(O)₂— group or a —SO₂R, where R is selected from hydrogen, aliphatic, heteroaliphatic, haloaliphatic, haloheteroaliphatic, aromatic, as defined herein, or any combination thereof.

By “thioalkoxy” is meant an alkyl group, as defined herein, attached to the parent molecular group through a sulfur atom. Example unsubstituted thioalkoxy groups include C₁₋₆ thioalkoxy. In some embodiments, the thioalkoxy group is —S—R, in which R is an alkyl group, as defined herein.

By “thiol” is meant an —SH group.

By “urea” is meant (R₁NR²)₂CO, where R¹ and R² are each independently selected from hydrogen, aliphatic, heteroaliphatic, haloaliphatic, haloheteroaliphatic, or aromatic, or R¹ and R² taken together with the atom to which each are attached, form a heterocyclic group, as defined herein.

A person of ordinary skill in the art would recognize that the definitions provided above are not intended to include impermissible substitution patterns (e.g., methyl substituted with 5 different groups, and the like). Such impermissible substitution patterns are easily recognized by a person of ordinary skill in the art. Any functional group disclosed herein and/or defined above can be substituted or unsubstituted, unless otherwise indicated therein.

### Apparatus

The methods described herein can be performed on any appropriate apparatus. The following description provides one example of an appropriate apparatus. The apparatus described herein allows for rapidly and precisely controlling a substrate's temperature during semiconductor processing, including performing etching using thermal energy, rather than or in addition to plasma energy, to drive the modification and removal operations. In certain embodiments, etching that relies upon chemical reactions in conjunction with primarily thermal energy, not a plasma, to drive the chemical reactions in the modification and removal operations may be considered “thermal etching”. This etching is not limited to ALE (atomic layer etching); it is applicable to any etching technique.

In certain embodiments, thermal etching processes, such as those employing one or more thermal cycles have relatively fast heating and cooling and relatively precise temperature control. In some cases, these features may be leveraged to provide good throughput and/or to reduce nonuniformity and wafer defects.

Many conventional etching apparatuses do not have the ability to adjust and control the temperature of the substrate with adequate speed. For example, while some etching apparatuses may be able to heat a substrate to multiple temperatures, they can do so only slowly, or they may not be able to reach the desired temperature ranges, or they may not be able to maintain the substrate temperature for the desired time and at the desired temperature ranges. Similarly, typical etching apparatuses are often unable to cool the substrate fast enough to enable high throughput or cool the substrate to the desired temperature ranges. For some applications, it is desirable to reduce the temperature ramp times as much as possible, such as to less than about 120 seconds in some embodiments, but many conventional etching apparatuses cannot heat, cool, or both, a substrate in less than that time; it may take some apparatuses multiple minutes to cool and/or heat a substrate, which slows throughput.

In various embodiments, apparatuses described herein are designed or configured to rapidly heat and cool a wafer, and precisely control a wafer's temperature. In some embodiments, the wafer is rapidly heated and its temperature is precisely controlled using, in part, visible light emitted from light emitting diodes (LEDs) positioned in a pedestal under the wafer. The visible light may have wavelengths that include and range between 400 nanometers (nm) and 800 nm. The pedestal may include various features for enabling wafer temperature control, such as a transparent window that may have lensing for advantageously directing or focusing the emitted light, reflective material also for advantageously directing or focusing the emitted light, and temperature control elements that assist with temperature control of the LEDs, the pedestal, and the chamber.

The apparatuses may also thermally isolate, or thermally “float,” the wafer within the processing chamber so that only the smallest thermal mass is heated, the ideal smallest thermal mass being just the substrate itself, which enables faster heating and cooling. The wafer may be rapidly cooled using a cooling gas and radiative heat transfer to a heat sink, such as a top plate (or other gas distribution element) above the wafer, or both. In some instances, the apparatus also includes temperature control elements within the processing chamber walls, pedestal, and top plate (or other gas distribution element), to enable further temperature control of the wafer and processing conditions within the chamber, such the prevention of unwanted condensation of processing gases and vapors.

The apparatuses may also be configured to implement various control loops to precisely control the wafer and the chamber temperatures (e.g., with a controller configured to execute instructions that cause the apparatus to perform these loops). This may include the use of various sensors that determine wafer and chamber temperatures as part of open loops and feedback control loops. These sensors may include temperature sensors in the wafer supports which contact the wafer and measure its temperature, and non-contact sensors such as photodetectors to measure light output of the LEDs and a pyrometer configured to measure the temperature of different types of wafers. As described in more detail below, traditional pyrometers determine an item's temperature by emitting infrared or other optical signals at the item and measuring the signals reflected or emitted by the item. However, many silicon wafers cannot be measured by traditional pyrometers because the silicon can be optically transparent at various temperatures and with various treatments, e.g., doped or low doped silicon. For example, a low doped silicon wafer at a temperature less than 200° C. is transparent to infrared signals. The novel pyrometers provided herein are able to measure multiple types of silicon wafers at various temperatures.

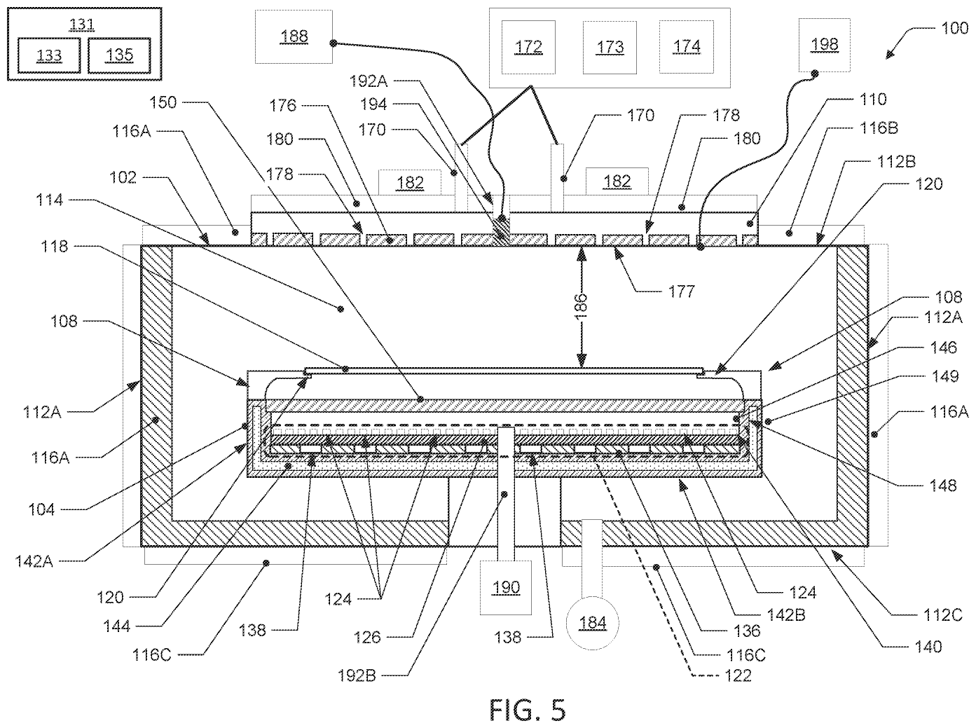

FIG. 5 depicts a cross-sectional side view of an example apparatus in accordance with disclosed embodiments. This apparatus may be used to perform any of the methods described herein, for example using the chemistry described herein. As detailed below, this apparatus 100 is capable of rapidly and precisely controlling the temperature of a substrate, including performing thermal etching operations. The apparatus 100 includes a processing chamber 102, a pedestal 104 having a substrate heater 106 and a plurality of substrates supports 108 configured to support a substrate 118, and a gas distribution unit 110.

The processing chamber 102 includes sides walls 112A, atop 112B, and a bottom 112C, that at least partially define the chamber interior 114, which may be considered a plenum volume. As stated herein, it may be desirable in some embodiments to actively control the temperature of the processing chamber walls 112A, top 112B, and bottom 112C in order to prevent unwanted condensation on their surfaces. Some emerging semiconductor processing operations flow vapors, such as water and/or alcohol vapor, onto the substrate which adsorb onto the substrate, but they may also undesirably adsorb onto the chamber's interior surfaces. This can lead to unwanted deposition and etching on the chamber interior surfaces which can damage the chamber surfaces and cause particulates to flake off onto the substrate thereby causing substrate defects. In order to reduce and prevent unwanted condensation on the chamber's interior surfaces, the temperature of chamber's walls, top, and bottom may be maintained at a temperature at which condensation of chemistries used in the processing operations does not occur.

This active temperature control of the chamber's surfaces may be achieved by using heaters to heat the chamber walls 112A, the top 112B, and the bottom 112C. As illustrated in FIG. 5, chamber heaters 116A are positioned on and configured to heat the chamber walls 112A, chamber heaters 116B are positioned on and configured to heat the top 112B, and chamber heaters 116C are positioned on and configured to heat the bottom 112C. The chamber heaters 116A-116C may be resistive heaters that are configured to generate heat when an electrical current is flowed through a resistive element. Chamber heaters 116A-116C may also be fluid conduits through which a heat transfer fluid may be flowed, such as a heating fluid which may include heated water. In some instances, the chamber heaters 116A-116C may be a combination of both heating fluid and resistive heaters. The chamber heaters 116A-116C are configured to generate heat in order to cause the interior surfaces of each of the chamber walls 112A, the top 112B, and the bottom 112C to the desired temperature, which may range between about 40° C. and about 150° C., including between about 80° C. and about 130° C., or about 90° C., or about 120° C., for instance. It has been discovered that under some conditions, water and alcohol vapors do not condense on surfaces kept at about 90° C. or higher.

The chamber walls 112A, top 112B, and bottom 112C, may also be comprised of various materials that can withstand the chemistries used in the processing techniques. These chamber materials may include, for example, an aluminum, anodized aluminum, aluminum with a polymer, such as a plastic, a metal or metal alloy with a yttria coating, a metal or metal alloy with a zirconia coating, and a metal or metal alloy with aluminum oxide coating; in some instances the materials of the coatings may be blended or layers of differing material combinations, such as alternating layers of aluminum oxide and yttria, or aluminum oxide and zirconia. These materials are configured to withstand the chemistries used in the processing techniques, such as anyhydrous HF, water vapor, methanol, isopropyl alcohol, chlorine, fluorine gases, nitrogen gas, hydrogen gas, helium gas, and the mixtures thereof.

The apparatus 100 may also be configured to perform processing operations at or near a vacuum, such as at a pressure of about 0.1 Torr to about 100 Torr, or about 20 Torr to about 200 Torr, or about 0.1 Torr to about 10 Torr. This may include a vacuum pump 184 configured to pump the chamber interior 114 to low pressures, such as a vacuum having a pressure of about 0.1 Torr to about 100 Torr, or another pressure range described herein.

Various features of the pedestal 104 will now be discussed. The pedestal 104 includes a heater 122 (encompassed by the dashed rectangle in FIG. 5) that has a plurality of LEDs 124 that are configured to emit visible light having wavelengths including and between 400 nm to 800 nm, including 450 nm. The heater LEDs emit this visible light onto the backside of the substrate, which heats the substrate. Visible light having wavelengths from about 400 nm to 800 nm is able to quickly and efficiently heat silicon wafers from ambient temperature, e.g., about 20° C., to about 600° C. because silicon absorbs light within this range. In contrast, radiant, including infrared radiant, heating may ineffectively heat silicon at temperatures up to about 400° C. because silicon tends to be transparent to infrared at temperatures lower than about 400° C. Additionally, radiant heaters that directly heat the topside of a wafer, as in many conventional semiconductor processes, can cause damage or other adverse effects to the topside films. Traditional “hot plate” heaters that rely on solid-to-solid thermal transference between the substrate and a heating platen, such as a pedestal with a heating coil, have relatively slow to heating and cooling rates, and provide nonuniform heating which may be caused by substrate warping and inconsistent contact with the heating platen. For example, it may take multiple minutes to heat a traditional pedestal to a desired temperature, and from a first to a second higher temperature, as well as to cool the pedestal to a lower temperature.

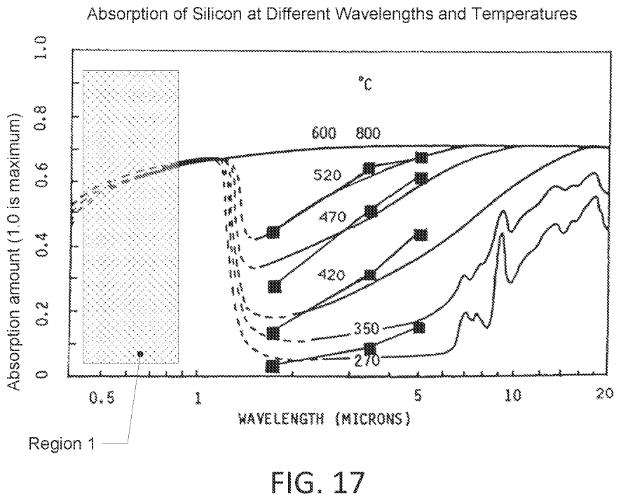

FIG. 17 depicts a graph of silicon absorption at various wavelengths and temperatures. The x-axis is light wavelength, the vertical axis is absorption with 1.0 being the maximum (i.e., 100%); the data is light absorption of silicon at different temperatures. As can be seen, in Region 1, silicon's absorption of light between 400 nm to 800 nm remains relatively constant with changes in the silicon's temperature. However, the silicon's absorption of infrared light, i.e., light with wavelengths above about 1 micron, changes with the temperature of the silicon such that the silicon absorption is inconsistent until the temperature reaches 600° C. Additionally, the absorption range for various wavelengths and temperatures is reduced as compared to the visible range. For example, silicon at 270° C. has a very low absorption rate, about 0.05 or 5%, for infrared emissions from about 1.8 microns to about 6 microns, and then inconsistent rates from about 6 microns to 10 microns. Silicon at 350° C. has the next lowest absorption rate of infrared light, ranging between about 10% and 20% from about 1.8 microns to about 5 microns. Accordingly, using visible light results in consistent absorption independent of the silicon's temperature.

The heater's plurality of LEDs may be arranged, electrically connected, and electrically controlled in various manners. Each LED may be configured to emit a visible blue light and/or a visible white light. In certain embodiments, white light (produced using a range of wavelengths in the visible portion of the EM spectrum) is used. In some semiconductor processing operations, white light can reduce or prevent unwanted thin film interference. For instance, some substrates have backside films that reflect different light wavelengths in various amounts, thereby creating an uneven and potentially inefficient heating. Using white light can reduce this unwanted reflection variation by averaging out the thin film interference over the broad visible spectrum provided by white light. In some instances, depending on the material on the back face of the substrate, it may be advantageous to use a visible non-white light, such as a blue light having a 450 nm wavelength, for example, in order to provide a single or narrow band of wavelength which may provide more efficient, powerful, and direct heating of some substrates that may absorb the narrow band wavelength better than white light.

Various types of LED may be employed. Examples include a chip on board (COB) LED or a surface mounted diode (SMD) LED. For SMD LEDs, the LED chip may be fused to a printed circuit board (PCB) that may have multiple electrical contacts allowing for the control of each diode on the chip. For example, a single SMD chip is typically limited to having three diodes (e.g., red, blue, or green) that can be individually controllable to create different colors, for instance. SMD LED chips may range in size, such as 2.8×2.5 mm, 3.0×3.0 mm, 3.5×2.8 mm, 5.0×5.0 mm, and 5.6×3.0 mm. For COB LEDs, each chip can have more than three diodes, such as nine, 12, tens, hundreds or more, printed on the same PCB. COB LED chips typically have one circuit and two contacts regardless of the number of diodes, thereby providing a simple design and efficient single color application. The ability and performance of LEDs to heat the substrate may be measured by the watts of heat emitted by each LED; these watts of heat may directly contribute to heating the substrate.

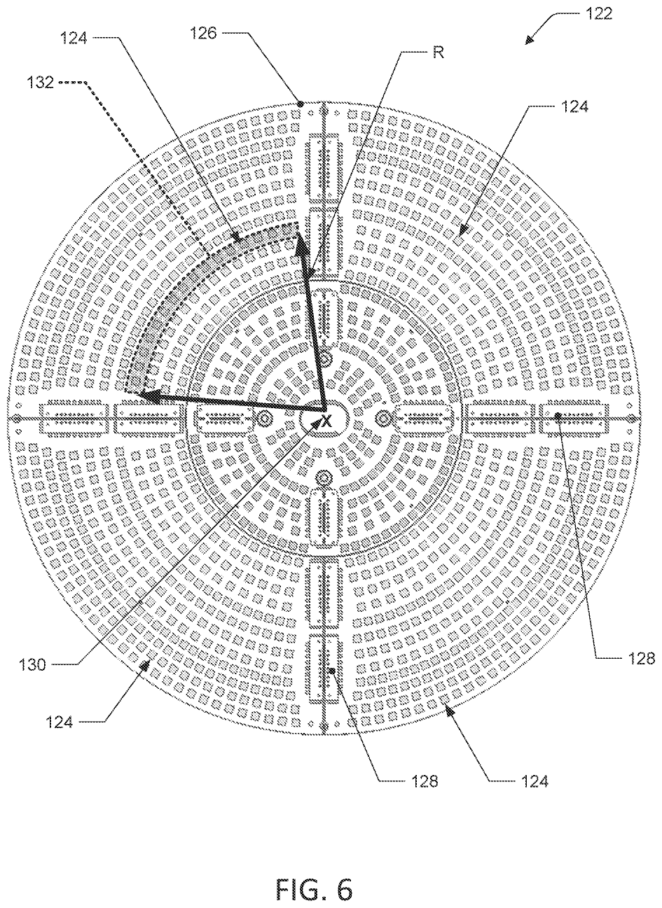

FIG. 6 depicts a top view of a substrate heater with a plurality LEDs. This substrate heater 122 includes a printed circuit board 126 and the plurality of LEDs 124, some of which are labeled; this depicted plurality includes approximately 1,300 LEDs. External connections 128 are connected by traces to provide power to the plurality of LEDs 124. As illustrated in FIG. 6, the LEDs may be arranged along numerous arcs that are radially offset from the center 130 of the substrate heater 122 by different radiuses; in each arc, the LEDs may be equally spaced from each other. For example, one arc 132 is surrounded by a partially shaded dotted shape, includes 16 LEDs 124, and is a part of a circle with a radius R that extends around the center 130. The 16 LEDs 124 may be considered equally spaced from each other along this arc 132.

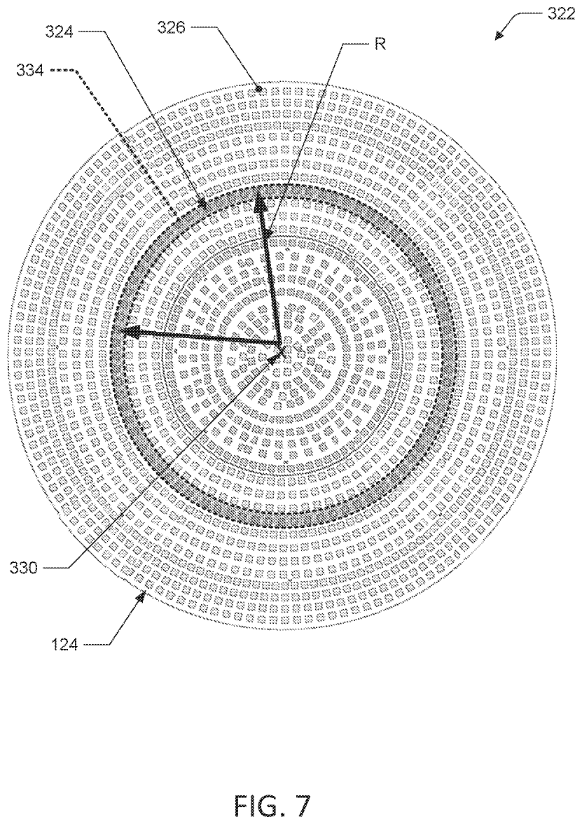

In some embodiments, the LEDs may also be arranged along circles around the center of the substrate heater. In some instances, some LEDs may be arranged along circles while others may be arranged along arcs. FIG. 7 depicts a top view of another example of a substrate heater with a plurality LEDs. This substrate heater 322 includes a printed circuit board 326 and the plurality of LEDs 324, some of which are labeled. Here, LEDs 324 are arranged along numerous circles that are radially offset from the center 330 of the substrate heater 322 by different radiuses; in each circle, the LEDs may be equally spaced from each other. For example, one circle 334 is surrounded by a partially shaded ring, includes 78 LEDs 324, a radius R that extends around the center 330. The 78 LEDs 324 may be considered equally spaced from each other along this circle 334. The arrangement of the LEDs in FIG. 7 may provide a more uniform light and heat distribution pattern across the entire backside of the substrate because the regions of the substrate heater 122 in FIG. 6 that contain the external connections may provide unheated cold spots on the wafer, especially because the substrate and heater remain stationary with respect to each other during processing; the substrate and the substrate heater do not rotate.

In some embodiments, the plurality of LEDs may include at least about 1,000 LEDs, including about 1,200, 1,500, 2,000, 3,000, 4,000, 5,000, or more than 6,000, for instance. Each LED may, in some instances, be configured to uses 4 watts or less at 100% power, including 3 watts at 100% power and 1 watt at 100% power. These LEDs may be arranged and electrically connected into individually controllable zones to enable temperature adjustment and fine tuning across the substrate. In some instances, the LEDs may be grouped into at least 20, for instance, independently controllable zones, including at least about 25, 50, 75, 80, 85 90, 95, or 100 zones, for instance. These zones may allow for temperature adjustments in the radial and azimuthal (i.e., angular) directions. These zones can be arranged in a defined pattern, such as a rectangular grid, a hexagonal grid, or other suitable pattern for generating a temperature profile as desired. The zones may also have varying shapes, such as square, trapezoidal, rectangular, triangular, obround, elliptical, circular, annular (e.g., a ring), partially annular (i.e., an annular sector), an arc, a segment, and a sector that may be centered on the center of the heater and have a radius less than or equal to the overall radius of the substrate heater's PCB. For example, in FIG. 6 the LEDs have 88 zones that are organized into at least 20, such as 20 or 21, concentric rings. These zones are able to adjust the temperature at numerous locations across the wafer in order to create a more even temperature distribution as well as desired temperature profiles, such as higher temperatures around the edge of the substrate than in the center of the substrate. The independent control of these zones may also include the ability to control the power output of each zone. For example, each zone may have at least 15, 20, or 25 adjustable power outputs. In some instances, each zone may have one LED thereby enabling each LED to be individually controlled and adjusted which can lead to a more uniform heating profile on the substrate. Accordingly, in some embodiments, each LED of the plurality of LEDs in the substrate heater may be individually controllable.

In certain embodiments, the substrate heater 122 is configured to heat the substrate to multiple temperatures and maintain each such temperatures for various durations. These durations may include the following non-limiting examples of at least about 1 second, at least about 5 seconds, at least about 10 seconds, at least about 30 seconds, at least about 60 seconds, at least about 90 seconds, at least about 120 second, at least about 150 seconds, or at least about 180 seconds. The substrate heater may be configured to heat the substrate to between about 50° C. and 600° C., including between about 50° C. and 150° C., including about 130° C., or between about 150° C. and 350° C., for example. Other possible temperature ranges are discussed above. The substrate heater may be configured to maintain the substrate at a temperature within these ranges for various durations, including the following non-limiting examples: at least about 1 second, at least about 5 seconds, at least about 10 seconds, at least about 30 seconds, at least about 60 seconds, at least about 90 seconds, at least about 120 seconds, at least about 150 seconds, or at least about 180 seconds, for example. Additionally, in some embodiments, the substrate heater 122 is configured to heat the substrate to any temperature within these ranges in less than about 60 seconds, less than about 45 seconds, less than about 30 seconds, or less than about 15 seconds, for instance. In certain embodiments, the substrate heater 122 is configured to heat a substrate at one or more heating rates, such as between at least about 0.1° C./second and at least about 20° C./second, for example.

The substrate heater may increase the temperature of the substrate by causing the LEDs to emit the visible light at one or more power levels, including at least about 80%, at least about 90%, at least about 95%, or at least about 100% power. In some embodiments, the substrate heater is configured to emit between about 10 W and 4000 W, including at least about 10 W, at least about 30 W, at least about 0.3 kilowatt (kW), at least about 0.5 kW, at least about 2 kW, at least about 3 kW, or at least about 4 kw. The apparatus is configured to supply between about 0.1 kw and 9 kW of power to the pedestal; the power supply is connected to the substrate heater through the pedestal but is not depicted in the Figures. During temperature ramps, the substrate heater may operate at the high powers, and may operate at the lower power levels (e.g., include between about 5 W and about 0.5 kW) to maintain the temperature of a heated substrate.

The pedestal may include reflective material on its internal surfaces that, during operation, reflects and directs the light emitted by the LEDs onto the backside of the substrate supported by the pedestal. In some such embodiments, the substrate heater may include such reflective material positioned on a top surface 140, as shown in FIG. 5, of the PCB 126 on which the plurality of LEDs 124 is positioned. The reflective material may be comprised of aluminum, such as polished aluminum, stainless steel, aluminum alloys, nickel alloys, and other protective layers which can prevent oxidation of the metal and/or enhance the reflectivity at specific wavelengths, such as reaching greater than 99% reflectivity for specific wavelengths, and other durable reflective coatings. Additionally or alternatively, the pedestal 104 may have a bowl 146 in which the substrate heater 122 is at least partially positioned. The bowl 146 may have exposed internal surfaces 148 of the pedestal sidewalls 149 upon which the reflective material may be positioned. This reflective material increases the heating efficiency of the substrate heater and reduces the unwanted heating of the PCB 126 and pedestal 104 by advantageously directing light back onto the substrate that would have otherwise been absorbed by the PCB 126 and the pedestal 104.

In some embodiments, the substrate heater may also include a pedestal cooler that is thermally connected to the LEDs such that heat generated by the plurality of LEDs can be transferred from the LEDs to the pedestal cooler. This thermal connection is such that heat can be conducted from the plurality of LEDs to the pedestal cooler along one or more heat flow pathways between these components. In some instances, the pedestal cooler is in direct contact with one or more elements of the substrate heater, while in other instances other conductive elements, such as thermally conductive plates (e.g., that comprise a metal) are interposed between the substrate heater and the pedestal cooler. Referring back to FIG. 5, the substrate heater includes a pedestal cooler 136 in direct contact with the bottom of the PCB 126. Heat is configured to flow from the LEDs, to the PCB 126, and to the pedestal cooler 136. The pedestal cooler 136 also includes a plurality of fluid conduits 138 through which a heat transfer fluid, such as water, is configured to flow in order to receive the heat and thus cool the LEDs in the substrate heater 122. The fluid conduits 138 may be connected to a reservoir and pump, not pictured, located outside the chamber. In some instances, the pedestal cooler may be configured to flow water that is cooled, such as between about 5° C. and 20° C.

As provided herein, it may be advantageous to actively heat the exterior surfaces of the processing chamber 102. In some instances, it may similarly be advantageous to heat the exterior surfaces of the pedestal 104 in order to prevent unwanted condensation and deposition on its external surfaces. As illustrated in FIG. 5, the pedestal 104 may further include a pedestal heater 144 inside of the pedestal 104 that is configured to heat the exterior surfaces of the pedestal 104, including its sides 142A and bottom 142B. The pedestal heater 144 may include one or more heating elements, such as one or more resistive heating elements and fluid conduits in which a heating fluid is configured to flow. In some instances, the pedestal cooler and the pedestal heater may both have fluid conduits that are fluidically connected to each other such that the same heat transfer fluid may flow in both the pedestal cooler and the pedestal heater. In these embodiments, the fluid may be heated to between 50° C. and 130° C. including about 90° C. and 120° C.

The pedestal may also include a window to protect the substrate heater, including the plurality of LEDs, from damage caused by exposure to the processing chemistries and pressures used during processing operations. As illustrated in FIG. 5, the window 150 may be positioned above the substrate heater 122 and may be sealed to the sidewall 149 of the pedestal 104 in order to create a plenum volume within the pedestal that is fluidically isolated from the chamber interior. This plenum volume may also be considered the inside of the bowl 146. The window may be comprised of one or more materials that are optically transparent to the visible light emitted by LEDs, including light having wavelengths in the range of 400 nm to 800 nm. In some embodiments, this material may be quartz, sapphire, quartz with a sapphire coating, or calcium fluoride (CaF). The window may also not have any holes or openings within it. In some embodiments, the heater may have a thickness of 15 to 30 mm, including 20 mm and 25 mm.

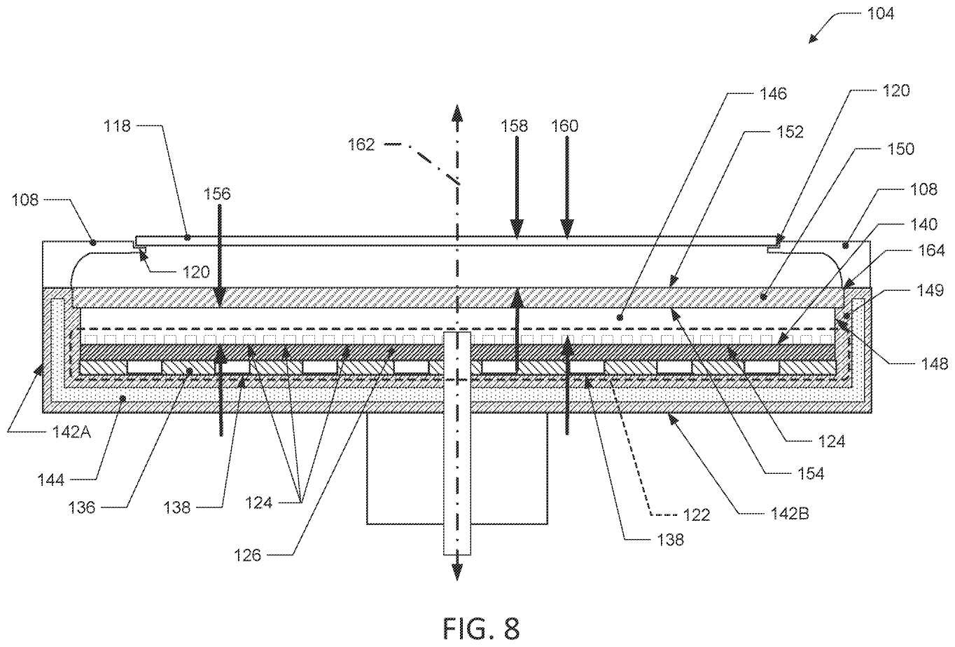

FIG. 8 depicts the pedestal of FIG. 5 with additional features in accordance with various embodiments. As identified in FIG. 8, the window 150 includes a top surface 152 that faces the substrate 118 supported by the pedestal 104, and a bottom surface 154 that faces the substrate heater 122. In some embodiments, the top and the bottom surfaces 152 and 154 may be flat, planar surfaces (or substantially flat, e.g., within +10% or 5% of flat). In some other instances, the top 152, bottom 154, or both top 152 and bottom 154 may be nonplanar surfaces. The nonplanarity of these surfaces may be configured to refract and/or direct the light emitted by the substrate heater's 122 LEDs 124 to more efficiently and/or effectively heat the wafer. The nonplanarity may also be along some or all of the surface. For example, the entire bottom surface may have a convex or concave curvature, while in another example an outer annular region of the bottom surface may have a convex or concave curvature while the remaining portion of the surface is planar. In further examples, these surfaces may have multiple, but different, nonplanar sections, such as having a conical section in the center of the surface that is adjacent to a planar annular section, that is adjacent to a conical frustum surface at the same or different angle as the conical section. In some embodiments, the window 150 may have features that act as an array of lenses which are oriented to focus the light emitted by one or more LEDs, such as each LED.

With the window 150 positioned above the substrate heater 122, the window 150 gets heated by the substrate heater 122 which can affect the thermal environment around the substrate. Depending on the material or materials used for the window 150, such as quartz, the window may retain heat and progressively retain more heat over the course of processing one or more substrates. This heat can get radiatively transferred to the substrate and therefore directly heat the substrate. In some instances, the window can cause a temperature increase of between 50° C. and 80° C. above the heater temperature. This heat may also create a temperature gradient through the thickness, or in the vertical direction, of the window. In some instances, the top surface 152 is 30° C. hotter than the bottom surface 154. It may therefore be advantageous to adjust and configure the chamber to account for and reduce the thermal effects of the window. As described in more detail below, this may include detecting the substrate's temperature and adjusting the substrate heater to account for the heat retained by the window.

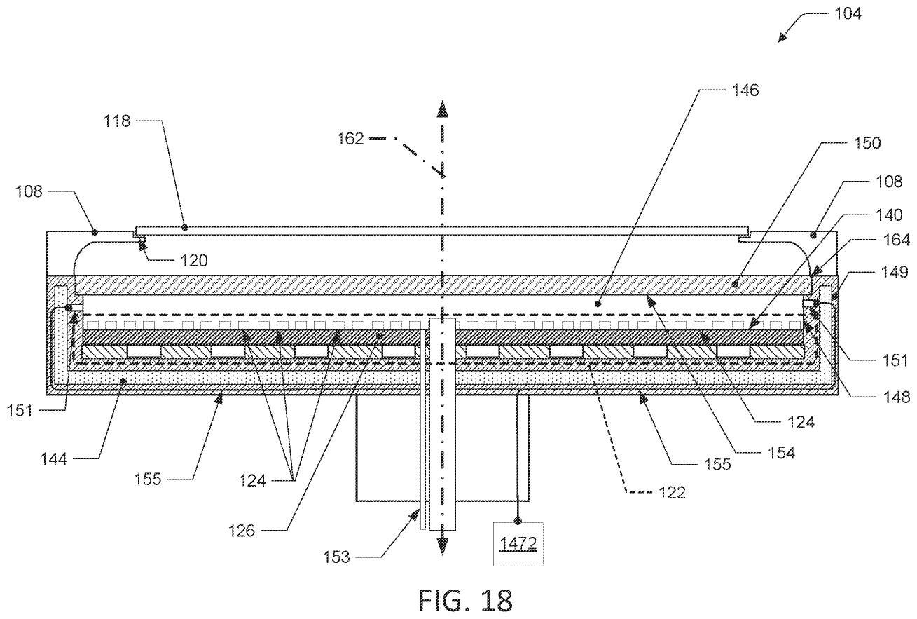

This may also include various configurations of the pedestal, such as actively cooling the window. In some embodiments, like that shown in FIGS. 5 and 8, the window 150 may be offset from the substrate heater 122 by a first distance 156. In some embodiments, this first distance may be between about 2 mm and 50 mm, including between about 5 mm and 40 mm. A cooling fluid, such as an inert gas, may be flowed between the window 150 and the substrate heater 122 in order to cool both the window 150 and the substrate heater 122. The pedestal may have one or more inlets and one or more outlets for flowing this gas within the plenum volume, or bowl 146, of the pedestal 104. The one or more inlets are fluidically connected to the inert gas source outside the chamber 102, which may include through fluid conduits that may be at least partially routed inside the pedestal 104. The one or more outlets are fluidically connected to an exhaust or other environment outside the chamber 102, which may also be through fluid conduits running within the pedestal. In FIG. 18, which depicts the pedestal of FIG. 8 with additional features in accordance with various embodiments, one or more inlets 151 are positioned in the sidewalls 149 and extend through the surface 148; the one or more inlets are also fluidically connected to an inert gas source 1472 through, in part, fluid conduits 155 that are routed through the pedestal 104. A single outlet 153 is positioned in a center region, i.e., not in the exact center but in close proximity, of the substrate heater 122. In some embodiments, the one or more gas inlets and one or more outlets may be switched, such that the one or more outlets extend through the sidewalls 149 (i.e., they are items 151 in FIG. 18), and the one or more inlets may be the center region of the substrate heater 122 (i.e., they are item 153 in FIG. 18). In some embodiments, there may be more than one outlet; in some embodiments, there may only be a single gas inlet. In some embodiments, one or more gas inlets extend through the interior surface 148 of the pedestal sidewall 149 underneath the LED heater 122 and one or more gas outlets extend through another part of the pedestal sidewall 149, such as a mounting bracket between the LED heater 122 and the pedestal sidewall 149.

In some embodiments, the window may be placed in direct, thermal contact with the substrate heater and the pedestal cooler may be configured to cool both the PCB and the window. In some embodiments, as also shown in FIGS. 5 and 8, the window 150 may be thermally connected to the sidewalls 149 of the pedestal 104 in order to transfer some of the retained heat in the window 150 to the pedestal 104. This transferred heat may be further transferred out of the pedestal using, for instance, the pedestal heater 144 which may flow fluid through the pedestal 104 that is heated to between about 20° C. and 100° C., for instance. This heated fluid may be cooler than the temperature of the pedestal 104 at the thermal connection with the window 150. In some embodiments, the window 150 may have one or more fluid conduits within the window 150 through which transparent cooling fluid may be configured to flow. These conduits may be of various arrangements in order to provide even cooling and temperature distribution within the window, such as a single flowpath with a single inlet, a single outlet, and a serpentine section. The fluid may be routed to the window through the pedestal from a fluid source or reservoir outside the chamber.

As shown in FIGS. 5 and 8, the pedestal's 104 substrate supports 108 are configured to support the substrate 118 above and offset from the window 150 and the substrate heater 122. In certain embodiments, the temperature of the substrate can be rapidly and precisely controlled by thermally floating, or thermally isolating, the substrate within the chamber. The heating and cooling of a substrate is directed at both the substrate's thermal mass and the thermal masses of other items in contact with the substrate. For instance, if the substrate is in thermal contact with a large body, such as the entirety of the substrate's back side resting on a large surface of a pedestal or electrostatic chuck as in many conventional etching apparatuses, this body acts as a heat sink for the substrate which affects the ability to accurately control the substrate temperature and reduces the quickness of substrate heating and cooling. It is therefore desirable to position the substrate so that the smallest thermal mass is heated and cooled. This thermal floating is configured to position the substrate so that it has minimal thermal contact (which includes direct and radiation) with other bodies in the chamber.

The pedestal 104 is therefore configured, in some embodiments, to support the substrate 118 by thermally floating, or thermally isolating, the substrate within the chamber interior 114. The pedestal's 104 plurality of substrate supports 108 are configured to support the substrate 118 such that the thermal mass of the substrate 118 is reduced as much as possible to the thermal mass of just the substrate 118. Each substrate support 108 may have a substrate support surface 120 that provides minimal contact with the substrate 118. The number of substrate supports 108 may range from at least 3 to, for example, at least 6 or more. The surface area of the support surfaces 120 may also be the minimum area required to adequately support the substrate during processing operations (e.g., in order to support the weight of the substrate and prevent inelastic deformation of the substrate). In some embodiments, the surface area of one support surface 120 may be less than about 0.1%, less than about 0.075%, less than about 0.05%, less than about 0.025%, or less than about 0.01%, for instance.

The substrate supports are also configured to prevent the substrate from being in contact with other elements of the pedestal, including the pedestal's surfaces and features underneath the substrate. As seen in FIGS. 5 and 8, the substrate supports 108 hold the substrate 118 above and offset from the next adjacent surface of the pedestal 104 below the substrate 118, which is the top surface 152 (identified in FIG. 8) of the window 150. As can be seen in these Figures, a volume or gap exists underneath the substrate, except for the contact with the substrate supports. As illustrated in FIG. 8, the substrate 118 is offset from the top surface 152 of the window 150 by a distance 158. This distance 158 may affect the thermal effects caused by the window 150 to the substrate 118. The larger the distance 158, the less the effects. It was found that a distance 158 of 2 mm or less resulted in a significant thermal coupling between the window and the substrate; it is therefore desirable to have a larger distance 158 than 2 mm, such as at least about 5 mm, about 10 mm, about 15 mm, about 20 mm, about 30 mm, about 50 mm, or about 100 mm, for example.

The substrate 118 is also offset from the substrate heater 122 (as measured in some instances from a top surface of the substrate heater 122 which may be the top surface of the LEDs 124) by a distance 160. This distance 160 affects numerous aspects of heating the substrate 118. In some instances, the LEDs 124 provide a nonuniform heating pattern, which increases as the distance 160 decreases; conversely, this nonuniform heating pattern is reduced by increasing the distance 160. In some instances as the distance 160 increases, the heating efficiency decreases across the substrate and decreases more in the edge region and causes nonuniform heating of the substrate. In some embodiments, a distance 160 of between about 5 mm and about 100 mm, for example between about 10 mm and about 90 mm, or between about 10 mm and about 30 mm, or between about 15 mm and 25 mm, provides a substantially uniform heating pattern and acceptable heating efficiency.

As stated, the substrate supports 108 are configured to support the substrate 118 above the window. In some embodiments, these substrate supports are stationary and fixed in position; they are not lift pins or a support ring. In some embodiments, at least a part of each substrate support 108 that includes the support surface 120 may be comprised of a material that is transparent at least to light emitted by LEDS 124. This material may be, in some instances, quartz or sapphire. The transparency of these substrate supports 108 may enable the visible light emitted by the substrate heater's 122 LEDs to pass through the substrate support 108 and to the substrate 118 so that the substrate support 108 does not block this light and the substrate 118 can be heated in the areas where it is supported. This may provide a more uniform heating of the substrate 118 than with a substrate support comprising a material opaque to visible light. In some other embodiments, the substrate supports 108 may be comprised of a non-transparent material, such as zirconium dioxide (ZrO₂).

In some embodiments, such as those shown in FIG. 8, the substrate supports 108 may be positioned closer to a center axis 162 of the window than the outer diameter 164 of the window 150. In some instances, portions of these substrate supports may extend over and above the window 150 such that they overlap the window 150 such that the support surfaces 120 are above the window 150.

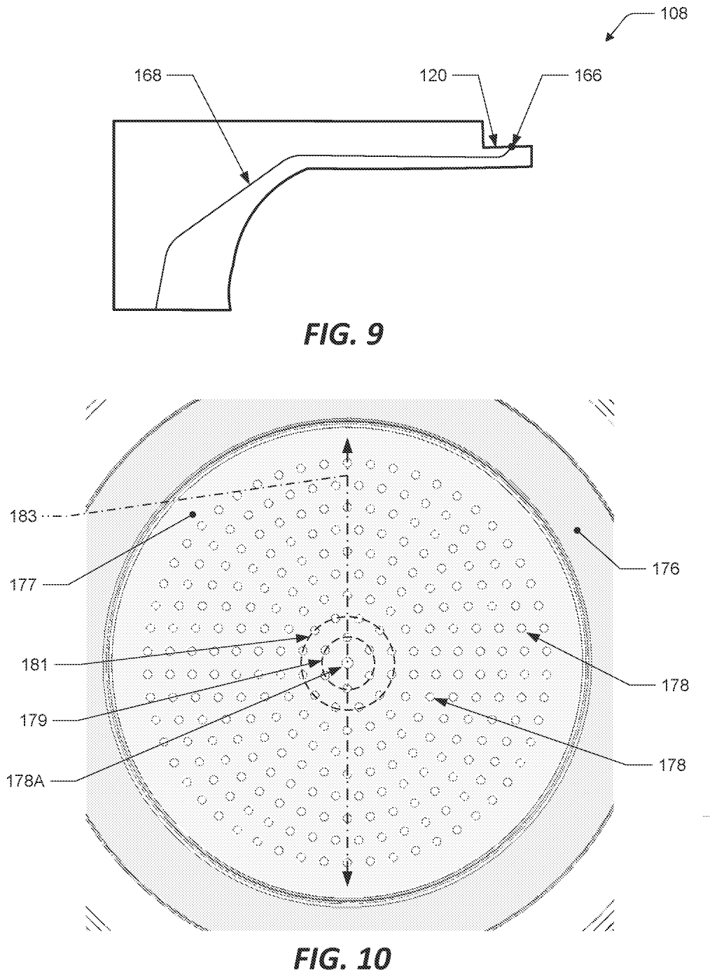

In some embodiments, the substrate supports may each contain a temperature sensor that is configured to detect the temperature of the substrate positioned on the support surface of the substrate supports. FIG. 9 depicts a substrate support of FIGS. 5 and 8 in accordance with disclosed embodiments. Here, the support surface 120 of the substrate support 108 is identified, along with a temperature sensor 166. In some embodiments, this temperature sensor 166 extends through the support surface 120 such that the temperature sensor 166 is in direct contact with a substrate held by the support surface 120. In some other embodiments, the temperature sensor 166 is positioned within the substrate support 108 and below the support surface 120. In some embodiments, this temperature sensor 166 is a thermocouple. In some other embodiments, the temperature sensor 166 may be a thermistor, a resistance temperature detector (RTD), and semiconductor sensor. The electrical wiring 168 for the temperature sensor 166 may be routed through the substrate support 108 and may also be routed through the pedestal 104.

Referring back to FIG. 5, in some embodiments, the pedestal is also configured to move vertically. This may include moving the pedestal such that a gap 186 between a faceplate 176 of the gas distribution unit 110 and the substrate 118 is capable of being in a range of 2 mm and 70 mm. As provided in more detail below, moving the pedestal vertically may enable active cooling of the substrate as well as rapid cycling time of processing operations, including flowing gas and purging, due to a low volume created between the gas distribution unit 110 and the substrate 118. This movement may also enable the creation of a small process volume between the substrate and the gas distribution unit which can result in a smaller purge and process volume and thus reduce purge and gas movement times and increase throughput.

The gas distribution unit 110 is configured to flow process gases, which may include liquids and/or gases, such as a reactant, modifying molecules, converting molecules, or removal molecules, onto the substrate 118 in the chamber interior 114. As seen in FIG. 5, the gas distribution unit 110 includes one or more fluid inlets 170 that are fluidically connected to one or more gas sources 172 and/or one or more vapor sources 174. In some embodiments, the gas lines and mixing chamber may be heated to prevent unwanted condensation of the vapors and gases flowing within. These lines may be heated to at least about 40° C., at least about 80° C., at least about 90° C., or at least about 120° C., at least about 130° C., or at least about 150° C. The one or more vapor sources may include one or more sources of gas and/or liquid which is vaporized. The vaporizing may be a direct inject vaporizer, a flow over vaporizer, or both. The gas distribution unit 110 also includes the faceplate 176 that includes a plurality of through-holes 178 that fluidically connect the gas distribution unit 110 with the chamber interior 114. These through-holes 178 are fluidically connected to the one or more fluid inlets 170 and also extend through a front surface 177 of the faceplate 176, with the front surface 177 configured to face the substrate 118. In some embodiments, the gas distribution unit 110 may be considered a top plate and in some other embodiments, it may be considered a showerhead.

The through-holes 178 may be configured in various ways in order to deliver uniform gas flow onto the substrate. In some embodiments, these through-holes may all have the same outer diameter, such as between about 0.03 inches and 0.05 inches, including about 0.04 inches (1.016 mm). These faceplate through-holes may also be arranged throughout the faceplate in order to create uniform flow out of the faceplate.

FIG. 10 depicts a plan view of first example faceplate 176 with the front surface 177 (the surface configured to face a substrate) and the through-holes 178 visible. As can be seen, the faceplate 176 through-holes 178 extend through the faceplate 176 and the front surface 177. These through-holes are also arranged along multiple circles that are centered around the center axis of the faceplate, thereby offsetting the holes from each other. For example, the faceplate 176 may have a through-hole 178A that is centered on the center axis of the faceplate 176. Immediately adjacent to this center through-hole 178A may be a plurality of holes arranged equally spaced along a first circle 179 with a first diameter; immediately radially outwards from this circle may be another circle 181 with a second plurality of holes having more holes than the plurality of holes, and this second plurality of holes may be equally spaced along this second circle. This equal spacing may not always be exact and may be considered substantially equally spaced, which may be due to manufacturing or other inconsistencies, such that the spacing may be within about +/−5% of equal. As illustrated, some circles of through-holes 178 may be centered on a referential datum 183, while other circles of the through-holes are offset from the referential datum 183 by an angle, such as about 15°, 7.5°, etc. Here, the through-holes along the first circle 179 two through-holes centered on the datum, while the through-holes along the second circle are not centered on the referential datum 183 and are offset from the datum 183 by about 15°. The concentric circles of through-holes may alternate between holes centered on the datum 183 and offset from the datum 183.

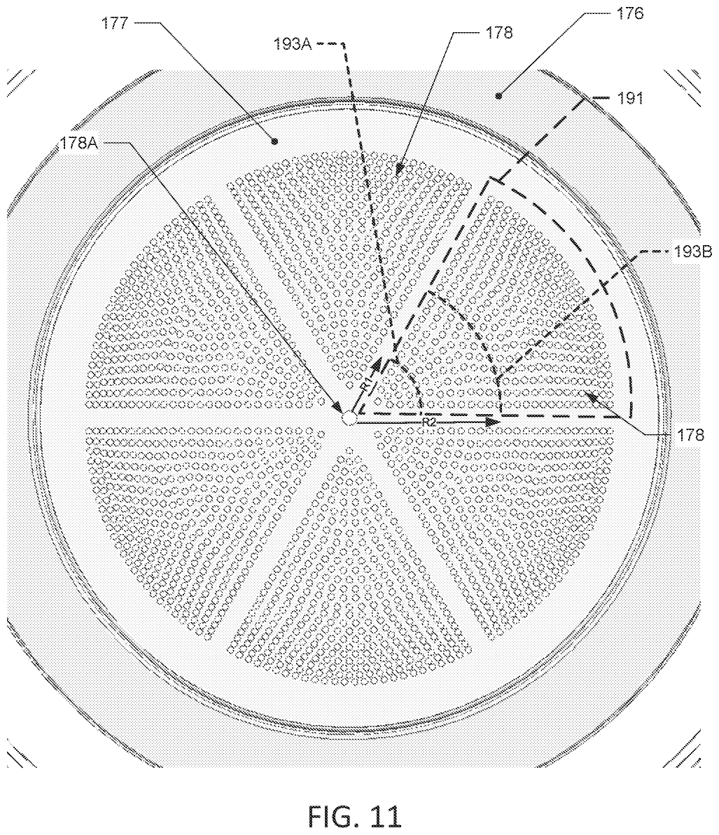

FIG. 11 depicts a plan view of second example faceplate 176 with the front surface 177 (the surface configured to face a substrate) and the through-holes 178 visible. As can be seen, the faceplate 176 through-holes 178 extend through the faceplate 176 and the front surface 177. These through-holes are arranged different than in FIG. 10, with one through-hole 178 centered on the center axis of the faceplate 176, and the through-holes 178 arranged in 6 sectors, such that in each sector, the through-holes are equally spaced along arcs in the sector. For instance, one sector 191 is contained with a dashed shape and the holes are arranged along a plurality of arcs within the sector that increase as their radial distance from the center of the faceplate 176 increases. A first example arc 193A is identified along which 6 through-holes 178 are equally spaced, and a second example arc 193B is identified along which 12 through-holes are equally spaced. The second example arc 193B is larger than the first example arc 193A and has a greater radial distance R2 than the first arc's 193A radial distance R1.

Referring back to FIG. 5, the gas distribution unit 110 may also include a unit heater 180 that is thermally connected to the faceplate 176 such that heat can be transferred between the faceplate 176 and the unit heater 180. The unit heater 180 may include fluid conduits in which a heat transfer fluid may be flowed. Similar to above, the heat transfer fluid may be heated to a temperature range of about 20° C. and 120° C., for example. In some instances, the unit heater 180 may be used to heat the gas distribution unit 110 to prevent unwanted condensation of vapors and gases; in some such instances, this temperature may be at least about 90° C. or 120° C.

In some embodiments, the gas distribution unit 110 may include a second unit heater 182 that is configured to heat the faceplate 176. This second unit heater 182 may include one or more resistive heating elements, fluid conduits for flowing a heating fluid, or both. Using two heaters 180 and 182 in the gas distribution unit 110 may enable various heat transfers within the gas distribution unit 110. This may include using the first and/or second unit heaters 180 and 182 to heat the faceplate 176 in order to provide a temperature-controlled chamber, as described above, in order to reduce or prevent unwanted condensation on elements of the gas distribution unit 110.

The apparatus 100 may also be configured to cool the substrate. This cooling may include flowing a cooling gas onto the substrate, moving the substrate close to the faceplate to allow heat transfer between the substrate and the faceplate, or both. Actively cooling the substrate enables more precise temperature control and faster transitions between temperatures which reduces processing time and improves throughput. In some embodiments, the first unit heater 180 that flows the heat transfer fluid through fluid conduits may be used to cool the substrate 118 by transferring heat away from the faceplate 176 that is transferred from the substrate 119. A substrate 118 may therefore be cooled by positioning it in close proximity to the faceplate 176, such as by a gap 186 of less than or equal to 5 mm or 2 mm, such that the heat in the substrate 118 is radiatively transferred to the faceplate 176, and transferred away from the faceplate 176 by the heat transfer fluid in the first unit heater 180. The faceplate 176 may therefore be considered a heat sink for the substrate 118 in order to cool the substrate 118.

In some embodiments, the apparatus 100 may further include a cooling fluid source 173 which may contain a cooling fluid (a gas or a liquid), and a cooler (not pictured) configured to cool the cooling fluid to a desired temperature, such as less than or equal to at least about 90° C., at least about 70° C., at least about 50° C., at least about 20° C., at least about 10° C., at least about 0° C., at least about −50° C., at least about −100° C., at least about −150° C., at least about −190° C., at least about −200° C., or at least about −250° C., for instance. The apparatus 100 includes piping to deliver the cooling fluid to the one or more fluid inlets 170, and the gas distribution unit 110 which is configured to flow the cooling fluid onto the substrate. In some embodiments, the fluid may be in liquid state when it is flowed to the chamber 102 and may turn to a vapor state when it reaches the chamber interior 114, for example if the chamber interior 114 is at a low pressure state, such as described above, e.g., between about 0.1 Torr and 100 Torr, or between about 20 Torr and 200 Torr, or between about 0.1 Torr and 10 Torr, for instance. The cooling fluid may be an inert element, such as nitrogen, argon, or helium. In some instances, the cooling fluid may include, or may only have, a non-inert element or mixture, such as hydrogen gas. In some embodiments, the flow rate of the cooling fluid into the chamber interior 114 may be at least about 0.25 liters per minute, at least about 0.5 liters per minute, at least about 1 liters per minute, at least about 5 liters per minute, at least about 10 liters per minute, at least about 50 liters per minute, or at least about 100 liters per minute, for example. In certain embodiments, the apparatus may be configured to cool a substrate at one or more cooling rates, such as at least about 5° C./second, at least about 10° C./second, at least about 15° C./second, at least about 20° C./second, at least about 30° C./second, or at least about 40° C./second.

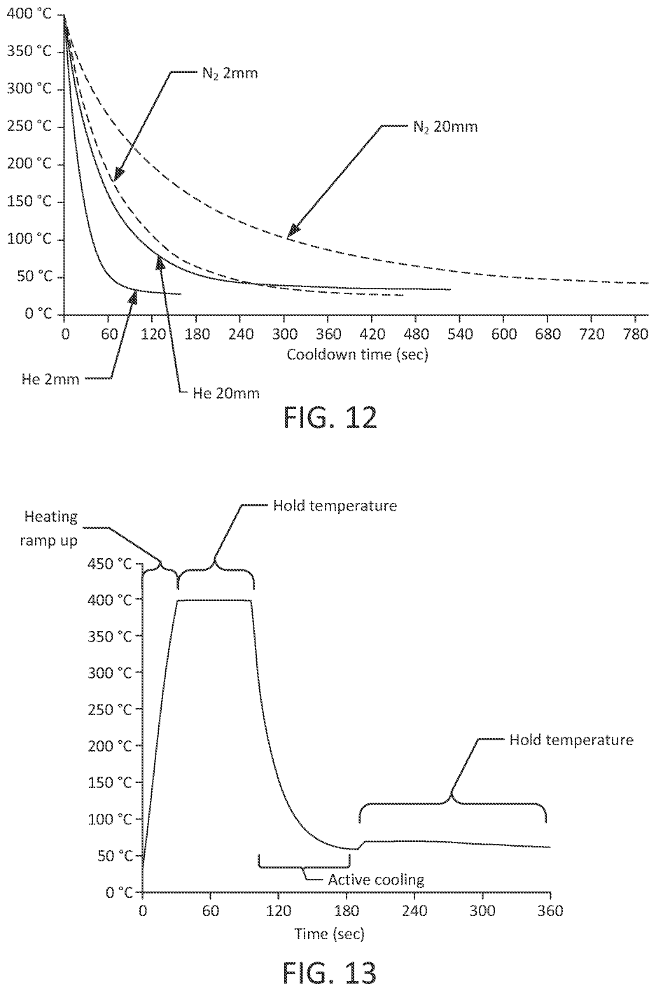

In some embodiments, the apparatus 100 may actively cool the substrate by both moving the substrate close to the faceplate and flowing cooling gas onto the substrate. In some instances, the active cooling may be more effective by flowing the cooling gas while the substrate is in close proximity to the faceplate. The effectiveness of the cooling gas may also be dependent on the type of gas used. FIG. 12 depicts a graph of four different active cooling experiments. In these four experiments the substrate was cooled from about 400° C. to about 25° C. using different gases and gaps between the substrate and the faceplate. In the first experiment, a 400° C. substrate was actively cooled by positioning the substrate 2 mm away from the faceplate and flowing helium gas onto the substrate (“He 2 mm”), in the second experiment, the 400° C. substrate was actively cooled by positioning the substrate 20 mm away from the faceplate and flowing helium gas onto the substrate (“He 20 mm”), in the third experiment, the 400° C. substrate was actively cooled by positioning the substrate 2 mm away from the faceplate and flowing nitrogen gas onto the substrate (“N2 2 mm”), and in the fourth experiment the 400° C. substrate was actively cooled by positioning the substrate 20 mm away from the faceplate and flowing nitrogen gas onto the substrate (“N2 20 mm”). As can be seen, the first experiment cooled the substrate in the fastest time, approximately 150 seconds, and the third experiment was the next fastest at approximately 450 seconds. These first and third experiments used both cooling gas and a gap of 2 mm, while the slower second and fourth experiments had a 20 mm gap.

The apparatuses provided herein can therefore rapidly heat and cool a substrate. FIG. 13 provides an example temperature control sequence. At time 0, the substrate is at approximately 20 or 25° C., and the LEDs of the substrate heater provided herein emit the visible light having wavelengths between 400 nm and 800 nm and cause the substrate temperature to rise to about 400° C. in approximately 30 seconds. This heating was accomplished using between 1 kW and 2 kW of heating power that is provided by approximately 9 kW of supplied power to the substrate heater. From about 30 seconds to about 95 seconds, the substrate heater 122 held the substrate at 400° C. using less power, such as 0.3 to about 0.5 kW of heating power provided by approximately 2 kW of supplied power. For about 30 to 60 seconds, the substrate was actively cooled using both cooling gas flowed onto the substrate (e.g., hydrogen or helium) and heat transfer to the faceplate. Once cooled, the substrate heater heated the substrate to hold its temperature at approximately 70° C. using between about 10 and 30 W of heating power provided by about 100 W of supplied power. Various processing techniques may use this type of sequence, either once or repeatedly, for processing a substrate.

In some embodiments, the apparatus 100 may include a mixing plenum for blending and/or conditioning process gases for delivery before reaching the fluid inlets 170. One or more mixing plenum inlet valves may control introduction of process gases to the mixing plenum. In some other embodiments, the gas distribution unit 110 may include one or more mixing plenums within the gas distribution unit 110. The gas distribution unit 110 may also include one or more annular flow paths fluidically connected to the through-holes 178 which may equally distribute the received fluid to the through-holes 178 in order to provide uniform flow onto the substrate.

The apparatus 100 may also include one or more additional non-contact sensors for detecting the temperature of the substrate. One such sensor may be anew pyrometer that is capable of detecting numerous temperature ranges of a silicon substrate. It is desirable to detect the temperature of substrates having different treatments, e.g., whether the silicon is doped or not doped, at different temperatures ranges at which processing operations may occur, such as under about 200° C., greater than about 200° C. and less than about 600° C., or above 600° C. However, traditional pyrometers are not able to detect different substrates within these ranges. Traditional pyrometers measure the optical signals reflected or emitted by an object's surface to determine the object's temperature according to some calibration. However, many silicon wafers cannot be measured by these pyrometers because the silicon is optically transparent at various temperatures and with various treatments. As discussed above, FIG. 17 shows different absorption rates for substrates at various temperatures. For example, a traditional pyrometer is capable of detecting emissions in a range of about 8-15 microns, but most silicon substrates under at least about 200° C. do not have an consistent emission signal in the range of about 8-15 microns and are therefore undetectable by a traditional pyrometer when under about 200° C.

Lightly doped, or undoped, silicon substrates have an emission signal from approximately 0.95 to 1.1 microns when the substrates are at or below about 300° C., that doped silicon substrates have an emission signal between about 1 and 4 microns when the substrates are below about 200° C., that silicon substrates have an emission signal at approximately 1 micron when around room temperature, such as under about 100° C. including, for instance 20° C., and that silicon substrates have an emission signal of about 8 to 15 microns when at temperatures over about 600° C. The new pyrometer is therefore configured to detect multiple emission ranges in order to detect multiple substrates, e.g., doped, low doped, or not doped, at various temperature ranges. This includes the configuration to detect emission ranges of about 0.95 microns to about 1.1 microns, about 1 micron, about 1 to about 4 microns, and/or about 8 to 15 microns. The new pyrometer is also configured to detect the temperature of a substrate at a shorter wavelength in order to differentiate the signal from the thermal noise of the chamber.

The new pyrometer may include an emitter configured to emit infrared signals and a detector configured to receive emissions. Referring to FIG. 5, the apparatus includes the new pyrometer 188 having an emitter within the pyrometer 188 and a detector 190. The new pyrometer may be configured to emit signals on one side of the substrate, either the top or the bottom, and configured to receive signals on the other side of the substrate. For instance, the emitter may emit signals on the top of the substrate and the detector is under the substrate and receives signals emitted through and under the substrate. The apparatus may therefore have at least a first port 192A on the top of the chamber 102, such as the port 192A through the center of the gas distribution unit 110, and a second port 192B through the pedestal 104 and substrate heater 122. The emitter in the pyrometer 188 may be connected to one of the ports 192A or 192B via a fiberoptic connection, such as the first port 192A as shown in FIG. 5, and the detector is optically connected to the other port, such as the second port 192B in FIG. 5. The first port 192A may include a port window 194 to seal the first port 192A from the chemistries within the chamber interior 114. The second port 192B is seen in FIG. 5 extending through the pedestal 104 and the substrate heater such that the emitter's emissions can pass through the substrate, through the window 150, into the second port 192B and to the detector 190 that may be positioned in the second port or optically connected to the second port through another fiberoptic connection (not shown). In some other embodiments, the emitter and the detector are flipped, such that the emitter emits through the second port 192B and the detector detects through the first port 192A.

The apparatus 100 may also include one or more optical sensors 198 to detect one or more metrics of the visible light emitted by the LEDs. In some embodiments, these optical sensors may be one or more photodetectors configured to detect the light intensity and/or thermal radiation of the visible light emitted by the LEDs of the substrate heater. In FIG. 5, a single optical sensor 198 is shown as connected to the chamber interior 114 via fiberoptic connection such that the optical sensor 198 is able to detect light emitted by the substrate heater 122. The optical sensor 198, and additional optical sensors, can be positioned in various locations in the top and sides, for instance, of the chamber 102 in order to detect the emitted light at various locations within the chamber 102. As discussed below, this may enable the measurement and adjustment of the substrate heater, such as the adjustment of one or more independently controllable zones of the LEDs. In some embodiments, there may be a plurality of optical sensors 198 arranged along a circle or multiple concentric circles in order to measure various regions of the LEDs throughout the chamber 102. In some embodiments, the optical sensors may be positioned inside the chamber interior 114.

In some embodiments, the apparatus may further be configured to generate a plasma and use the plasma for some processing in various embodiments. This may include having a plasma source configured to generate a plasma within the chamber interior, such as a capacitively coupled plasma (CCP), an inductively coupled plasma (ICP), an upper remote plasma, and a lower remote plasma.

The apparatuses described herein are not limited to ALE etching operations. These apparatuses may be used with any etching technique.

### Techniques for Thermal Processing

This section presents additional details regarding thermal processing methods that may apply in various embodiments. In some implementations, the chemistry described above is used in the context of performing the methods described in this section. In some embodiments, the methods described in relation to FIGS. 1-4 may be practiced according to some or all of the details provided in this section.

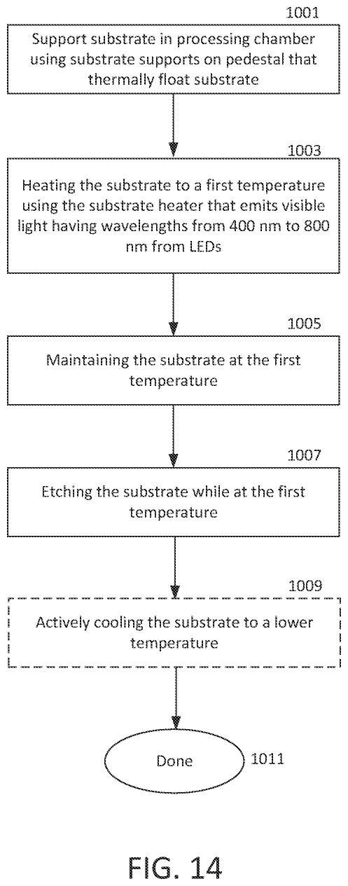

FIG. 14 depicts a first technique for thermal processing in accordance with disclosed embodiments. In operation 1001, the substrate is provided to the chamber and thermally floated in the chamber by positioning the substrate on the substrate supports of the pedestal; as described above, only the substrate support contact the substrate; it is not in contact with other elements of the processing chamber. Each substrate support contacts the edge region of the substrate as provided herein and shown in FIGS. 5 and 8, for instance.

In operation 1003, the substrate is heated to a first temperature while it is thermally floated in the chamber, i.e., while it is supported by only the substrate supports, using the substrate heater described herein that emits visible light having wavelengths between 400 nm and 800 nm from the plurality of LEDs. The first temperature may be any temperature provided herein, including between about 50° C. and about 600° C., including between about 20° C. and about 500° C., including between about 100° C. and about 500° C., including between about 20° C. and about 200° C., including between about 50° C. and about 150° C., including about 130° C., or between about 150° C. and about 350° C., for example. The substrate may be rapidly heated to the first temperature, such as in less than about 60 seconds, less than about 45 seconds, less than about 30 seconds, or less than about 15 seconds, for instance. This may include powering the LEDs to their maximum power, which together may be greater than or equal to at least about 1 kW, at least about 2 kW, at least about 3 kW, at least about 4 kW, or at least about 9 kW of delivered power. As provided herein, this heating does not include a plasma or plasma generation.

In operation 1005, the substrate is maintained at the first temperature. This may include the substrate heater operating at lower power in order to maintain the substrate at a specific temperature. The LEDs may therefore be at a lower non-zero power level than during a temperature ramp up to provide some heating and maintain the substrate at the desired temperature. Examples may include between about 5 W and about 0.5 kW, including at least about 10 W, at least about 30 W, at least about 0.3 kW, or at least about 0.5 kW.

In operation 1007, the substrate is etched while at the first temperature. This etching may include flowing one or more gases to remove one or more modified layers of material. This etching also does not include a plasma or plasma generation. In various embodiments herein, the etching chemistry includes the species described above, for example HF, an organic solvent and/or water, an additive, and a carrier gas.

In operation 1009, which may be optional in some embodiments, the substrate is actively cooled. This active cooling may include flowing the cooling the gas onto the substrate, moving the substrate in close proximity to the faceplate, or both as described herein. In some instances, this close proximity is less than or equal 5 mm, including 2 mm. The cooling gas may also include, for example, helium and nitrogen. Following operation 1009, in some instances, operations 1003 through 1009 may be repeated, with each sequence being considered a cycle.

In some embodiments, operations 1003, 1005, and 1007 may also be performed while the chamber walls, the faceplate, and/or the external surfaces of the pedestal are actively heated as described above. These items may be heated to between about 80° C. and about 130° C., including at least about 90° C. or at least about 120° C. Operations 1003, 1005, 1007, and 1009 may also be performed while the chamber interior is at a vacuum, which may be a pressure between about 0.1 Torr and about 10 Torr, or between about 0.2 Torr and about 10 Torr.

The techniques provided herein may make various adjustments to the processing conditions. In some embodiments, these adjustments may be based on various received measurements, such as measurements of the substrate's temperature and the LEDs. In some other embodiments, these adjustments may be performed in an open loop manner based on empirical or calculated data. In some embodiments, the techniques may follow a similar sequence as in FIGS. 13 and 14, for example. In some other embodiments, the sequence may perform etching or a part of one etching cycle with the substrate at a first temperature, followed by a temperature increase to a higher, second temperature at which another etching cycle, or another portion of the same etching cycle, is performed. After this, the substrate may be actively cooled, and the etching may be repeated on the same substrate or a new substrate.

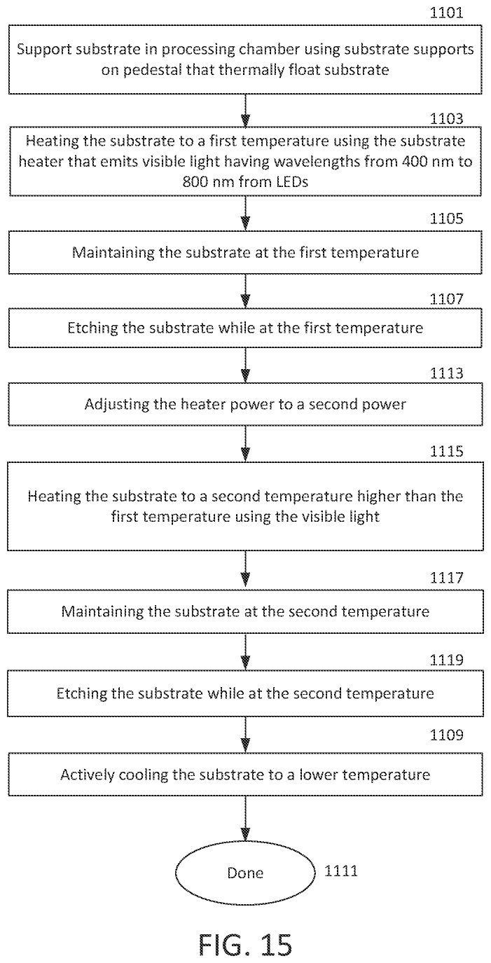

FIG. 15 depicts a second technique in accordance with disclosed embodiments. Here, operations 1101 through 1107 are the same as operations 1001 through 1007. After the etching of operation 1007, the heater power is adjusted in operation 1113 to a different power than used during the maintaining of operation 1005 in order to heat the substrate to a second, higher temperature as provided in operation 1115. The substrate's temperature may be maintained at this second temperature during another etching or modification of the substrate as indicated by operations 1117 and 1119. In various embodiments herein, the etching chemistry for operation 1119 includes the species described above, for example HF, an organic solvent and/or water, an additive, and a carrier gas. In some cases, the substrate may be modified at the second temperature, for example as described in relation to operation 205 in FIG. 2. In such cases, the chemistry used for operation 1107 may be selected to modify a material on the surface of the substrate in a desired manner. Following these operations, the substrate may be actively cooled in operation 1109. In some instances, the etching operations 1103 through 1109 may be repeated on the same substrate, or on a different substrate. While the first temperature is described as being lower than the second temperature, this feature is not limiting. In some embodiments, for example as described in relation to FIGS. 2 and 4, the first temperature (which may be used to drive modification of a material on the substrate surface) may be higher than the second temperature (which may be used to drive etching of the modified material on the substrate surface).

In some embodiments, the heating and maintaining operations may be based on empirical and measured data, such as empirically derived temperature drift of the apparatus, such as the window of the pedestal. As mentioned above, the window may retain heat throughout processing and act as an independent heater to the substrate. Adjustments may be made to the substrate heater in order to account for this drift, such as decreasing the overall power delivered to the LEDs of the substrate heater during the maintaining and etching operations, such as 1005, 1105, 1007, and 1107. These adjustments may be linear or non-linear, such as stepped or curved. This may also include adjustments to only some of the LEDs, such as to one or more of the independently controlled zones. For example, the center of the window may generate the most heat over time because the heat may not be able to be removed, while the edges of the window generate the least heat because some of this heat is transferred to the pedestal. Accordingly, to maintain uniform heating, one or more independently controllable zones of LEDs in the center of the substrate heater may be lowered to account for the increased heat in the center of the window. This may result in the same heat transferred to the substrate in the center region, with the heat generated by both the window and the substrate heater. Similarly, one or more independently controllable zones of LEDs in the outer region of the substrate heater may be lowered or kept the same to account for any additional heating, if any, caused by the exterior edge of the window.

In some embodiments as mentioned above, each LED may be individually controllable and in some such embodiments, a single LED may be adjusted to emit more or less light than one or more other LEDs. This adjustment may be made to account for a hot or cold spot on the substrate. For example, a spot on the wafer may have a temperature hotter or colder than other portions of the substrate and one LED underneath, or in close proximity to, that spot on the substrate may be adjusted to adjust the temperature at that spot. This may include decreasing the light emitted by the one LED to reduce the temperature at that spot or increasing the light emitted by the one LED to increase the temperature at that spot.

The techniques provided herein may also include feedback control loops for adjusting operating parameters, such as the power of one or more zones of the LEDs. These feedback loops may be implemented during the heating, maintaining, and etching operations described herein. This may include the using one or more of the sensors described herein to determine temperatures at the edge and in one or more locations on the substrate interior and adjust the substrate heater based on these measurements.

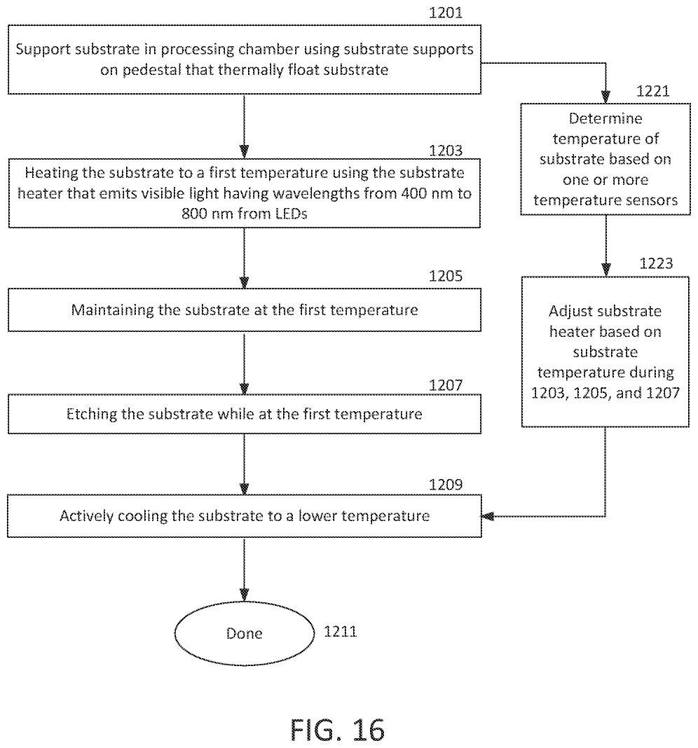

FIG. 16 depicts a third technique in accordance with disclosed embodiments. Here, operations 1201 through 1211 are the same as operations 1001 through 1011, except that the technique here measures the substrate temperature during one or more of these operations and adjusts the substrate heater based on these measurements. The temperature measurements are represented by operation 1221 and the adjustment(s) is represented by operation 1223. The adjustments to the substrate heater may include increasing or decrease the power to one or more of the independently controllable zones of LEDs, including all of the LEDs. For instance, the temperature sensors in the substrate supports, as described above with respect to FIG. 9, may indicate that the substrate edge has reached, or is above, the first temperature during one or more of operations 1203, 1205, and 1207, and the power delivered to all of the LEDs may be decreased in order to lower the temperature of the substrate. This may indicate a determination that at least one of the sensors indicates that the temperature of the substrate is above a particular threshold, such as above the first temperature. In another example, only one of the substrate supports may indicate that the substrate temperature is higher than the first temperature and adjustments may be made to independently controllable LED zones around this one sensor to decrease the heat delivered at that location as opposed to the entire substrate.

Similarly, the pyrometer described above may also detect the temperature of the substrate at a location on the substrate, such as its center. This temperature measurement may also be used, alone or in combination with the temperature sensors in the substrate supports, to adjust the substrate heater. For example, the pyrometer may indicate that the substrate center is higher than the first temperature and adjustments may be made to independently controllable LED zones around the center of the substrate, or to the whole substrate, in order to reduce the substrate's temperature at this location. While these examples are made with respect to decreasing power of LEDs, the adjustments are not limited to such examples; the power of one or more independently controllable LED zones may be adjusted to increase the temperature at one or more locations on the substrate.

Another technique may measure the light emitted by the LEDs and adjust one or more independently controllable LED zones based on that measuring. This may include emitting the emitting visible light that has wavelengths between 400 nm and 800 nm from the LEDs, and measuring, using one or more sensors configured to detect the visible light emitted from the plurality of LEDs, one or more metrics of the visible light emitted by the LEDs. These sensors may include a photodetector described above. Based on this measured visible light, the power of one or more LED zones may be adjusted.

In some embodiments, the apparatuses described herein may include a controller that is configured to control various aspects of the apparatus in order to perform the techniques described herein. For example, referring back to FIG. 5, apparatus 100 includes a controller 131 (which may include one or more physical or logical controllers) that is communicatively connected with and that controls some or all of the operations of a processing chamber. The system controller 131 may include one or more memory devices 133 and one or more processors 135. In some embodiments, the apparatus includes a switching system for controlling flow rates and durations, the substrate heating unit, the substrate cooling unit, the loading and unloading of a substrate in the chamber, the thermal floating of the substrate, and the process gas unit, for instance, when disclosed embodiments are performed. In some embodiments, the apparatus may have a switching time of up to about 500 ms, or up to about 750 ms. Switching time may depend on the flow chemistry, recipe chosen, reactor architecture, and other factors.

In some implementations, the controller 131 is part of an apparatus or a system, which may be part of the above-described examples. Such systems or apparatuses can include semiconductor processing equipment, including a processing tool or tools, chamber or chambers, a platform or platforms for processing, and/or specific processing components (a gas flow system, a substrate heating unit, a substrate cooling unit, etc.). These systems may be integrated with electronics for controlling their operation before, during, and after processing of a semiconductor wafer or substrate. The electronics may be referred to as the “controller,” which may control various components or subparts of the system or systems. The controller 131, depending on the processing parameters and/or the type of system, may be programmed to control any of the processes disclosed herein, including the delivery of processing gases, temperature settings (e.g., heating and/or cooling), pressure settings, vacuum settings, power settings, radio frequency (RF) generator settings, RF matching circuit settings, frequency settings, flow rate settings, fluid delivery settings, positional and operation settings, wafer transfers into and out of a tool and other transfer tools and/or load locks connected to or interfaced with a specific system.

Broadly speaking, the controller 131 may be defined as electronics having various integrated circuits, logic, memory, and/or software that receive instructions, issue instructions, control operation, enable cleaning operations, enable endpoint measurements, and the like. The integrated circuits may include chips in the form of firmware that store program instructions, digital signal processors (DSPs), chips defined as application specific integrated circuits (ASICs), and/or one or more microprocessors, or microcontrollers that execute program instructions (e.g., software). Program instructions may be instructions communicated to the controller in the form of various individual settings (or program files), defining operational parameters for carrying out a particular process on or for a semiconductor wafer or to a system. The operational parameters may, in some embodiments, be part of a recipe defined by process engineers to accomplish one or more processing operations during the fabrication of one or more layers, materials, metals, oxides, silicon, silicon dioxide, surfaces, circuits, and/or dies of a wafer.

The controller 131, in some implementations, may be a part of or coupled to a computer that is integrated with, coupled to the system, otherwise networked to the system, or a combination thereof. For example, the controller may be in the “cloud” or all or a part of a fab host computer system, which can allow for remote access of the wafer processing. The computer may enable remote access to the system to monitor current progress of fabrication operations, examine a history of past fabrication operations, examine trends or performance metrics from a plurality of fabrication operations, to change parameters of current processing, to set processing operations to follow a current processing, or to start a new process. In some examples, a remote computer (e.g. a server) can provide process recipes to a system over a network, which may include a local network or the Internet. The remote computer may include a user interface that enables entry or programming of parameters and/or settings, which are then communicated to the system from the remote computer. In some examples, the controller 131 receives instructions in the form of data, which specify parameters for each of the processing operations to be performed during one or more operations. It should be understood that the parameters may be specific to the type of process to be performed and the type of tool that the controller is configured to interface with or control. Thus as described above, the controller 131 may be distributed, such as by comprising one or more discrete controllers that are networked together and working towards a common purpose, such as the processes and controls described herein. An example of a distributed controller for such purposes would be one or more integrated circuits on a chamber in communication with one or more integrated circuits located remotely (such as at the platform level or as part of a remote computer) that combine to control a process on the chamber.

As noted above, depending on the process operation or operations to be performed by the apparatus, the controller 131 might communicate with one or more of other apparatus circuits or modules, other tool components, cluster tools, other tool interfaces, adjacent tools, neighboring tools, tools located throughout a factory, a main computer, another controller, or tools used in material transport that bring containers of wafers to and from tool locations and/or load ports in a semiconductor manufacturing factory.

As also stated above, the controller is configured to perform any technique described above. This may include causing a substrate transfer robot to position the substrate in the chamber on the plurality of substrate supports causing power to be delivered to the LEDs so that they emit the visible light having wavelengths between 400 nm and 800 nm to heat the substrate to a first temperature, such as between 100° C. and 600° C., and causing etchant gases to flow into the chamber and etch the substrate. This may also include cooling, while the substrate is supported by only the plurality of substrate supports, the substrate by flowing the cooling gas onto the substrate, and/or moving the pedestal vertically so that the substrate is offset from a faceplate of a gas distribution unit by a first nonzero distance, and thereby causing heat to transfer from the substrate to the faceplate through noncontact radiation. This may also include controlling the chemistry delivered to the reaction chamber, as described herein.

### CONCLUSION

Although the foregoing embodiments have been described in some detail for purposes of clarity of understanding, it will be apparent that certain changes and modifications may be practiced within the scope of the appended claims. It should be noted that there are many alternative ways of implementing the processes, systems, and apparatus of the present embodiments. Accordingly, the present embodiments are to be considered as illustrative and not restrictive, and the embodiments are not to be limited to the details given herein.

1. A method of etching a substrate, the method comprising:
a. providing the substrate in a reaction chamber, the substrate comprising a target material that is to be partially or wholly removed from the substrate during etching;
b. providing a gas mixture in the reaction chamber and exposing the substrate to the gas mixture, wherein the gas mixture is vapor phase and comprises:
i. a halogen source,
ii. an organic solvent and/or water,
iii. an additive comprising a hydrogen fluoride complex forming chemical, and
iv. a carrier gas; and
c. providing thermal energy to the reaction chamber to drive a reaction that partially or wholly etches the target material from the substrate, wherein the substrate is not exposed to plasma during etching.

2. The method of claim 1, further comprising:
prior to (b), providing a second gas mixture in the reaction chamber and exposing the substrate to thermal energy and to the second gas mixture, wherein the thermal energy drives a second reaction between the second gas mixture and the target material to form a modified target material, and wherein the reaction in (c) etches the modified target material to thereby partially or wholly etch the target material.

3. The method of claim 1, wherein the hydrogen fluoride complex forming chemical comprises at least one group selected from the group consisting of an amine group, a urea group, a phosphine group, an alkyl group, an imidazole group, a heterocyclic aliphatic group, a heterocyclic aromatic group, an ether group, or a combination thereof.

4. The method of claim 3, wherein the hydrogen fluoride complex forming chemical comprises the urea group.

5. The method of claim 4, wherein the hydrogen fluoride complex forming chemical comprises N,N′-dimethylpropylene urea (DMPU).

6. The method of claim 3, wherein the hydrogen fluoride complex forming chemical comprises an alkyl-substituted ammonium compound.

7. The method of claim 6, wherein the hydrogen fluoride complex forming chemical comprises a compound selected from the group consisting of tetraethylammonium, tetrabutylammonium, and combinations thereof.

8. The method of claim 3, wherein the hydrogen fluoride complex forming chemical comprises a heterocyclic aromatic amine-containing compound.

9. The method of claim 8, wherein the hydrogen fluoride complex forming chemical comprises melamine.

10. The method of claim 3, wherein the hydrogen fluoride complex forming chemical comprises a heterocyclic aliphatic compound and/or a cyclic ether compound.

11. The method of claim 10, wherein the hydrogen fluoride complex forming chemical comprises tetrahydrofuran.

12. The method of claim 3, wherein the hydrogen fluoride complex forming chemical comprises an alkyl-substituted imidazole compound, an alkyl-substituted ether compound, and/or an alkyl-substituted phosphine compound.

13. The method of claim 12, wherein the hydrogen fluoride complex forming chemical comprises a compound selected from the group consisting of dialkylimidazolium, dimethyl ether, trialkylphosphine, and combinations thereof.

14. An apparatus for etching a substrate, the apparatus comprising:
a reaction chamber configured to withstand sub-atmospheric pressure;
a substrate support configured to support the substrate during etching;
an inlet for introducing a gas mixture to the reaction chamber, wherein the gas mixture is vapor phase;
an outlet for removing vapor phase species from the reaction chamber; and
a controller configured to cause:
(a) providing the substrate in the reaction chamber, the substrate comprising a target material that is to be partially or wholly removed from the substrate during etching,
(b) providing the gas mixture to the reaction chamber and exposing the substrate to the gas mixture, wherein the gas mixture is vapor phase and comprises:
i. a halogen source,
ii. an organic solvent and/or water,
iii. an additive comprising a hydrogen fluoride complex forming chemical, and
iv. a carrier gas, and
(c) providing thermal energy to the reaction chamber to drive a reaction that partially or wholly etches the target material from the substrate, wherein the substrate is not exposed to plasma during etching.

15. The apparatus of claim 14, wherein the hydrogen fluoride complex forming chemical comprises at least one group selected from the group consisting of an amine group, a urea group, a phosphine group, an alkyl group, an imidazole group, a heterocyclic aliphatic group, a heterocyclic aromatic group, an ether group, or a combination thereof.

16. The apparatus of claim 15, wherein the hydrogen fluoride complex forming chemical comprises the urea group.

17. The apparatus of claim 16, wherein the hydrogen fluoride complex forming chemical comprises N,N′-dimethylpropylene urea (DMPU).

18. The apparatus of claim 15, wherein the hydrogen fluoride complex forming chemical comprises an alkyl-substituted ammonium compound.

19. The apparatus of claim 18, wherein the hydrogen fluoride complex forming chemical comprises a compound selected from the group consisting of tetraethylammonium, tetrabutylammonium, and combinations thereof.

20. The apparatus of claim 15, wherein the hydrogen fluoride complex forming chemical comprises a heterocyclic aromatic amine-containing compound.

21. The apparatus of claim 20, wherein the hydrogen fluoride complex forming chemical comprises melamine.

22. The apparatus of claim 15, wherein the hydrogen fluoride complex forming chemical comprises a heterocyclic aliphatic compound and/or a cyclic ether compound.

23. The apparatus of claim 22, wherein the hydrogen fluoride complex forming chemical comprises tetrahydrofuran.

24. The apparatus of claim 15, wherein the hydrogen fluoride complex forming chemical comprises an alkyl-substituted imidazole compound, an alkyl-substituted ether compound, and/or an alkyl-substituted phosphine compound.

25. The apparatus of claim 24, wherein the hydrogen fluoride complex forming chemical comprises a compound selected from the group consisting of dialkylimidazolium, dimethyl ether, trialkylphosphine, and combinations thereof.

26. The method of claim 3, wherein the hydrogen fluoride complex forming chemical comprises an alkyl amine.

27. The method of claim 26, wherein the alkyl amine comprises trimethylamine and/or triethylamine.

28. The method of claim 1, wherein the organic solvent comprises an alcohol.

29. The method of claim 28, wherein the alcohol comprises 1-butanol.
